(19) United States
(12) Patent Application Publication
(10) Pub. No.: US 2024/0421142 A1
(43) Pub. Date: Dec. 19, 2024

(54) LIGHT-EMITTING DEVICE, DISPLAY DEVICE, WEARABLE DEVICE, AND METHOD OF MANUFACTURING LIGHT-EMITTING DEVICE

(71) Applicants: SHARP KABUSHIKI KAISHA, Osaka (JP); Meijo University, Nagoya-shi (JP)

(72) Inventors: YOSHIHIRO UETA, Sakai City, Osaka (JP); Motoaki IWAYA, Nagoya-shi (JP); Yoshinobu SUEHIRO, Nagoya-shi (JP); Yuta IMAIZUMI, Nagoya-shi (JP); Tatsunari SAITO, Nagoya-shi (JP); Naoki HASEGAWA, Nagoya-shi (JP); Keigo IMURA, Nagoya-shi (JP)

(21) Appl. No.: 18/744,578

(22) Filed: Jun. 14, 2024

(30) Foreign Application Priority Data
Jun. 16, 2023 (JP) 2023-099520
Jun. 16, 2023 (JP) 2023-099521
Jun. 16, 2023 (JP) 2023-099522
Jun. 16, 2023 (JP) 2023-099523

(51) Int. Cl. H01L 25/18; H01L 27/15

(52) U.S. Cl. CPC H01L 25/18; H01L 27/156

(57) ABSTRACT

A light-emitting device in accordance with the present disclosure includes: a first semiconductor layer including a first light-emitting layer, and a second semiconductor layer including a second light-emitting layer, wherein the first semiconductor layer has a first sidewall adjacent to a second sidewall of the second semiconductor layer over a gap, and a normal to the first sidewall is not parallel to a normal to the second sidewall (α≠0°).

### FIELD OF THE INVENTION

The present disclosure relates to light-emitting devices, display devices, wearable devices, and methods of manufacturing light-emitting devices.

### BACKGROUND OF THE INVENTION

Patent Literature 1 discloses a micro-LED panel that is rectangular in a plan view and in which there is provided a plurality of micro LEDs in rows and columns.

### CITATION LIST

### Patent Literature

Patent Literature 1: Japanese Unexamined Patent Application Publication No. 2018-185515
Patent Literature 2: Japanese Unexamined Patent Application Publication No. 2023-001062
Patent Literature 3: Japanese Unexamined Patent Application Publication No. 2010-96882

### SUMMARY OF THE INVENTION

### Problems to be Solved by the Invention

However, the above-described conventional art disadvantageously allows for generation of visually recognizable levels of stray light.

### Solution to the Problems

To address this problem, the present disclosure, in one aspect thereof, is directed to a light-emitting device including: a first semiconductor layer including a first light-emitting layer; and a second semiconductor layer including a second light-emitting layer, wherein the first semiconductor layer has a first sidewall adjacent to a second sidewall of the second semiconductor layer over a gap, and a normal to the first sidewall is not parallel to a normal to the second sidewall.

To address this problem, the present disclosure, in one aspect thereof, is directed to a display device including the light-emitting device in accordance with the present disclosure.

To address this problem, the present disclosure, in one aspect thereof, is directed to a wearable device including the light-emitting device in accordance with the present disclosure.

To address this problem, the present disclosure, in one aspect thereof, is directed to a method of manufacturing a light-emitting device, the method including: a step of growing a semiconductor crystal on a growth substrate; and a step of forming a first semiconductor layer and a second semiconductor layer by patterning the semiconductor crystal, the first semiconductor layer including a first light-emitting layer and having a first sidewall, the second semiconductor layer including a second light-emitting layer and having a second sidewall, wherein the first sidewall is adjacent to the second sidewall over a gap, and a normal to the first sidewall is not parallel to a normal to the second sidewall.

### Advantageous Effects of the Invention

The present disclosure, in an aspect thereof, enables reducing stray light.

### BRIEF DESCRIPTION OF DRAWINGS

FIG. 1 is a plan view of an exemplary structure of a light-emitting device in accordance with an embodiment of the present disclosure.

FIG. 2 is an X-direction cross-sectional view taken through an anode shown in FIG. 1.

FIG. 3 is an X-direction cross-sectional view taken through a cathode shown in FIG. 1.

FIG. 4 is Y-direction cross-sectional views taken through respective first to third light-emitting elements shown in FIG. 1.

FIG. 5 is a two-view drawing including a plan view and an X-direction cross-sectional view of a structure of a light-emitting device in accordance with Comparative Example 1.

FIG. 6 is a plan view of some other exemplary structures of the light-emitting device in accordance with the embodiment of the present disclosure.

FIG. 7 is a plan view of some other exemplary structures of the light-emitting device in accordance with the embodiment of the present disclosure.

FIG. 8 is a plan view of some other exemplary structures of the light-emitting device in accordance with the embodiment of the present disclosure.

FIG. 9 is a plan view of another exemplary structure of the light-emitting device in accordance with the embodiment of the present disclosure.

FIG. 10 is a plan view of another exemplary structure of the light-emitting device in accordance with the embodiment of the present disclosure.

FIG. 11 is a plan view of various exemplary shapes of a semiconductor layer in accordance with the embodiment of the present disclosure.

FIG. 12 is a plan view of an exemplary positional relationship of semiconductor layers in accordance with the embodiment of the present disclosure.

FIG. 13 is a plan view of an exemplary positional relationship of semiconductor layers in accordance with the embodiment of the present disclosure.

FIG. 14 is a plan view of an exemplary positional relationship of semiconductor layers in accordance with the embodiment of the present disclosure.

FIG. 15 is an X-direction cross-sectional view representing a light distribution of light exiting a light-emitting layer.

FIG. 16 is a diagram representing an intensity distribution of the light extracted when the light-emitting layer in accordance with Comparative Example 1 shown in FIG. 5 is emitting light.

FIG. 17 is an X-direction cross-sectional view depicting primary emitted light and cyclic stray light in accordance with Comparative Example 1 shown in FIG. 5.

FIG. 18 is an X-direction cross-sectional view depicting broad stray light and cyclic stray light in accordance with Comparative Example 1 shown in FIG. 5.

FIG. 19 is a flow chart representing a method of manufacturing a light-emitting device in accordance with Example 1 of an embodiment of the present disclosure.

FIG. 20 is a cross-sectional view of the method of manufacturing the light-emitting device in accordance with Example 1.

FIG. 21 is a cross-sectional view of the method of manufacturing the light-emitting device in accordance with Example 1.

FIG. 22 is a cross-sectional view of the method of manufacturing the light-emitting device in accordance with Example 1.

FIG. 23 is a cross-sectional view of the method of manufacturing the light-emitting device in accordance with Example 1.

FIG. 24 is a cross-sectional view of a structure of a light-emitting device in accordance with Example 2 of the present embodiment.

FIG. 25 is a representation of a photograph taken of a glowing one of light-emitting elements in a light-emitting device in accordance with Comparative Example 2.

FIG. 26 is a representation of a photograph taken of a glowing one of light-emitting elements in a light-emitting device in accordance with Example 2.

FIG. 27 is a plan view of a light-emitting device in accordance with an embodiment of the present disclosure.

FIG. 28 is an X-direction cross-sectional view taken through an anode in a light-emitting device in accordance with an embodiment of the present disclosure.

FIG. 29 is a cross-sectional view of an exemplary structure of a display device in accordance with an embodiment of the present disclosure.

FIG. 30 is a cross-sectional view of an exemplary structure of a display device in accordance with an embodiment of the present disclosure.

FIG. 31 is a cross-sectional view of a schematic configuration of a display panel according to a fourth embodiment;

FIG. 32 is a plan view of a display surface of the display panel illustrated in FIG. 31;

FIG. 33 is a flowchart showing a method for producing the display panel illustrated in FIG. 31;

FIG. 34 is a diagram showing Step S20, Step S22, and Step S24 in FIG. 33;

FIG. 35 is a diagram showing Step S26 in FIG. 33;

FIG. 36 is a diagram showing Step S28 in FIG. 33;

FIG. 37 is a diagram showing Step S30 in FIG. 33;

FIG. 38 is a plan view of a wafer after Step S30 shown in FIG. 33 and before Step S32 shown in FIG. 33, the wafer being viewed from toward an anode and a cathode;

FIG. 39 is a cross-sectional view of a schematic configuration of a display panel according to Comparative Example 4 example;

FIG. 40 is a diagram showing a factor why the display panel according to the fourth embodiment and the display panel according to Comparative Example 4 produce stray light;

FIG. 41 is a diagram showing a case where, in the display panel according to Comparative Example 4, how the stray light produced by the factor illustrated in FIG. 40 makes an adjacent subpixel, including an OFF light-emitting element, appear to falsefully emit light;

FIG. 42 is a diagram showing another factor why the display panel according to the fourth embodiment and the display panel according to Comparative Example 4 produce stray light;

FIG. 43 is a diagram showing a case where, in the display panel according to Comparative Example 4, how the stray light produced by the factor illustrated in FIG. 42 makes an adjacent subpixel, including an OFF light-emitting element, appear to falsefully emit light;

FIG. 44 is a graph showing a distribution of stray light in the display panel according to Comparative Example 4;

FIG. 45 shows a graph showing a distribution of stray light in the display panel according to the fourth embodiment and a diagram showing why light emitted from an ON light-emitting element can be kept from becoming stray light in the display panel according to the fourth embodiment;

FIG. 46 is a graph showing a distribution of stray light obtained by optical calculation using, as a model, a display panel according to Comparative Example 5 illustrated in FIG. 57;

FIG. 47 is a graph showing a stray light distribution obtained by optical calculation using, as a model, the display panel according to the fifth embodiment illustrated in FIG. 56, the display panel including a light absorber having a refractive index of 2.47 and a transmittance of 0.9;

FIG. 48 is a graph showing a stray light distribution obtained by optical calculation using, as a model, the display panel according to the fifth embodiment illustrated in FIG. 56, the display panel including a light absorber having a refractive index of 2.47 and a transmittance of 0.7;

FIG. 49 is a graph showing a stray light distribution obtained by optical calculation using, as a model, the display panel according to the fifth embodiment illustrated in FIG. 56, the display panel including a light absorber having a refractive index of 2.47 and a transmittance of 0.3;

FIG. 50 is a graph showing a stray light distribution obtained by optical calculation using, as a model, the display panel according to the fifth embodiment illustrated in FIG. 56, the display panel including a light absorber having a refractive index of 2.47 and a transmittance of 0.1;

FIG. 51 is a graph showing a stray light distribution obtained by optical calculation using, as a model, the display panel according to the fifth embodiment illustrated in FIG. 56, the display panel including a light absorber having a refractive index of 1.5 and a transmittance of 1;

FIG. 52 is a graph showing a stray light distribution obtained by optical calculation using, as a model, the display panel according to the fifth embodiment illustrated in FIG. 56, the display panel including a light absorber having a refractive index of 3.47 and a transmittance of 1;

FIG. 53 is a graph showing a stray light distribution obtained by optical calculation using, as a model, the display panel according to the fifth embodiment illustrated in FIG. 56, the display panel including a light absorber having a refractive index of 3.47 and a transmittance of 0.3;

FIG. 54 is a cross-sectional view of a schematic configuration of another display panel according to the fourth embodiment;

FIG. 55 is a cross-sectional view of a schematic configuration of still another display panel according to the fourth embodiment;

FIG. 56 is a cross-sectional view of a schematic configuration of a display panel according to a fifth embodiment;

FIG. 57 is a cross-sectional view of a schematic configuration of the display panel according to Comparative Example 5;

FIG. 58 is a graph showing a stray light distribution in a direction H1 in FIG. 32, as to each of the display panel illustrated in FIG. 56 according to the fifth embodiment and the display panel illustrated in FIG. 57 according to Comparative Example 5;

FIG. 59 is a graph showing a stray light distribution in a direction H2 in FIG. 32, as to each of the display panel illustrated in FIG. 56 according to the fifth embodiment and the display panel illustrated in FIG. 57 according to Comparative Example 5;

FIG. 60 is a cross-sectional view of a schematic configuration of a display panel according to a sixth embodiment; and

FIG. 61 is a cross-sectional view of a schematic configuration of a display panel according to Comparative Example 6.

FIG. 62 is a cross-sectional view of a schematic configuration of a display panel according to Embodiment 7;

FIG. 63 is a plan view of a display surface of the display panel illustrated in FIG. 62;

FIG. 64 is a flowchart showing a method for producing the display panel illustrated in FIG. 62;

FIG. 65 is a diagram showing Step S20, Step S22, and Step S24 in FIG. 64;

FIG. 66 is a diagram showing Step S26 in FIG. 64;

FIG. 67 is a diagram showing Step S28 in FIG. 64;

FIG. 68 is a diagram showing Step S30 in FIG. 64;

FIG. 69 is a plan view of the display panel after Step S30 shown in FIG. 64 and before Step S32 shown in FIG. 64, the display panel being viewed from toward an anode and a cathode;

FIG. 70 is a cross-sectional view of a schematic configuration of a display panel according to Comparative example 4;

FIG. 71 is a diagram showing a factor why the display panel according to Embodiment 7 and the display panel according to Comparative example 4 produce stray light;

FIG. 72 is a diagram showing a case where, in the display panel according to Comparative example 4, how the stray light produced by the factor illustrated in FIG. 71 makes an adjacent subpixel, including an OFF light-emitting element, appear to falsefully emit light;

FIG. 73 is a diagram showing another factor why the display panel according to Embodiment 7 and the display panel according to Comparative example 4 produce stray light;

FIG. 74 is a diagram showing a case where, in the display panel according to Comparative example 4, how the stray light produced by the factor illustrated in FIG. 73 makes an adjacent subpixel, including an OFF light-emitting element, appear to falsefully emit light;

FIG. 75 is a graph showing a distribution of stray light in the display panel according to Comparative example 4;

FIG. 76 shows a graph showing a distribution of stray light in the display panel according to Embodiment 7 and a diagram showing why light emitted from an ON light-emitting element can be kept from becoming stray light in the display panel according to Embodiment 7;

FIG. 77 is a cross-sectional view of a schematic configuration of another display panel according to Embodiment 7;

FIG. 78 is a cross-sectional view of a schematic configuration of still another display panel according to Embodiment 7;

FIG. 79 is a diagram showing Rayleigh scattering by a scatterer;

FIG. 80 is a diagram showing Mie scattering by a scatterer;

FIG. 81 is a graph showing a distribution of stray light obtained by optical calculation using, as a model, a display panel according to Embodiment 8, which is the same as the display panel illustrated in FIG. 62, except that scatterers used for the display panel according to Embodiment 8 are larger in size than the scatterers used for the display panel illustrated in FIG. 62;

FIG. 82 is a cross-sectional view of a schematic configuration of a display panel according to Embodiment 9;

FIG. 83 is a graph showing a distribution of stray light in the display panel according to Embodiment 9;

FIG. 84 is a cross-sectional view of a schematic configuration of a display panel according to Embodiment 10;

FIG. 85 is a cross-sectional view of a schematic configuration of a display panel according to Comparative Example 5;

FIG. 86 is a graph showing a distribution of stray light obtained by optical calculation using, as a model, the display panel according to Comparative Example 5 illustrated in FIG. 85;

FIG. 87 is a graph showing a distribution of stray light obtained by optical calculation using, as a model, the display panel according to Embodiment 10 illustrated in FIG. 84;

FIG. 88 is a cross-sectional view of a schematic configuration of a display panel according to Embodiment 11; and

FIG. 89 is a cross-sectional view of a schematic configuration of a display panel according to Comparative Example 6.

FIG. 90 is a flow chart representing an exemplary method of manufacturing a light-emitting device in accordance with Embodiment 12.

FIG. 91 is a cross-sectional view of this exemplary manufacturing method in accordance with Embodiment 12.

FIG. 92 is a cross-sectional view of the exemplary manufacturing method in accordance with Embodiment 12.

FIG. 93 is a cross-sectional view of the exemplary manufacturing method in accordance with Embodiment 12.

FIG. 94 is a cross-sectional view of the exemplary manufacturing method in accordance with Embodiment 12.

FIG. 95 is a cross-sectional view of an exemplary structure of a display device in accordance with Embodiment 12.

FIG. 96 is a schematic illustration of a structure of a light-emitting device in accordance with Embodiment 13.

FIG. 97 is a schematic cross-sectional view of the light-emitting device in accordance with Embodiment 13.

FIG. 98 is an exemplary image of a plurality of actual light-emitting elements manufactured by the inventors.

FIG. 99 is a diagram illustrating a cause of stray light in a light-emitting device in accordance with an aspect of the present disclosure.

FIG. 100 illustrates a light intensity measurement direction in a simulation.

FIG. 101 represents exemplary light intensity distributions respectively in a first model and in a second model derived in a simulation.

FIG. 102 is a schematic illustration of stray light that occurs in the first model.

FIG. 103 is a schematic illustration of stray light that occurs in the second model.

FIG. 104 illustrates another exemplary structure of a light-emitting device in accordance with Embodiment 13.

### DESCRIPTION OF EMBODIMENTS

### Embodiment 1

### Structure

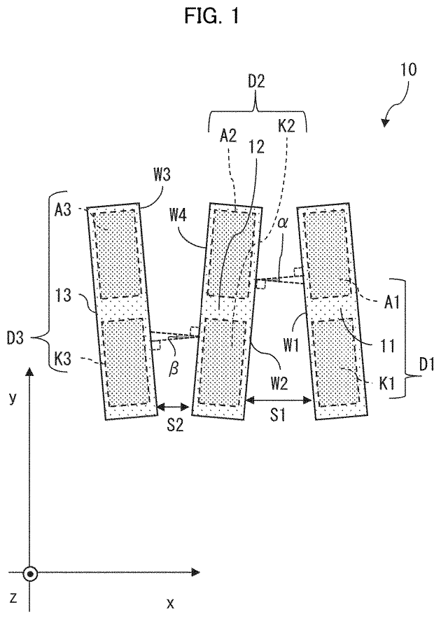

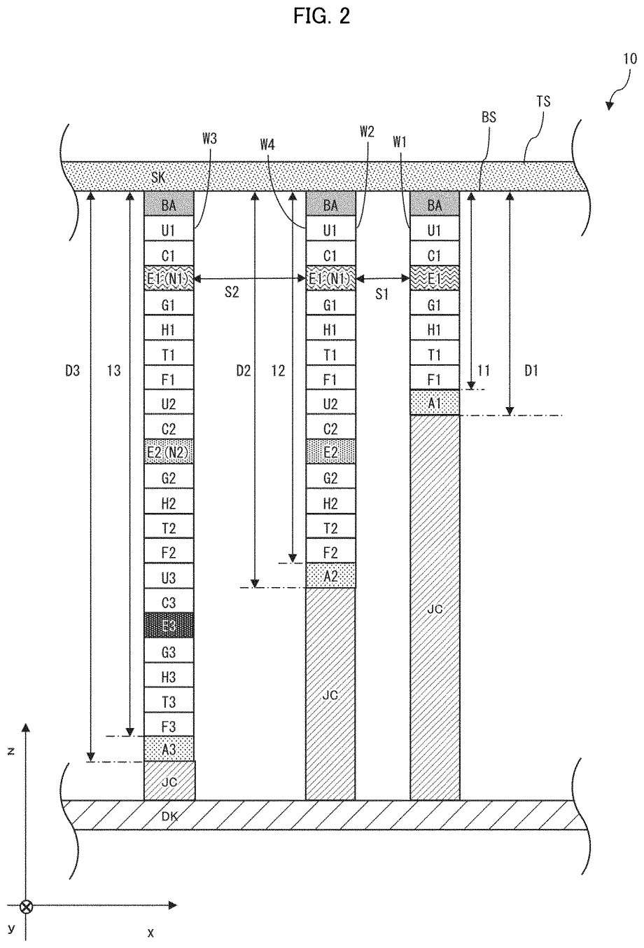

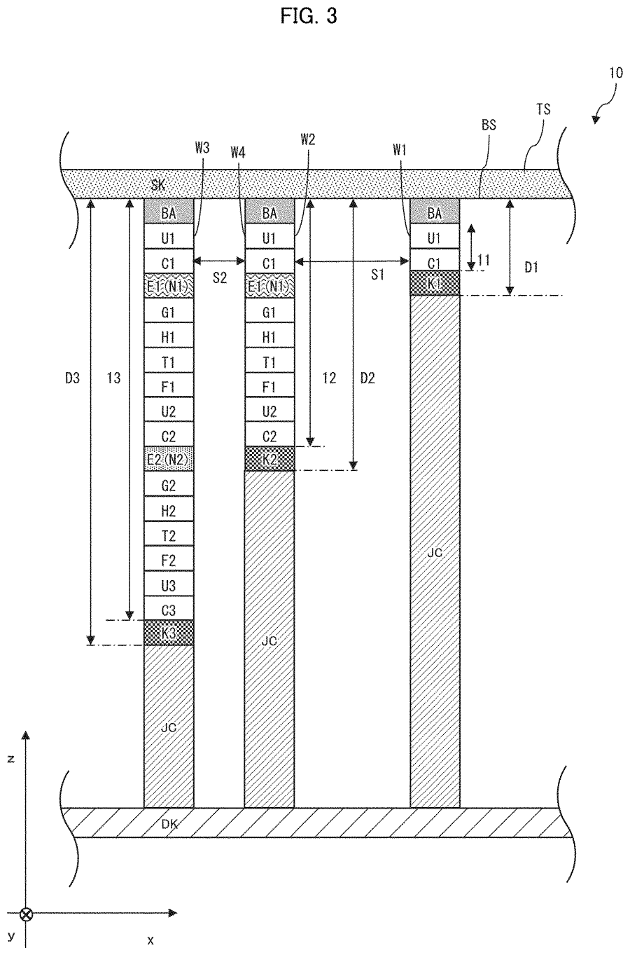

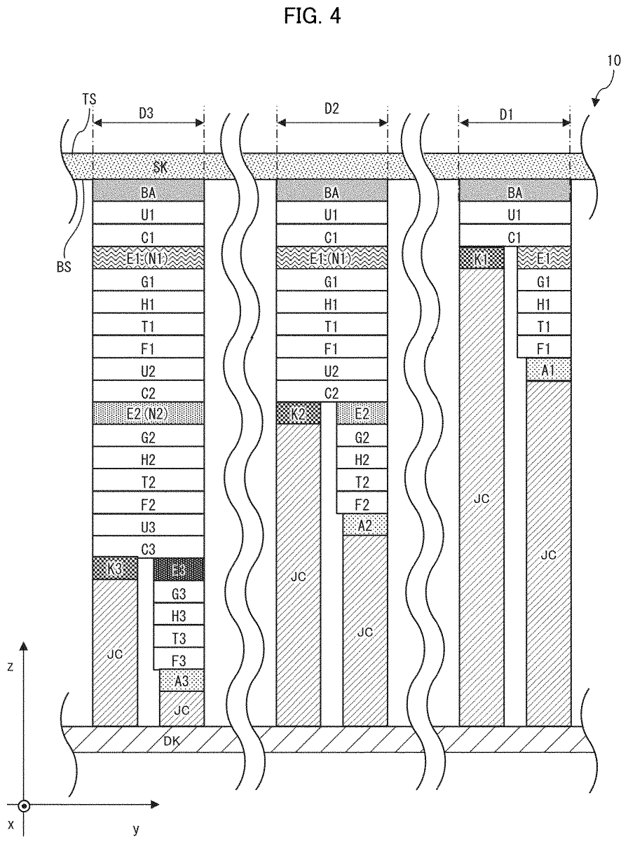

FIG. 1 is a plan view of an exemplary structure of a light-emitting device in accordance with an embodiment of the present disclosure. FIG. 2 is an X-direction cross-sectional view taken through an anode shown in FIG. 1. FIG. 3 is an X-direction cross-sectional view taken through a cathode shown in FIG. 1. FIG. 4 is Y-direction cross-sectional views taken through respective first to third light-emitting elements shown in FIG. 1. In an embodiment of the present disclosure, the z-direction is defined as a light-extracting direction for a light-emitting device 10, the x-direction is defined as a direction along which a first light-emitting element D1 and a second light-emitting element D2 are lined up, and the y-direction is defined as a direction perpendicular to the x-direction and the z-direction. In addition, the up/down direction is defined as the light-extracting direction (z-direction), and the upper side is defined as a side of the light-emitting device 10 on which there is provided a light-extracting face TS.

Referring to FIGS. 1 to 4, the light-emitting device 10 in accordance with an embodiment of the present disclosure includes a first semiconductor layer 11 including a first light-emitting layer E1 and a second semiconductor layer 12 including a second light-emitting layer E2. In the light-emitting device 10, the first semiconductor layer 11 has a first sidewall W1, and the second semiconductor layer 12 has a second sidewall W2, the first sidewall W1 and the second sidewall W2 being adjacent to each other via a gap S1. A normal to the first sidewall W1 is not parallel to a normal to the second sidewall W2 in a plan view. A normal to a plane is parallel to the intersection of two planes that are perpendicular to this plane and passes through the plane. A normal to a curved face is a normal to a tangent plane of this curved face and passes through a point of tangency of the tangent plane to the curved face.

In this structure, the light exiting perpendicularly through the first sidewall W1 travels through the gap S1 and obliquely strikes the second sidewall W2. Then, part of the light reflects off the second sidewall W2 and returns to the gap S1, and other part of the light refracts at the second sidewall W2 and enters the second semiconductor layer 12. As described here, the light exiting perpendicularly through the first sidewall W1 will likely reflect off, and refract at, the second sidewall W2 and hence poorly propagate and readily attenuate inside the light-emitting device 10.

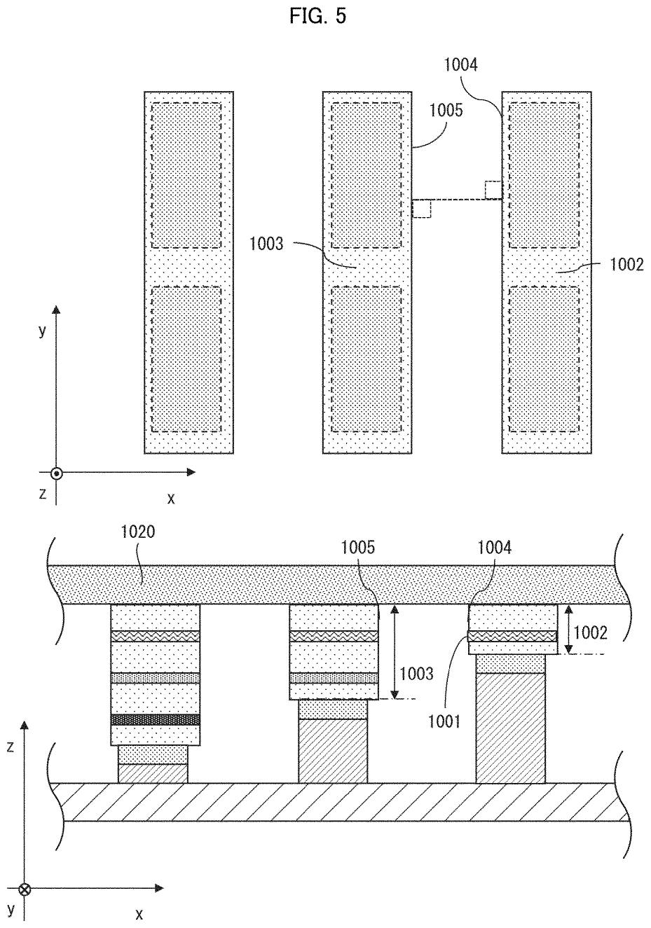

FIG. 5 is a two-view drawing including a plan view and an X-direction cross-sectional view of a structure of a light-emitting device in accordance with Comparative Example 1. Referring to FIG. 5, Comparative Example 1 includes: a semiconductor layer 1002 including a light-emitting layer 1001; and a semiconductor layer 1003 adjacent to the semiconductor layer 1002 via a gap. A normal to a sidewall 1004 of the semiconductor layer 1002 is parallel to a normal to a sidewall 1005 of the semiconductor layer 1003. The light exiting perpendicularly through the sidewall 1004 is perpendicularly incident to the sidewall 1005. Perpendicularly incident light reflects less than obliquely incident light and additionally does not refract. Therefore, the light exiting perpendicularly through the sidewall 1004 readily propagates and likely to exit the light-emitting device as stray light in a location removed from the light-emitting layer 1001.

Therefore, the structure in accordance with an embodiment of the present disclosure is capable of reducing stray light in the light-emitting device 10 when compared with the structure in accordance with Comparative Example 1 shown in FIG. 4.

Referring to FIG. 1, the second sidewall W2 is specified so that a normal to the first sidewall W1 can intersect with the second sidewall W2. A normal to the first sidewall W1 may intersect with the second sidewall W2, and also a normal to the second sidewall W2 may intersect with the first sidewall W1. Because the first sidewall W1 and the second sidewall W2 are not parallel to each other, the distance by which the first sidewall W1 and the second sidewall W2 are separated from each other over the gap S1 is variable. The first sidewall W1 and the second sidewall W2 are separated from each other by a minimum distance of from 30 nm to 2.0 μm. The distance separating the first sidewall W1 from the second sidewall W2 is variable in a plan view of the first semiconductor layer 11 and the second semiconductor layer 12. A normal to the first sidewall W1 may form acute angle α of less than or equal to 10° with a normal to the second sidewall W2.

In the present disclosure, when a sidewall of a semiconductor layer X is adjacent to a sidewall of another semiconductor layer Y via a gap, and also a normal to this sidewall of the semiconductor layer X intersects with this sidewall of the semiconductor layer Y, the sidewall of the semiconductor layer Y is described as being opposite the sidewall of the semiconductor layer X. When a normal to a first sidewall of the semiconductor layer X intersects with a second sidewall of the semiconductor layer X, the semiconductor layer X is described as having the second sidewall opposite the first sidewall. When a normal to a sidewall is parallel to a normal to another sidewall, these two sidewalls are described as being parallel to each other.

The gap S1 between the first sidewall W1 and the second sidewall W2 may have a lower refractive index than the refractive indices of the first semiconductor layer 11 and the second semiconductor layer 12. This refractive index difference renders the light incident to the second sidewall W2 more likely to reflect and refract. Accordingly, stray light can be further reduced. The refractive indices of the first semiconductor layer 11 and the second semiconductor layer 12 are preferably greater than or equal to twice the refractive index of the gap S1. For example, the first semiconductor layer 11 and the second semiconductor layer 12 are formed of a gallium nitride-based semiconductor, and the gap S1 is filled with a gas. The gallium nitride-based semiconductor has a refractive index of approximately 2.4, and the gas has a refractive index of approximately 1, to 450 nm light.

Referring to FIGS. 2 to 4, the first light-emitting layer E1 and the second light-emitting layer E2 are separated by different distances from the light-extracting face TS. The second semiconductor layer 12 includes a dummy light-emitting layer N1 made of the same material as the first light-emitting layer E1, and the dummy light-emitting layer N1 is separated by the same distance from the light-extracting face TS as is the first light-emitting layer E1. The first light-emitting layer E1 emits light of a first color, and the second light-emitting layer E2 emits light of a second color. Each of the first color and the second color is any of the red, green, and blue colors.

The first semiconductor layer 11 emits light also through sidewalls including the first sidewall W1. The second semiconductor layer 12 emits light also through sidewalls including the second sidewall W2 and a fourth sidewall W4 (detailed later). Light also exits through the first sidewall W1 and the second sidewall W2.

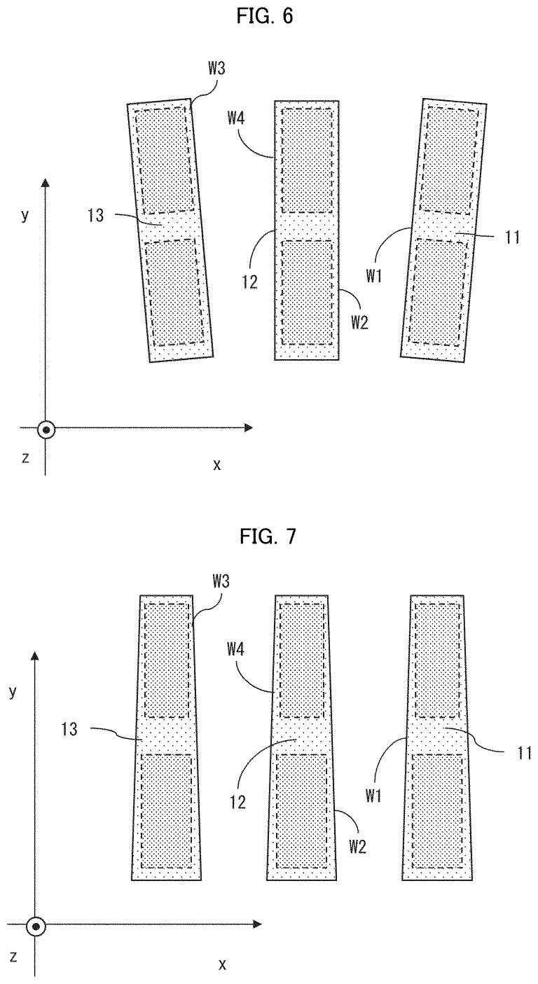

FIGS. 6, 7, and 8 are plan views of some other exemplary structures of the light-emitting device in accordance with the embodiment of the present disclosure. Referring to FIGS. 1, 6, 7, and 8, the first sidewall W1 and the second sidewall W2 are planar. Referring to FIGS. 1, 6, 7, and 8, the first semiconductor layer 11 and the second semiconductor layer 12 are, for example, quadrilateral in a plan view. The quadrilateral may be any one of a rectangle, a trapezoid, and a rhombus.

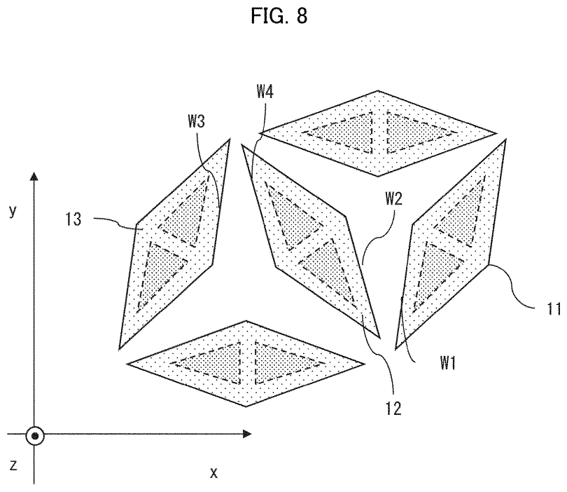

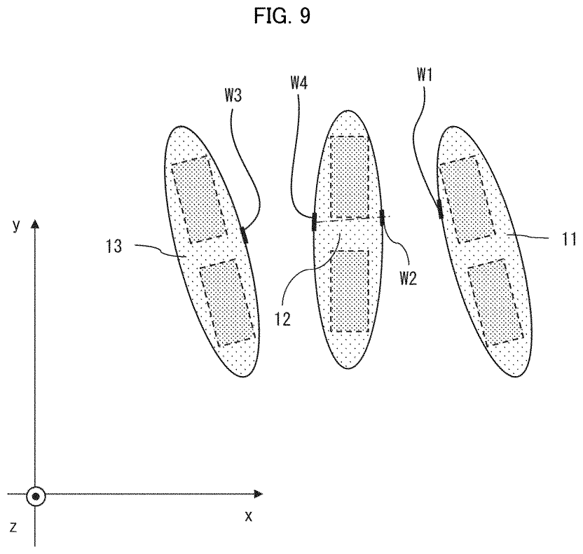

FIG. 9 is a plan view of another exemplary structure of the light-emitting device in accordance with the embodiment of the present disclosure. Referring to FIG. 9, the first sidewall W1 and the second sidewall W2 may be curved. The first semiconductor layer 11 and the second semiconductor layer 12 are, for example, circular or elliptical in a plan view. The major axis of the ellipse in a plan view of the first semiconductor layer 11 is not parallel to the major axis of the ellipse in a plan view of the second semiconductor layer 12. When the first semiconductor layer 11 has a curved sidewall, a portion, of this sidewall of the first semiconductor layer 11, a normal to which intersects with a sidewall of the second semiconductor layer is specified as the first sidewall W1. When the second semiconductor layer 12 has a curved sidewall, a portion, of this sidewall of the second semiconductor layer 12, that intersects with a normal to the first sidewall W1 is specified as the second sidewall W2.

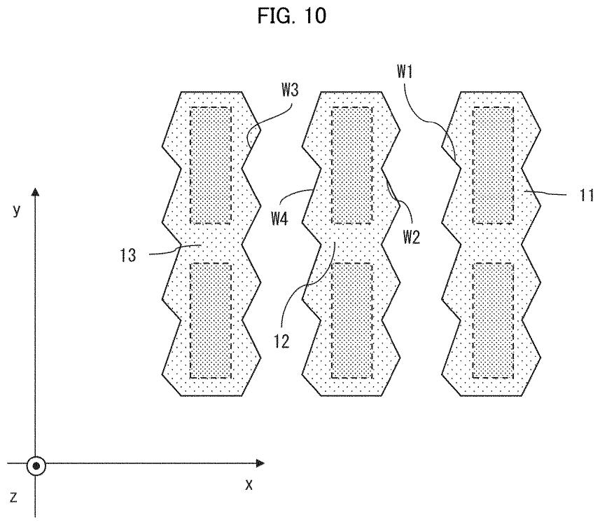

FIG. 10 is a plan view of another exemplary structure of the light-emitting device in accordance with the embodiment of the present disclosure. Referring to FIG. 10, the first sidewall W1 and the second sidewall W2 are planar, and the first semiconductor layer 11 and the second semiconductor layer 12 are concave polygons with five or more sides in a plan view.

Referring to FIGS. 2 and 3, the first sidewall W1 and the second sidewall W2 are separated from each other by a distance that is substantially constant regardless of the position along a thickness direction z. The first sidewall W1 and the second sidewall W2 are substantially perpendicular to the light-extracting face TS.

Referring to FIGS. 1 to 4, the light-emitting device 10 further includes a third semiconductor layer 13 including a third light-emitting layer E3. The third semiconductor layer 13 has a third sidewall W3 adjacent via a gap S2 to the fourth sidewall W4 of the second semiconductor layer 12 opposite the second sidewall W2. A normal to the third sidewall W3 is not parallel to a normal to the fourth sidewall W4 in a plan view. The fourth sidewall W4 is specified to be one of the sidewalls of the second semiconductor layer 12 that intersects with a normal to the second sidewall W2.

In this structure, the light exiting perpendicularly through the fourth sidewall W4 travels through the gap S2 and obliquely strikes the third sidewall W3. Therefore, the light traveling through the gap S1 and the second semiconductor layer 12 and then exiting perpendicularly through the fourth sidewall W4 will likely reflect off, and refract at, the third sidewall W3 and hence poorly propagate and readily attenuate inside the light-emitting device 10. Therefore, stray light can be further reduced.

The third sidewall W3 is specified so that a normal to the fourth sidewall W4 can intersect with the third sidewall W3. A normal to the fourth sidewall W4 may intersect with the third sidewall W3, and also a normal to the third sidewall W3 may intersect with the fourth sidewall W4. Because the third sidewall W3 and the fourth sidewall W4 are not parallel to each other, the distance by which the third sidewall W3 and the fourth sidewall W4 are separated over the gap S2 is variable. The third sidewall W3 and the fourth sidewall W4 are separated from each other by a minimum distance of from 30 nm to 2.0 μm. The distance separating the third sidewall W3 from the fourth sidewall W4 is variable in a plan view of the third semiconductor layer 13 and the second semiconductor layer 12. The minimum distance between the third sidewall W3 and the fourth sidewall W4 may differ from the minimum distance between the first sidewall W1 and the second sidewall W2. A normal to the third sidewall W3 may form acute angle β of less than or equal to 10° with a normal to the fourth sidewall W4.

The gap S2 between the third sidewall W3 and the fourth sidewall W4 may have a lower refractive index than the refractive indices of the third semiconductor layer 13 and the second semiconductor layer 12. This refractive index difference renders the light incident to the third sidewall W3 more likely to reflect and refract. Accordingly, stray light can be further reduced. The refractive indices of the third semiconductor layer 13 and the second semiconductor layer 12 are preferably greater than or equal to twice the refractive index of the gap S2. For example, the third semiconductor layer 13 and the second semiconductor layer 12 are formed of a gallium nitride-based semiconductor, and the gap S2 is filled with a gas.

The third light-emitting layer E3 is separated by different distances from the light-extracting face TS than are the first light-emitting layer E1 and the second light-emitting layer E2. The third semiconductor layer 13 includes a dummy light-emitting layer N1 made of the same material as the first light-emitting layer E1, and the dummy light-emitting layer N1 is separated by the same distance from the light-extracting face TS as is the first light-emitting layer E1. The third semiconductor layer 13 includes a dummy light-emitting layer N2 made of the same material as the second light-emitting layer E2, and the dummy light-emitting layer N2 is separated by the same distance from the light-extracting face TS as is the second light-emitting layer E2. The third light-emitting layer E3 emits light of a third color. The third color is any of the red, green, and blue colors.

The third semiconductor layer 13 emits light also through sidewalls including the third sidewall W3. The third sidewall W3 is planar, and the third semiconductor layer 13 is quadrilateral in a plan view. Referring to FIGS. 1, 6, 7, and 8, the quadrilateral may be any one of a rectangle, a trapezoid, and a rhombus. Referring to FIG. 9, the third sidewall W3 and the fourth sidewall W4 may be curved. The third semiconductor layer 13 is, for example, circular, elliptical, or oval in a plan view. The major axis of the ellipse in a plan view of the third semiconductor layer 13 is not parallel to the major axis of the ellipse in a plan view of the second semiconductor layer 12. Referring to FIG. 10, the third sidewall W3 may be planar, and the third semiconductor layer 13 may be a concave polygon with five or more sides in a plan view.

In addition, there is preferably no sidewall parallel to, and opposite, the first sidewall W1. More preferably, there is no sidewall parallel to, and opposite, any sidewall of the first semiconductor layer 11. Likewise, there is preferably no sidewall parallel to, and opposite, any sidewall of the second semiconductor layer 12 and the third semiconductor layer 13.

FIG. 11 is a plan view of various exemplary shapes of a semiconductor layer in accordance with the embodiment of the present disclosure. Referring to FIG. 11, the first semiconductor layer 11, the second semiconductor layer 12, and the third semiconductor layer 13 may be shaped like, among many other examples, a triangle, a non-isosceles trapezoid, or a heptagon. When the first semiconductor layer 11, the second semiconductor layer 12, or the third semiconductor layer 13 is polygonal, at least one of its sides is preferably not parallel to the opposite side.

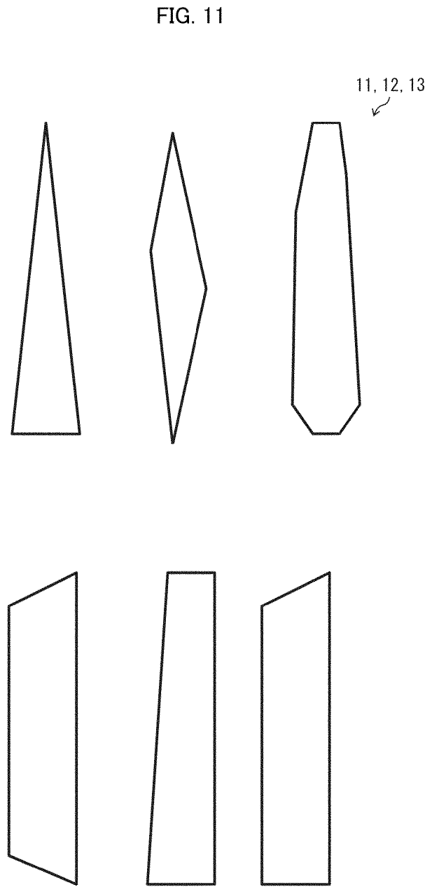

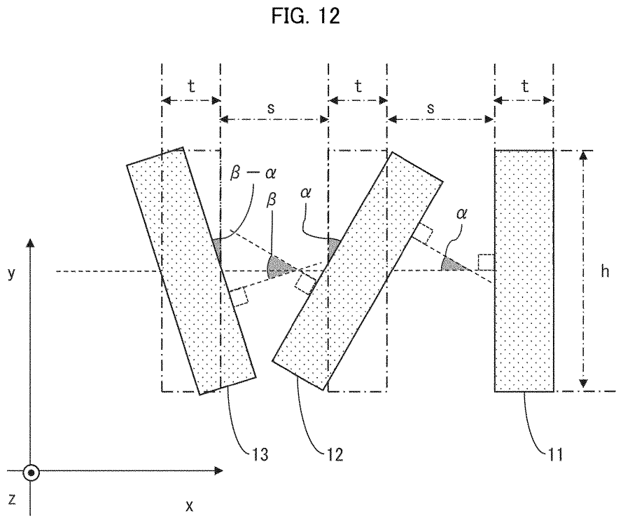

FIG. 12 is a plan view of an exemplary positional relationship of semiconductor layers in accordance with the embodiment of the present disclosure. Referring to FIG. 12, when the first semiconductor layer 11, the second semiconductor layer 12, and the third semiconductor layer 13 are substantially rectangular with a width t and a height h in a plan view and have sidewalls separated by an average interval s, condition expression (1) below holds such that the first sidewall W1 and the second sidewall W2 are separated from each other. In addition, condition expressions (2) and (3) below hold such that the third sidewall W3 and the fourth sidewall W4 are not parallel to each other and separated from each other. Both acute angles α and β are an acute angle and are for this reason larger than 0° and smaller than 90°.

$$\begin{matrix}Math . 1 & \\ h \times cos ( α ) < 2 s + t & ( 1 )\end{matrix}$$

$$α \neq β \qquad ( 2 )$$

$$\frac{h}{2} \times cos ( α ) + \frac{h}{2} \times cos ( β - α ) < s \qquad ( 3 )$$

Condition expressions (1′) and (3′) below are derived respectively from condition expressions (1) and (3).

$$\begin{matrix}Math . 2 & \\ α < {cos}^{- 1} ( \frac{2 s + t}{h} ) & ( {1}^{′} )\end{matrix}$$

$$β < {sin}^{- 1} ( \frac{\sqrt{2 s}}{h} ) \qquad ( {3}^{′} )$$

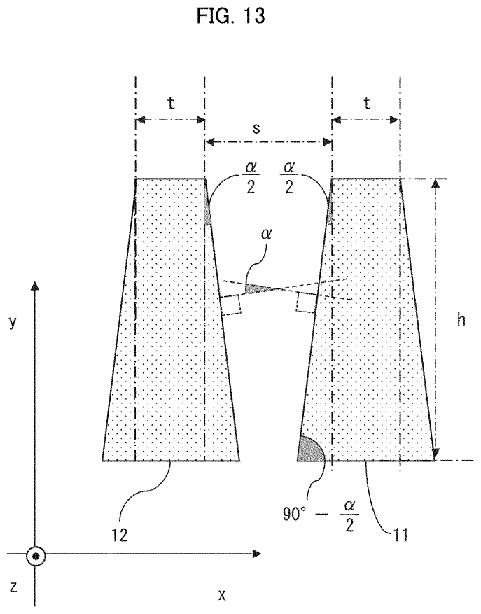

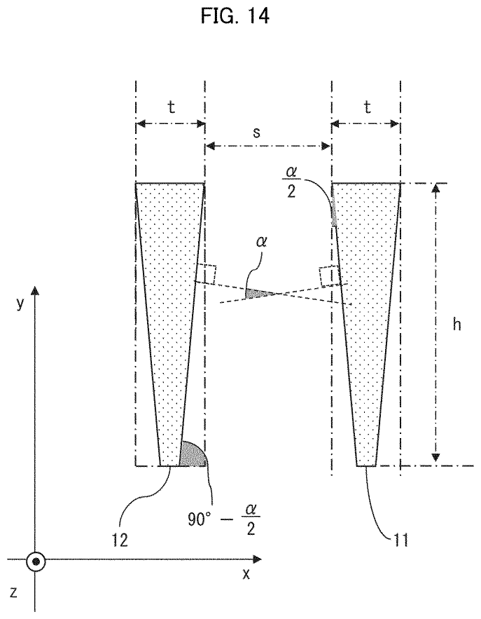

FIGS. 13 and 14 are plan views of an exemplary positional relationship of semiconductor layers in accordance with the embodiment of the present disclosure. FIGS. 13 and 14 show that each of the first semiconductor layer 11 and the second semiconductor layer 12 is an isosceles trapezoid having upper base length t and height h in a plan view, the upper bases being lined up on a straight line with interval s, the first to fourth sidewalls W1 to W4 being oblique sides of the isosceles trapezoid. Referring to FIG. 13, when the upper base is shorter than the lower base, condition expression (4) below holds such that the first sidewall W1 and the second sidewall W2 are separated from each other. Referring to FIG. 14, when the upper base is longer than the lower base, condition expression (5) below holds such that the lower base has a length greater than 0.

$$\begin{matrix}Math . 3 & \\ h \times tan ( \frac{α}{2} ) < \frac{s}{2} & ( 4 )\end{matrix}$$

$$h \times tan ( \frac{α}{2} ) < \frac{t}{2} \qquad ( 5 )$$

Condition expressions (4′) and (5′) below are derived respectively from condition expressions (4) and (5).

$$\begin{matrix}Math . 4 & \\ α < 2 \times {tan}^{- 1} ( \frac{s}{2 \times h} ) & ( {4}^{′} )\end{matrix}$$

$$α < 2 \times {tan}^{- 1} ( \frac{t}{2 \times h} ) \qquad ( {5}^{′} )$$

Referring to FIGS. 1 to 4, the light-emitting device 10 includes: the first light-emitting element D1 including the first light-emitting layer E1; the second light-emitting element D2 including the second light-emitting layer E2; and a third light-emitting element D3 including the third light-emitting layer E3. The light-emitting device 10 includes: a growth substrate SK bonded to the first semiconductor layer 11, the second semiconductor layer 12, and the third semiconductor layer 13; and a driver substrate DK to which the first light-emitting element D1, the second light-emitting element D2, and the third light-emitting element D3 are mounted.

The first light-emitting element D1 includes the first semiconductor layer 11 and further includes an anode A1 and a cathode K1 between the first semiconductor layer 11 and the driver substrate DK. The second light-emitting element D2 includes the second semiconductor layer 12 and further includes an anode A2 and a cathode K2 between the second semiconductor layer 12 and the driver substrate DK. The third light-emitting element D3 includes the third semiconductor layer 13 and further includes an anode A3 and a cathode K3 between the third semiconductor layer 13 and the driver substrate DK. The anodes A1, A2, and A3 and the cathodes K1, K2, and K3 may be made of the same material.

The light-emitting device 10 includes a conductive layer JC electrically connecting each of the anodes A1, A2, and A3 and each of the cathodes K1, K2, and K3 to the driver substrate DK. The conductive layer JC may function also as a bonding material for mechanically bonding the first light-emitting element D1, the second light-emitting element D2, and the third light-emitting element D3 to the driver substrate DK.

The first semiconductor layer 11 includes: an anode contact layer F1 in contact with the anode A1; and a cathode contact layer C1 in contact with the cathode K1. Both the anode contact layer F1 and the cathode contact layer C1 are an n-type semiconductor layer. The first semiconductor layer 11 further includes: a tunnel junction layer T1 between the first light-emitting layer E1 and the anode contact layer F1; a p-type layer H1 between the first light-emitting layer E1 and the tunnel junction layer T1; and an intermediate layer G1 between the first light-emitting layer E1 and the p-type layer H1. The first semiconductor layer 11 further includes: a buffer layer BA in contact with the growth substrate SK; and a base layer U1 between the buffer layer BA and the cathode contact layer C1.

“P-type” indicates that the Fermi level of the semiconductor material is closer to the valence band than the middle of the valence band and the conduction band. P-type semiconductors exhibit hole transportability. “N-type” indicates that the Fermi level of the semiconductor material is closer to the conduction band than the middle of the valence band and the conduction band. N-type semiconductors exhibit electron transportability.

The second semiconductor layer 12 includes: an anode contact layer F2 in contact with the anode A2; and a cathode contact layer C2 in contact with the cathode K2. The anode contact layer F2 and the cathode contact layer C2 are n-type semiconductor layers. The second semiconductor layer 12 further includes: a tunnel junction layer T2 between the second light-emitting layer E2 and the anode contact layer F2; a p-type layer H2 between the second light-emitting layer E2 and the tunnel junction layer T2; and an intermediate layer G2 between the second light-emitting layer E2 and the p-type layer H2. The second semiconductor layer 12 further includes: a buffer layer BA in contact with the growth substrate SK; and a base layer U2 between the buffer layer BA and the cathode contact layer C2.

The second semiconductor layer 12 may include dummy layers made of the same material as the base layer U1, the cathode contact layer C1, the intermediate layer G1, the p-type layer H1, the tunnel junction layer T1, and the anode contact layer F1 respectively.

The third semiconductor layer 13 includes: an anode contact layer F3 in contact with the anode A3; and a cathode contact layer C3 in contact with the cathode K3. The anode contact layer F3 and the cathode contact layer C3 are n-type semiconductor layers. The third semiconductor layer 13 further include: a tunnel junction layer T3 between the third light-emitting layer E3 and the anode contact layer F3; a p-type layer H3 between the third light-emitting layer E3 and the tunnel junction layer T3; and an intermediate layer G3 between the third light-emitting layer E3 and the p-type layer H3. The third semiconductor layer 13 further includes: a buffer layer BA in contact with the growth substrate SK; and a base layer U3 between the buffer layer BA and the cathode contact layer C3.

The third semiconductor layer 13 may include dummy layers made of the same material as the base layer U1, the cathode contact layer C1, the intermediate layer G1, the p-type layer H1, the tunnel junction layer T1, the anode contact layer F1, the base layer U2, the cathode contact layer C2, the intermediate layer G2, the p-type layer H2, the tunnel junction layer T2, and the anode contact layer F2 respectively.

The first semiconductor layer 11, the second semiconductor layer 12 and the third semiconductor layer 13 may each be a gallium-containing nitride semiconductor crystal. The first semiconductor layer 11, the second semiconductor layer 12, and the third semiconductor layer 13 are each bonded to a growth face BS of the growth substrate SK (bottom face in FIGS. 2 to 4), so that the face opposite the growth face BS of the growth substrate SK (top face in FIGS. 2 to 4) is the light-extracting face TS for the light-emitting device 10. The anodes A1, A2, and A3 and the cathodes K1, K2, and K3 preferably exhibit light reflectivity. This light reflectivity enables improving the light extraction efficiency of the light-emitting device 10.

### Light Distribution and Intensity Distribution

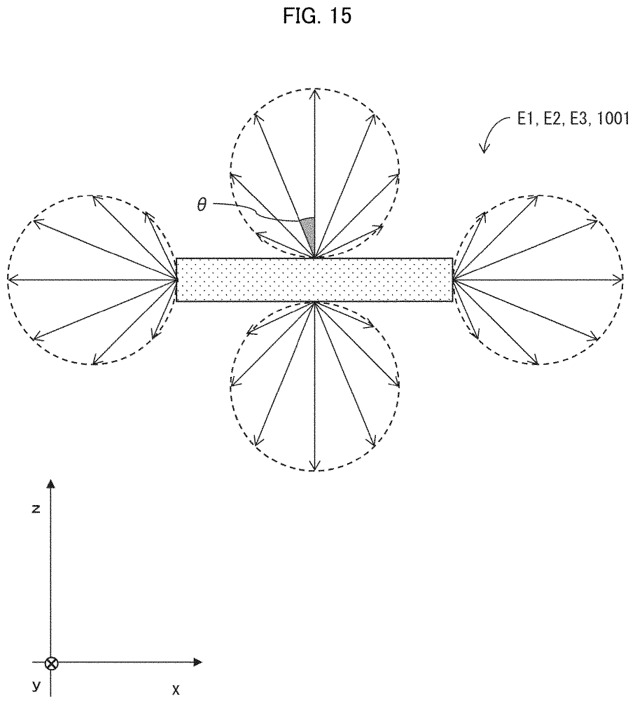

FIG. 15 is an X-direction cross-sectional view representing a light distribution of light exiting a light-emitting layer. Referring to FIG. 15, the light exiting the first light-emitting layer E1, the second light-emitting layer E2, the third light-emitting layer E3, and the light-emitting layer 1001 in accordance with Comparative Example 1 exhibits a Lambertian light distribution regardless of through which face the light exits the layer. In other words, letting the angle of emergence θ be the angle between a normal to the exit face and the exit direction, the light emission intensity is proportional to cosθ.

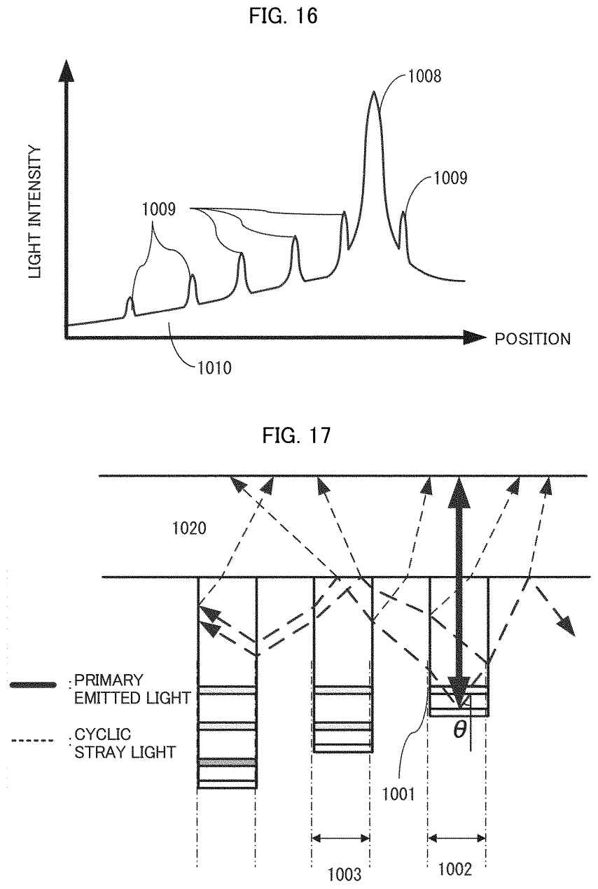

FIG. 16 is a diagram representing an intensity distribution of the light extracted when the light-emitting layer in accordance with Comparative Example 1 shown in FIG. 5 is emitting light. Referring to FIG. 16, an intensity distribution 1007 at a light-extracting face 1006 when the light-emitting layer 1001 in accordance with Comparative Example 1 is emitting light is a sum of a component 1008 resulting from primary emitted light, a component 1009 resulting from cyclic stray light, and a component 1010 resulting from broad stray light.

FIG. 17 is an X-direction cross-sectional view depicting primary emitted light and cyclic stray light in accordance with Comparative Example 1 shown in FIG. 5. Referring to FIG. 17, the light exiting the light-emitting layer 1001 in the direction substantially perpendicular to the light-extracting face provides the primary emitted light. This includes the light exiting at θ≈0° through the top and bottom faces of the light-emitting layer 1001 and the light exiting at θ≈90° through the sidewalls of the light-emitting layer 1001, for example, includes the light exiting at θ≤5° through the top and bottom faces of the light-emitting layer 1001 and the light exiting at 85°≤0 through the sidewalls of the light-emitting layer 1001.

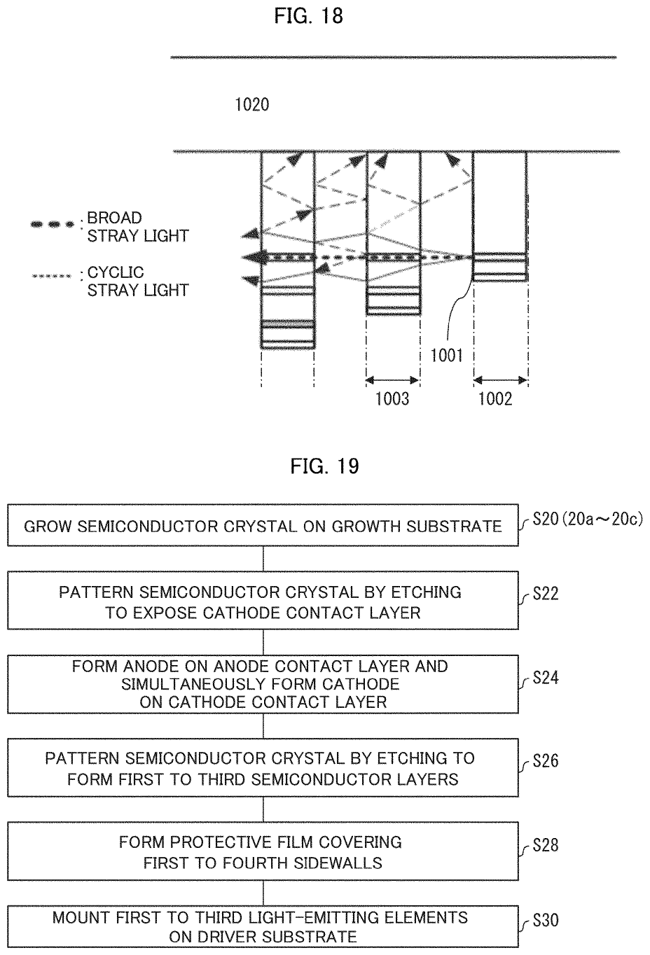

FIG. 18 is an X-direction cross-sectional view depicting broad stray light and cyclic stray light in accordance with Comparative Example 1 shown in FIG. 5. Referring to FIG. 18, the light exiting the light-emitting layer 1001 in the direction substantially parallel to the light-extracting face provides broad stray light. This includes the light exiting at θ≈90° through the top and bottom faces of the light-emitting layer 1001 and the light exiting at θ≈0° through the sidewalls of the light-emitting layer 1001, for example, includes the light exiting at 85°≤θ through the top and bottom faces of the light-emitting layer 1001 and the light exiting at θ≤5° through the sidewalls of the light-emitting layer 1001.

Referring to FIGS. 17 and 18, the light exiting the light-emitting layer 1001 in directions oblique to the light-extracting face provides cyclic stray light. This includes the light exiting at 0°<<θ<<90° through the top face, bottom face, and sidewalls of the light-emitting layer 1001, for example, includes the light exiting at 5°<θ<85° through the top face, bottom face, and sidewalls of the light-emitting layer 1001.

When adjacent sidewalls are parallel to each other as in Comparative Example 1, the light exiting perpendicularly through the sidewall is perpendicularly incident on the other sidewall, hence hardly reflected. Therefore, the light exiting perpendicularly through the sidewalls can propagate over a long distance. In contrast, in the structure in accordance with an embodiment of the present disclosure, the light exiting perpendicularly through the first sidewall W1 is not perpendicularly incident on the second sidewall W2. Since the semiconductor material generally has a greater refractive index than does the atmosphere, the light incident to the atmosphere from the semiconductor material has a large total reflection angle. Therefore, the light not perpendicularly incident to the second semiconductor layer 12 is reflected off the second semiconductor layer 12, hence poorly exiting into the atmosphere. Stray light is thereby reduced.

### Example 1

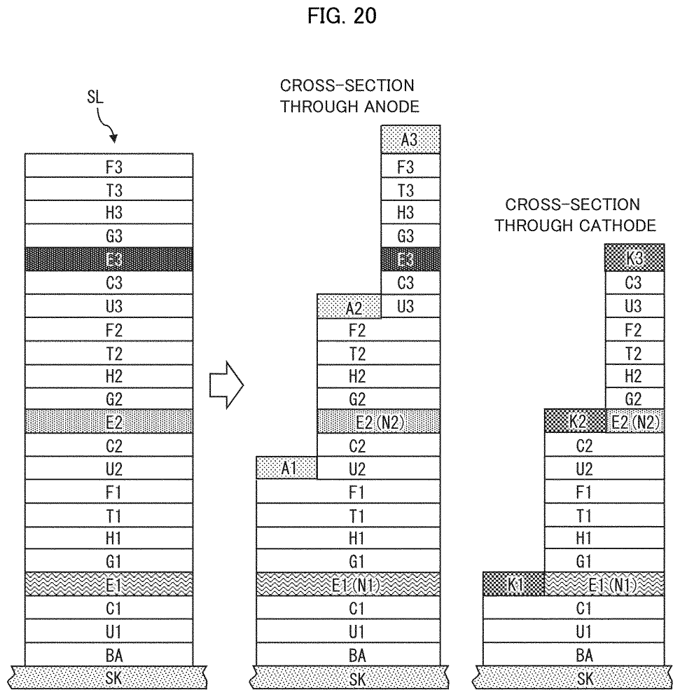

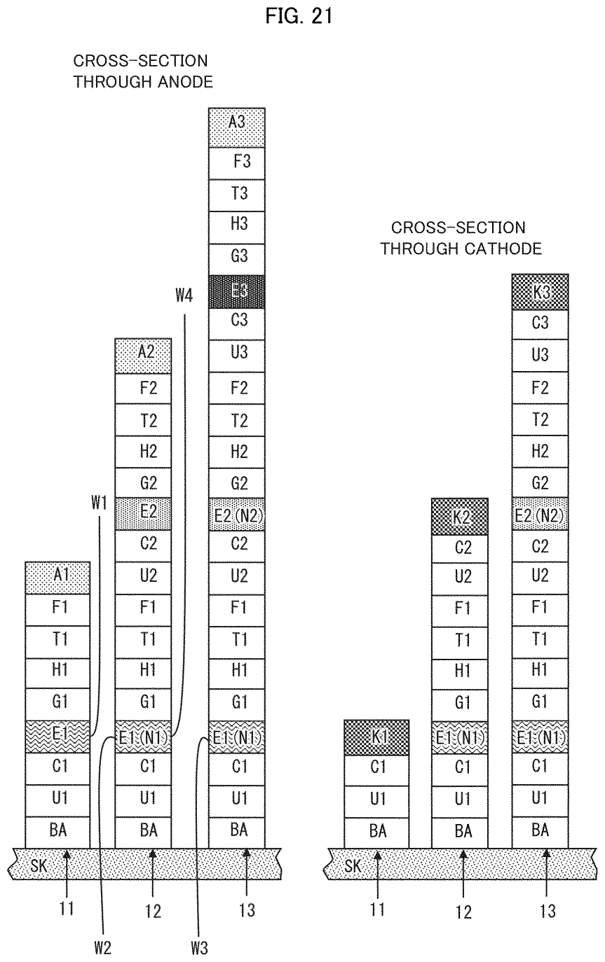

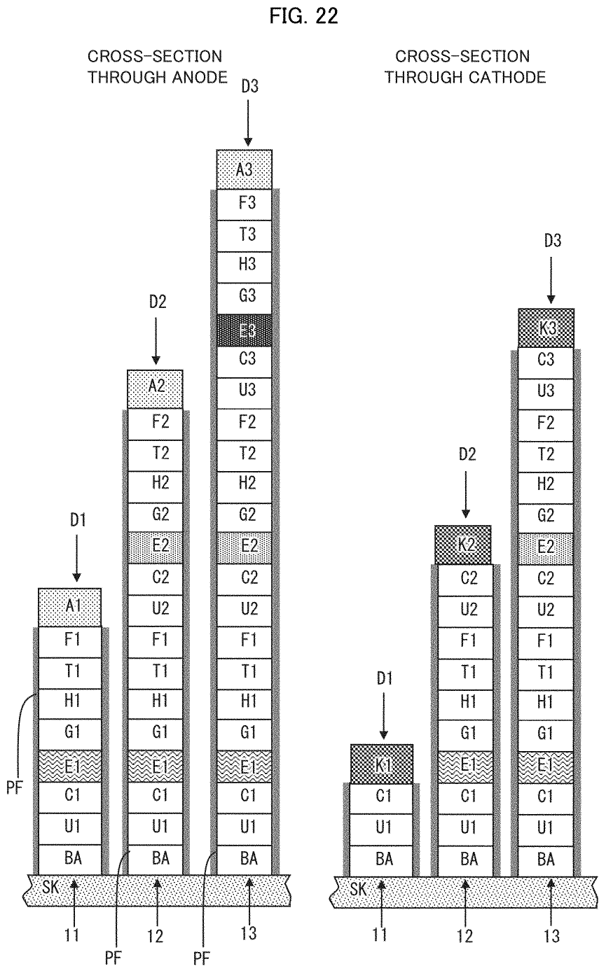

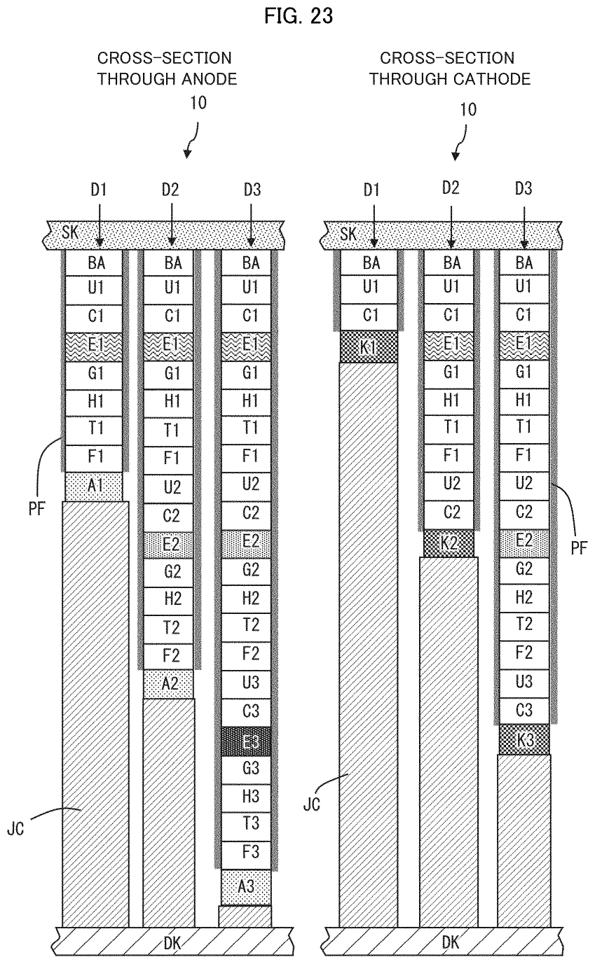

FIG. 19 is a flow chart representing a method of manufacturing a light-emitting device in accordance with Example 1 of the present embodiment. FIGS. 20 to 23 are cross-sectional views of the method of manufacturing the light-emitting device in accordance with Example 1. Referring to FIGS. 20 to 23, in step S20, a semiconductor crystal SL is epitaxially grown on a growth substrate SK (e.g., a C-plane sapphire substrate) using, for example, an MOCVD device. The semiconductor crystal SL may be a nitride semiconductor crystal. Examples of the nitride semiconductor include AlN (aluminum nitride) and InN (indium nitride) as well as GaN-based semiconductors. In the present disclosure, epitaxial growth may be simply referred to as “growth.”

Step S20 involves: step 20a of forming the buffer layer BA, the base layer U1, the cathode contact layer C1, the first light-emitting layer E1, the intermediate layer G1, the p-type layer H1, the tunnel junction layer T1, and the anode contact layer F1, all of which are provided in this order; step 20b of forming the base layer U2, the cathode contact layer C2, the second light-emitting layer E2, the intermediate layer G2, the p-type layer H2, the tunnel junction layer T2, and the anode contact layer F2, all of which are provided in this order; and step 20c of forming the base layer U3, the cathode contact layer C3, the third light-emitting layer E3, the intermediate layer G3, the p-type layer H3, the tunnel junction layer T3, and the anode contact layer F3, all of which are provided in this order. Steps 20a to 20c can be sequentially performed in, for example, an MOCVD device.

The buffer layer BA may be a gallium nitride crystal (e.g., with a thickness of 40 nm) formed at low temperature (e.g., at or below 600° C.). The base layers U1, U2, and U3 may be a non-doped gallium nitride crystal (e.g., with a thickness of 2 μm). The cathode contact layers C1, C2, and C3 may be an n-type gallium nitride crystal (e.g., with a thickness of 2 μm). The first light-emitting layer E1, the second light-emitting layer E2, and the third light-emitting layer E3 may be active layers with an MQW (multiplex quantum well) structure. As an example, the first light-emitting layer E1 that emits blue light of a wavelength of approximately 450 nm may be indium gallium nitride (a mixed crystal with an In—Ga atomic ratio of 1:4) with an In (indium) composition ratio of 20% and a thickness of 50 nm. As an example, the second light-emitting layer E2 that emits green light of a wavelength of approximately 550 nm may be indium gallium nitride (a mixed crystal) with an In composition ratio of 25%. As an example, the third light-emitting layer E3 that emits red light of a wavelength of approximately 630 nm may be indium gallium nitride (a mixed crystal) with an In composition ratio of 30%. The intermediate layers G1, G2, and G3 may be a p-type aluminum gallium nitride crystal (e.g., with a thickness of 20 nm). The p-type layers H1, H2, and H3 may be a p-type gallium nitride crystal (e.g., with a thickness of 120 nm). The tunnel junction layers T1, T2, and T3 may be a non-doped gallium nitride crystal (e.g., with a thickness of 25 nm). The anode contact layers F1, F2, and F3 may be an n-type gallium nitride crystal (e.g., with a thickness of 400 nm).

In step S22, the semiconductor crystal SL is patterned by dry etching to expose the cathode contact layers C1, C2, and C3. An etching mask in step S22 may be either a resist or an inorganic film (e.g., a silicon oxide film or a nickel film) patterned by lift-off. The dry etching may be reactive ion etching (RIE) using a halogen such as chlorine or fluorine. The etching mask is removed using, for example, a remover or an acidic solution.

In step S24, the anodes A1, A2, and A3 are formed on the anode contact layers F1, F2, and F3, and the cathodes K1, K2, and K3 are simultaneously formed on the cathode contact layers C1, C2, and C3. Specifically, an electrode material vapor-deposited using a resist as a mask (e.g., a stack film of aluminum and titanium) is patterned by lift-off.

In step S26, the semiconductor crystal SL is patterned by dry etching to form the first semiconductor layer 11, the second semiconductor layer 12, and the third semiconductor layer 13. In this example, the regions other than the regions in which elements are isolated are protected with a resist, and those portions of the semiconductor crystal SL which are between elements are completely removed by, for example, halogen-based RIE so as to expose the growth substrate SK between the elements. Projections and depressions may be formed on the growth substrate SK by etching the growth substrate SK itself. Electrical element isolation can be done by stopping the etching immediately below the first light-emitting layer E1, the second light-emitting layer E2, and the third light-emitting layer E3. Alternatively, the etching may be performed so as to expose the surface of the growth substrate SK for optical element isolation.

In step S28, the first light-emitting element D1, the second light-emitting element D2, and the third light-emitting element D3 are obtained by forming a protective film PF that covers the first sidewall W1 contained in the first semiconductor layer 11, the second sidewall W2 and the fourth sidewall W4 contained in the second semiconductor layer 12, and the third sidewall W3 contained in the third semiconductor layer 13. In this example, after a mask that covers the anodes A1, A2, and A3 and the cathodes K1, K2, and K3 is formed by, for example, photolithography, silicon oxide that covers the first to fourth sidewalls W1 to W4 is formed by electron beam evaporation, to obtain the protective film PF. The protective film PF has functions of preventing short-circuiting between elements and preventing oxidation.

In step S30, the first light-emitting element D1, the second light-emitting element D2, and the third light-emitting element D3 are mounted to the driver substrate DK via the conductive layer JC, to obtain the light-emitting device 10. The conductive layer JC may be solder or an anisotropic conductive adhesive. The growth substrate SK may be lifted off the first light-emitting element D1, the second light-emitting element D2, and the third light-emitting element D3 by, for example, laser lift-off after the first to third light-emitting elements D1 to D3 are mounted to the driver substrate DK.

Comparative Example 1 includes: a cathode contact layer of an n-type semiconductor and an anode contact layer of a p-type semiconductor. The gallium nitride-based semiconductor has a large bandgap between the valence band and the conduction band. Therefore, in the structure in accordance with Comparative Example 1, the metals suited for use in the cathode and the anode respectively have vastly different work functions, and different metals need to be used. Aluminum and titanium are suited as the cathode, and nickel and gold are suited as the anode. These metals have such different vapor-deposition conditions as to need to be separately vapor-deposited. Therefore, a plurality of insulating layers are needed to form the cathode and the anode, and a plurality of rounds of photolithography for the vapor-deposition mask are needed.

In contrast, the light-emitting device 10 in accordance with Example 1 is structured to tunnel-inject holes from the anodes A1, A2, and A3 to the p-type layers H1, H2, and H3 via the cathode contact layers C1, C2, and C3, which are n-type semiconductor layers, and also via the tunnel junction layers T1, T2, and T3. This particular structure enables forming the anodes A1, A2, and A3 and the cathodes K1, K2, and K3 simultaneously from the same material, which allows for simplification of steps over general techniques where the anodes and cathodes are formed from different materials in different processes. In addition, the p-type (semiconductor) layers, which will readily have their resistance increased in dry etching and machine polishing, do not need to be exposed, so that the light-emitting elements advantageously exhibit stable electrical properties. FIGS. 1 to 5 show the first to third light-emitting elements D1 to D3 being formed monolithically on the growth substrate SK, which is merely illustrative. The first to third light-emitting elements D1 to D3 may be formed individually and mounted to the driver substrate DK.

### Example 2

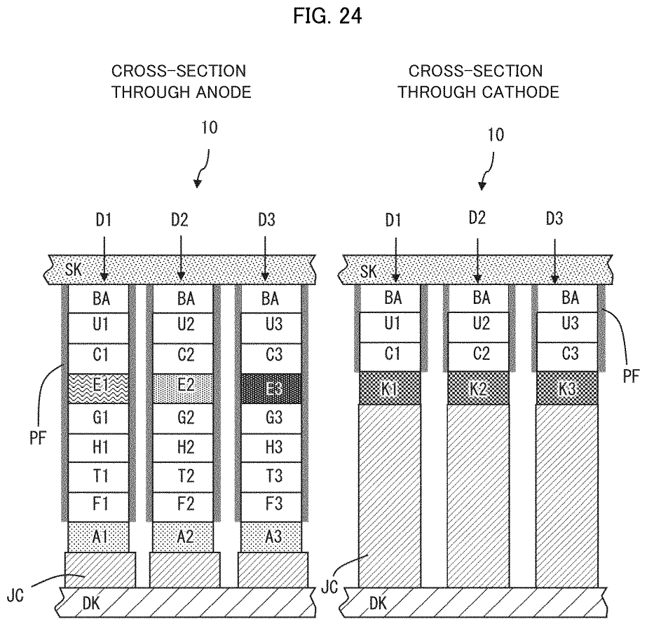

FIG. 24 is a cross-sectional view of a structure of a light-emitting device in accordance with Example 2 of the present embodiment. Referring to FIG. 24, the first light-emitting layer E1, the second light-emitting layer E2, and the third light-emitting layer E3 in accordance with Example 2 are all made of the same material and from the same layer. The base layers U1, U2, and U3, the cathode contact layers C1, C2, and C3, the intermediate layers G1, G2, and G3, the p-type layers H1, H2, and H3, the tunnel junction layers T1, T2, and T3, and the anode contact layers F1, F2, and F3 are also rendered common respectively. The first semiconductor layer 11, the second semiconductor layer 12, and the third semiconductor layer 13 in accordance with Example 2 are arranged so that the acute angles α and β formed by normals can be 2° in a plan view as shown in FIG. 1.

The light-emitting device 10 in accordance with Example 2 further includes a plurality of semiconductor layers arranged so that opposite sidewalls are not parallel.

### Comparative Example 2

A light-emitting device in accordance with Comparative Example 2 is formed in the same manner as the light-emitting device 10 in accordance with Example 2, except that the semiconductor layers are arranged so that opposite sidewalls are parallel.

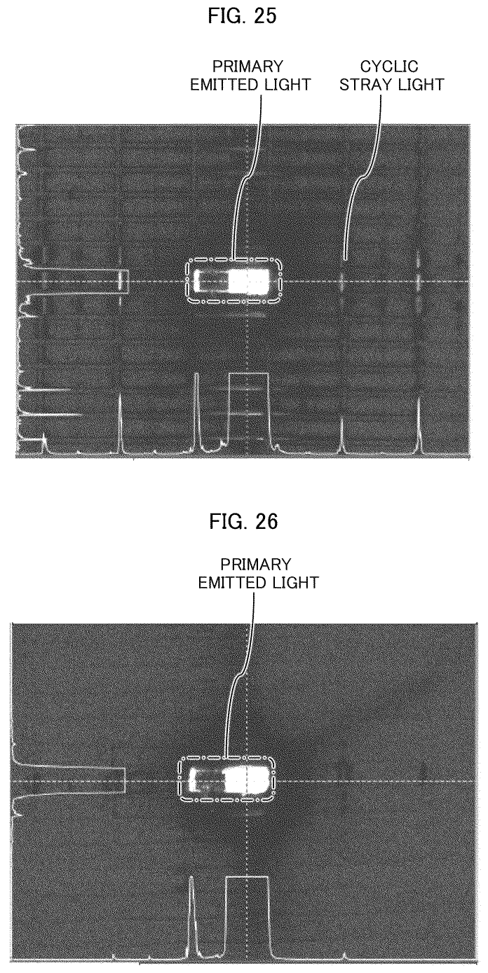

FIG. 25 is a representation of a photograph taken of a glowing one of light-emitting elements in a light-emitting device in accordance with Comparative Example 2, with the light emitted for 30 ms and collected for 300 ms. FIG. 26 is a representation of a photograph taken of a glowing one of light-emitting elements in the light-emitting device in accordance with Example 2, with the light emitted for 30 ms and collected for 300 ms. Referring to FIGS. 25 and 26, components due to cyclic stray light were observed with the light-emitting device in accordance with Comparative Example 2, but not with the light-emitting device 10 in accordance with Example 2. Therefore, it is verified that the structure in accordance with an embodiment of the present disclosure can reduce cyclic stray light.

### Embodiment 2

The following will describe another embodiment of the present disclosure. Note that for convenience of description, members of the present embodiment that have the same function as members of the preceding embodiment are indicated by the same reference numerals, and description thereof is omitted.

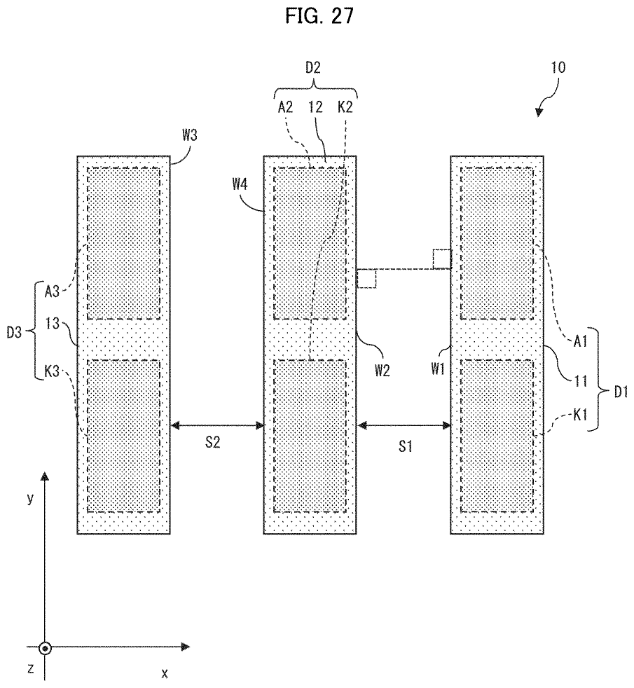

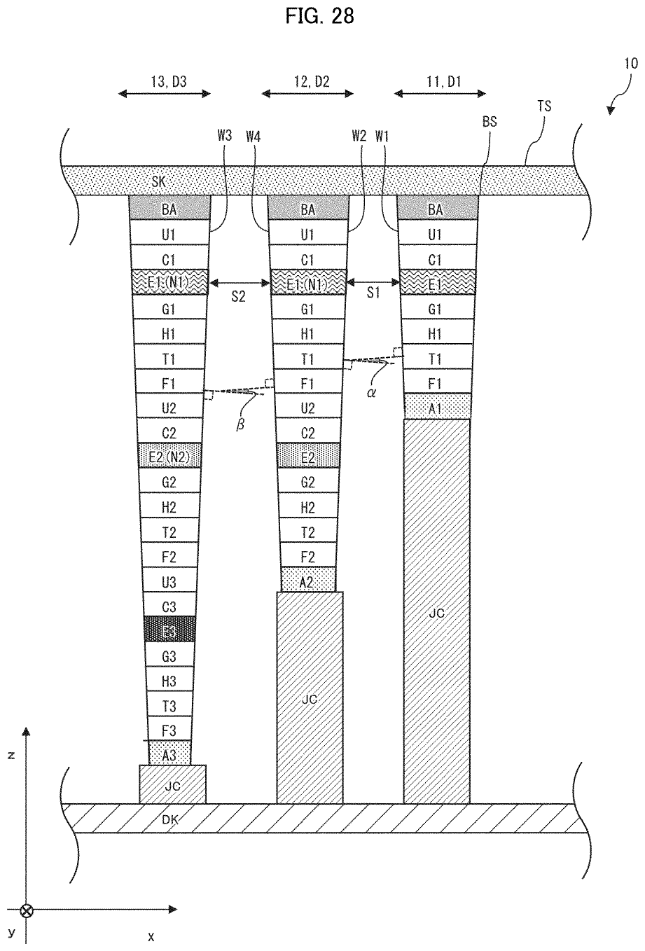

FIG. 27 is a plan view of a light-emitting device in accordance with an embodiment of the present disclosure. FIG. 28 is an X-direction cross-sectional view taken through an anode in a light-emitting device in accordance with an embodiment of the present disclosure. Referring to FIGS. 27 to 28, a normal to the first sidewall W1 is not parallel to a normal to the second sidewall W2 in the cross-sectional view. The distance between the first sidewall W1 and the second sidewall W2 changes with the position along the thickness direction z. Both the first semiconductor layer 11 and the second semiconductor layer 12 are tapered, for example, so as to become thinner with an increase in the distance from the light-extracting face TS. In addition, a normal to the third sidewall W3 is not necessarily parallel to a normal to the fourth sidewall W4 in the cross-sectional view. The distance between the third sidewall W3 and the fourth sidewall W4 changes with the position along the thickness direction z, and the third semiconductor layer 13 is tapered so as to become thinner with an increase in the distance from the light-extracting face TS.

Referring to FIG. 5, to increase the element density, it is generally advantageous that the elements are separated only by narrow gaps and also that the sidewall 1004 and the sidewall 1005 are substantially parallel in the cross-sectional view. Therefore, the sidewall 1004 and the sidewall 1005 are substantially perpendicular to a substrate 1020. Meanwhile, the inventors of the present disclosure have found that it is advantageous that the first sidewall W1 and the second sidewall W2 are not parallel in the cross-sectional view to reduce stray light. Therefore in the structure in accordance with the present embodiment, the first sidewall W1 and the second sidewall W2 are inclined to the growth substrate SK. This structure is realized by specifying a material of an etching mask in step S300 so that the etching selectivity is greater than 1. The selectivity R is defined as being equal to V₁/V₂, where V₁ is the ratio at which the etching mask is etched, and V₂ is the ratio at which the semiconductor crystal SL is etched.

Both acute angles α and β may be less than or equal to 10°. Present Embodiment 2 may be combined with aforementioned Embodiment 1. For example, a normal to the first sidewall W1 may not be parallel to a normal to the second sidewall W2 both in a plan view and in a cross-sectional view.

### Embodiment 3

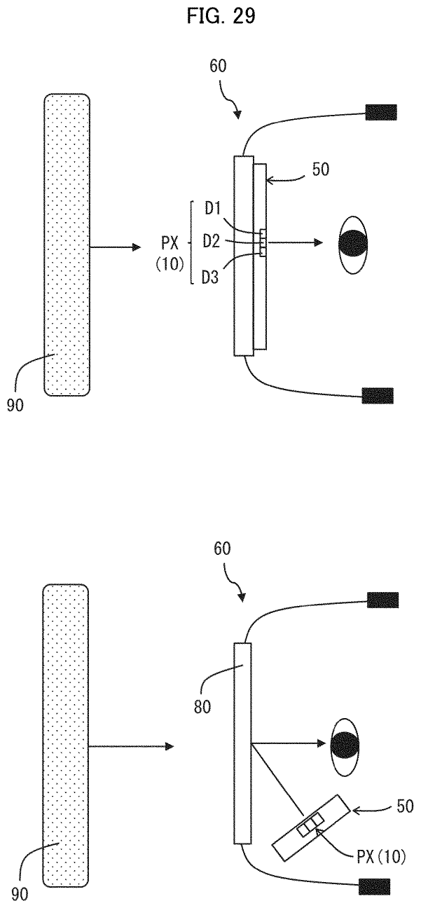

FIG. 29 is a cross-sectional view of an exemplary structure of a display device in accordance with an embodiment of the present disclosure. Referring to FIG. 29, a display device 50 in accordance with an embodiment of the present disclosure includes a light-emitting device 10. The display device 50 includes a plurality of pixels PX, and the pixels PX include, for example, first to third light-emitting elements D1 to D3. Light from the pixel PX may be incident, for example, to the human eye or a sensor either directly or via a projection object 80. A wearable device 60 including the light-emitting device 10 or the display device 50 may be constructed to superimpose an image produced by the display device 50 onto an external world 90.

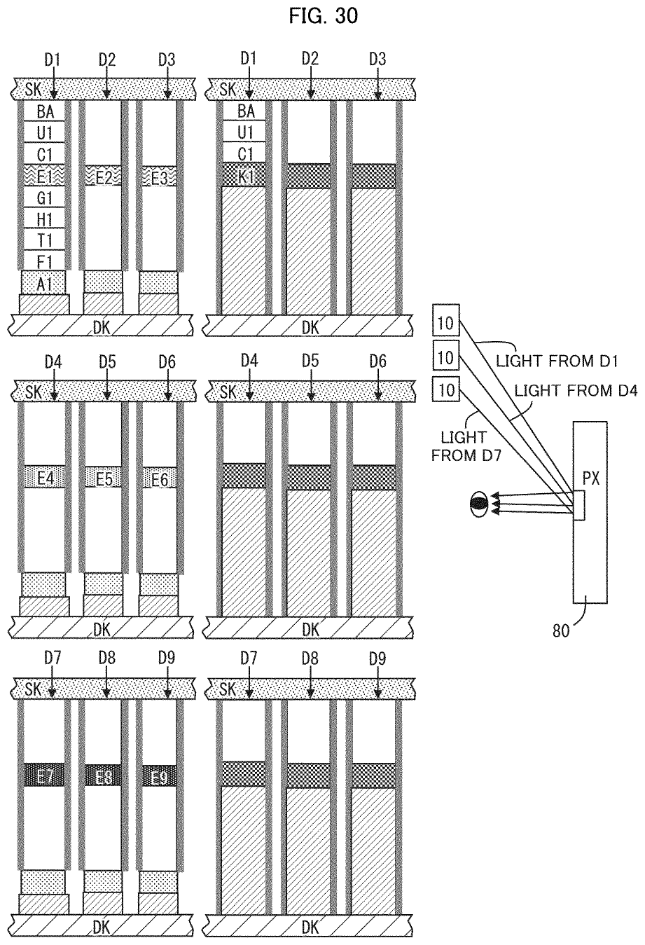

FIG. 30 is a cross-sectional view of an exemplary structure of a display device in accordance with an embodiment of the present disclosure. Referring to FIG. 30, a blue display panel including a light-emitting device 10 that in turn includes the first to third light-emitting elements D1 to D3, a green display panel including a light-emitting device 10 that in turn includes fourth to sixth light-emitting elements D4 to D6, and a red display panel including a light-emitting device 10 that in turn includes fifth to eighth light-emitting elements D5 to D9 may be combined for use in a display device. Multicolor displays can be achieved by superimposing monotonous display panels. Alternatively, light from the first, fourth, and seventh light-emitting elements D1, D4, and D7 may be superimposed at the same pixel PX of the projection object 80.

### Embodiment 4

In recent years, display panels including a plurality of micro LEDs have attracted much attention because these display panels can be applicable to various fields including the augmented reality (AR), the virtual reality (VR), and small to large size display devices.

Japanese Unexamined Patent Application Publication No. 2023-001062 discloses an organic EL display device including a structure body that either absorbs or reflects visible light. The structure body includes: a dome-shaped resin layer provided in a portion between adjacent light-emitting elements; a portion of an organic layer (e.g., an electron injection layer) that is a continuous layer common to the light-emitting elements provided along the shape of the dome-shaped resin layer; and a portion of a common reflective electrode layer.

However, the organic EL display device described in Japanese Unexamined Patent Application Publication No. 2023-001062 includes an organic layer (e.g., an electron injection layer) that is a continuous layer common to the light-emitting elements. Hence, when a subpixel including an ON light-emitting element emits light, the light propagates through the organic layer (e.g., an electron injection layer) that is a continuous layer common to the light-emitting elements, and becomes stray light. A problem is that the stray light inevitably makes an adjacent subpixel, including an OFF light-emitting element, appear to falsefully emit light (i.e., false light).

Furthermore, another problem is that such a common reflective electrode layer, which is a continuous layer common to the light-emitting elements, cannot be provided to a display panel including a plurality of micro LEDs. As a result, it is impossible to form the structure body described in Japanese Unexamined Patent Application Publication No. 2023-001062.

An aspect of the present disclosure sets out to provide a display panel capable of reducing a chance that light emitted from an ON light-emitting element becomes stray light.

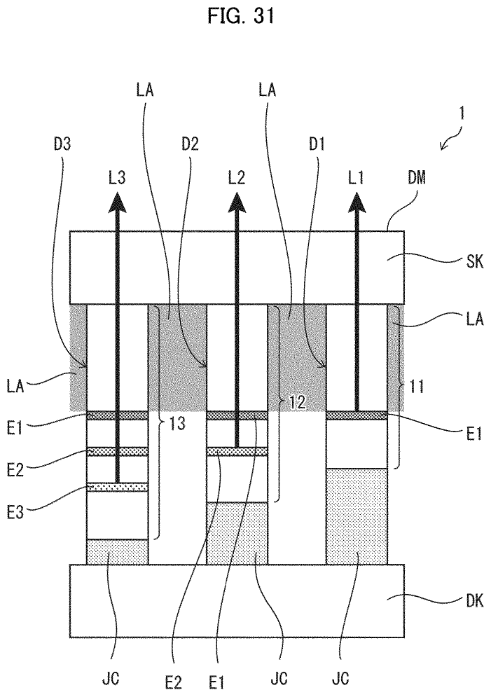

FIG. 31 is a cross-sectional view of a schematic configuration of a display panel 1 according to Embodiment 4. Note that FIG. 31 omits illustrations of anodes A1 to A3, cathodes K1 to K3, and an insulating film PF.

The display panel 1 illustrated in FIG. 31 includes a light-emitting element D1, a light-emitting element D2, and a light-emitting element D3. The light-emitting element D1 includes: an island-shaped multilayer stack 11 including a plurality of semiconductor layers stacked on top of another and including a light-emitting layer E1; the anode A1; and the cathode K1. The light-emitting element D2 includes: an island-shaped multilayer stack 12 including a plurality of semiconductor layers stacked on top of another and including light-emitting layers E1 and E2; the anode A2; and the cathode K2. The light-emitting element D3 includes: an island-shaped multilayer stack 13 including a plurality of semiconductor layers stacked on top of another and including light-emitting layers E1 to E3; the anode A3; and the cathode K3. A light absorber LA is provided between the island-shaped multilayer stacks 11, 12, and 13, respectively included in the light-emitting elements D1, D2, and D3. The light absorber LA contains a material different from a material of the island-shaped multilayer stacks 11 to 13, and absorbs light in a visible light region.

This embodiment exemplifies a case as follows. The light-emitting element (i.e., a first light-emitting element) D1 includes the island-shaped multilayer stack 11 including a plurality of semiconductor layers stacked on top of another and including the light-emitting layer E1 that is a blue light-emitting layer. The light-emitting element D1 serves as a blue light-emitting element in which the light-emitting layer E1 emits a light L1 colored blue. The light-emitting element (i.e., a second light-emitting element) D2 includes the island-shaped multilayer stack 12 including a plurality of semiconductor layers stacked on top of another and including the light-emitting layer E2 that is a green light-emitting layer and the light-emitting layer E1 that does not emit light. The light-emitting element D2 serves as a green light-emitting element in which the light-emitting layer E2 emits a light L2 colored green. The light-emitting element (i.e., a third light-emitting element) D3 includes the island-shaped multilayer stack 13 including a plurality of semiconductor layers stacked on top of another and including the light-emitting layer E3 that is a red light-emitting layer and the light-emitting layers E1 and E2 that do not emit light. The light-emitting element D3 serves as a red light-emitting element in which the light-emitting layer E3 emits a light L3 colored red. However, this embodiment shall not be limited to such a case.

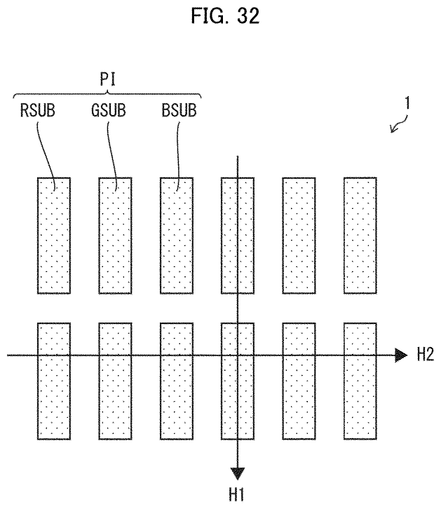

FIG. 32 is a plan view of a display surface SM of the display panel 1 illustrated in FIG. 31.

As illustrated in FIG. 32, this embodiment exemplifies a case as follows. One pixel PI includes: a red subpixel RSUB; a green subpixel GSUB; and a blue subpixel BSUB. The blue subpixel BSUB includes the light-emitting element (i.e., the first light-emitting element) D1 that is a blue light-emitting element. The green subpixel GSUB includes the light-emitting element (i.e., the second light-emitting element) D2 that is a green light-emitting element. The red subpixel RSUB includes the light-emitting element (i.e., the third light emitting element) D3 that is a red light-emitting element. However, this embodiment shall not be limited to such a case. For example, the one pixel PI may further include a subpixel in another color, other than the red subpixel RSUB, the green subpixel GSUB, and the blue subpixel BSUB.

The light-emitting elements D1 to D3 illustrated in FIG. 31 are separated from each other, and can control emission of light on a subpixel-by-subpixel basis illustrated in FIG. 32. This embodiment exemplifies a case of the display panel 1 produced as follows. A plurality of monolithic wafers are produced so that each of which has the plurality of light-emitting elements D1 to D3 provided on a growth substrate SK (e.g., a C-plane sapphire substrate) to emit light in different colors. On a wafer-by-wafer basis, the plurality of wafers are arranged on, and bonded to, a drive substrate DK through a conductive adhesive layer JC to form the display panel 1. However, this embodiment shall not be limited to such a case. For example, as seen in a display panel 2 to be described later in Embodiment 5, a plurality of monolithic wafers may be produced so that each of which has a plurality of the light-emitting elements D1′ provided on the growth substrate SK to emit light in the same color. On a wafer-by-wafer basis, the plurality of wafers may be arranged on, and bonded to, the drive substrate DK through the conductive adhesive layer JC to form the display panel 2. Furthermore, for example, as seen in a display panel 3 to be described later in Embodiment 6, a plurality of chips may be produced so that each of which includes one of the light-emitting element D1′ that is a blue light-emitting element, a light-emitting element D2′ that is a green light-emitting element, or a light-emitting element D3′ that is a red light-emitting element. The plurality of chips may be bonded to one drive substrate DK on a chip-by-chip basis through the conductive adhesive layer JC, and arranged on the one drive substrate DK, to form the display panel 3. Note that the display panels 1, 1a, and 1b to be described in this embodiment and the display panel 3 to be described in Embodiment 6 are display panels including a plurality of light-emitting elements that emit light in different colors. Hence, for example, one such display panel can be used for the augmented reality (AR), the virtual reality (VR), and small to large color display devices. Whereas, the display panels 2 to be described in Embodiment 5 is a monochromatic display panel including a plurality of light-emitting elements that emit light in one color. Hence, for example, three display panels including a red monochromatic display panel, a green monochromatic display panel, and a blue monochromatic display panel, and an optical member such as a mirror, can be used for the augmented reality (AR), the virtual reality (VR), and small to large color display devices.

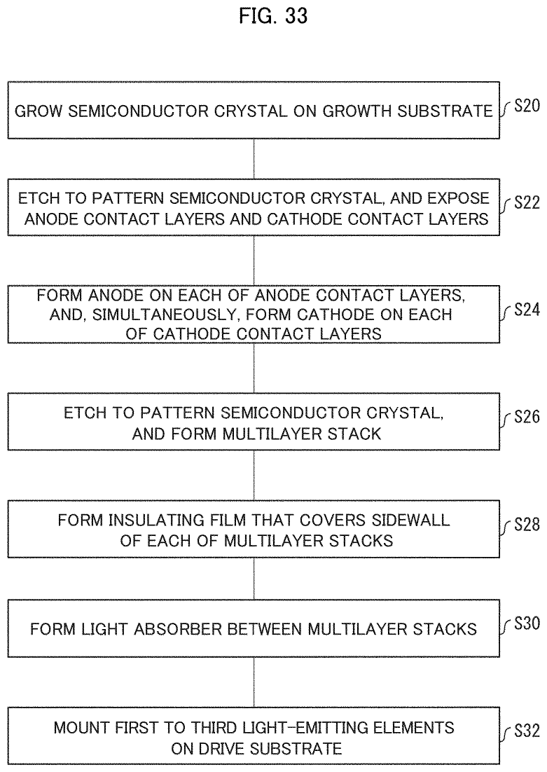

Hereinafter, steps of producing the display panel 1 according to this embodiment will be described, with reference to FIGS. 33 to 37.

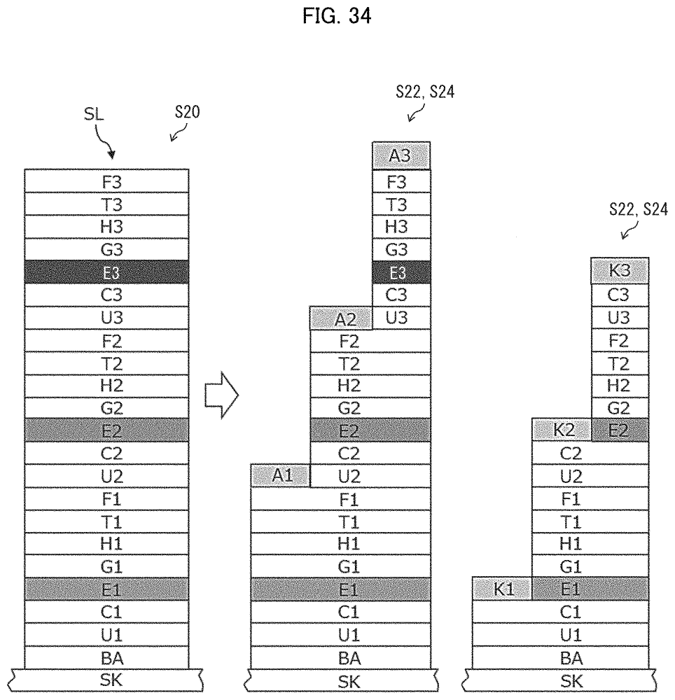

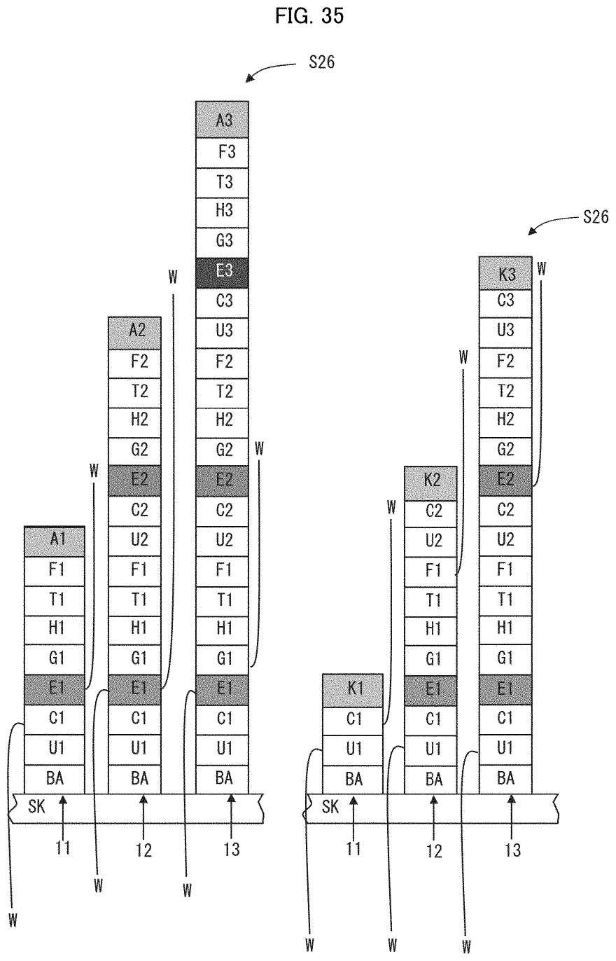

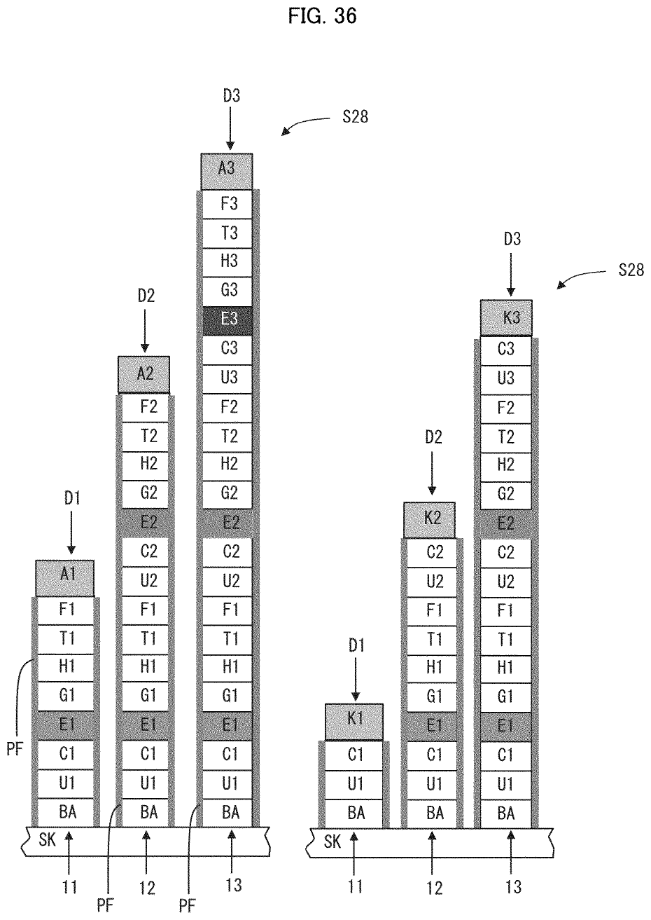

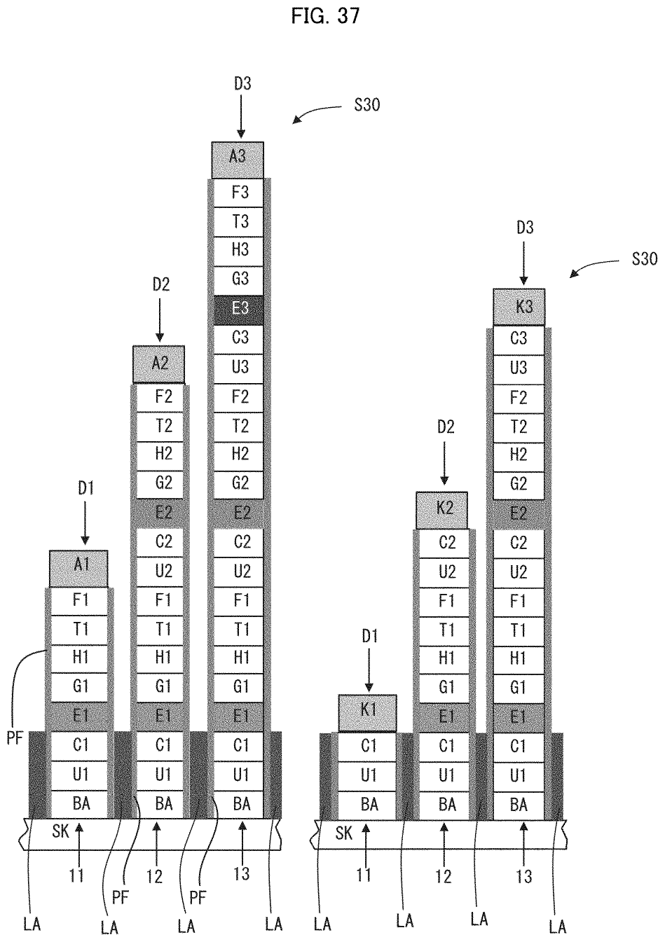

FIG. 33 is a flowchart showing a method for producing the display panel 1 illustrated in FIG. 31. FIG. 34 is a diagram showing Step S20, Step S22, and Step S24 in FIG. 33. FIG. 35 is a diagram showing Step S26 in FIG. 33. FIG. 36 is a diagram showing Step S28 in FIG. 33. FIG. 37 is a diagram showing Step S30 in FIG. 33.

Step S20 in FIG. 33 involves “growing a semiconductor crystal on a growth substrate”. As illustrated in FIG. 34, a semiconductor crystal SL is epitaxially grown on the growth substrate SK (e.g., a C-plane sapphire substrate), using such an apparatus as an MOCVD apparatus. The semiconductor crystal SL may be, for example, a nitride semiconductor crystal. Examples of the nitride semiconductor crystal may include GaN-based semiconductor, and additionally include aluminum nitride (AlN) and indium nitride (InN).

As illustrated in FIG. 34, Step S20 of forming the semiconductor crystal SL includes: a first step of forming a buffer layer BA, an underlayer U1, a cathode contact layer C1, the light-emitting layer E1, a middle layer G1, a p-type layer H1, a tunnel junction layer T1, and an anode contact layer F1 in the stated order; a second step of forming an underlayer U2, a cathode contact layer C2, the light-emitting layer E2, a middle layer G2, a p-type layer H2, a tunnel junction layer T2, and an anode contact layer F2 in the stated order; and a third step of forming an underlayer U3, a cathode contact layer C3, the light-emitting layer E3, a middle layer G3, a p-type layer H3, a tunnel junction layer T3, and an anode contact layer F3 in the stated order. Each of the first to third steps described above can be sequentially carried out in, for example, the MOCVD apparatus.

The buffer layer BA may be a gallium nitride crystal (e.g., 40 nm thick) formed at a low temperature (e.g., 600° C. or below). The underlayers U1, U2, and U3 may be non-doped gallium nitride crystals (e.g., 2 μm thick). The cathode contact layers C1, C2, and C3 may be n-type gallium nitride crystals (e.g., 2 μm thick). The light-emitting layers E1, E2, and E3 may be active layers having a multiple quantum well (MQW) structure. For example, the light-emitting layer E1 that emits a blue light having a wavelength of approximately 450 nm may be formed of indium gallium nitride (i.e., a mixed crystal containing In and Ga at an atomic ratio of 1 to 4) having a thickness of 50 nm and containing indium (In) at a composition rate of 20%. For example, the light-emitting layer E2 that emits a green light having a wavelength of approximately 550 nm may be formed of indium gallium nitride (i.e., a mixed crystal) containing In at a composition rate of 25%. For example, the light-emitting layer E3 that emits a red light having a wavelength of approximately 630 nm may be formed of indium gallium nitride (i.e., a mixed crystal) containing In at a composition rate of 30%. The middle layers G1, G2, and G3 may be p-type aluminum gallium nitride crystals (e.g., 20 nm thick). The p-type layers H1, H2, and H3 may be p-type gallium nitride crystals (e.g., 120 nm thick). The tunnel junction layers T1, T2, and T3 may be non-doped gallium nitride crystals (e.g., 25 nm thick). The anode contact layers F1, F2, and F3 may be n-type gallium nitride crystals (e.g., 400 μm thick).

Step S22 in FIG. 33 involves “etching to pattern the semiconductor crystal, and exposing the anode contact layers and the cathode contact layers”. As illustrated in FIG. 34, the semiconductor crystal SL is dry-etched and patterned, and the cathode contact layers C1, C2, and C3 and the anode contact layers F1, F2, and F3 are exposed. At this step, a resist or an inorganic film (e.g., a silicon oxide film or a nickel film) patterned by liftoff can be used as an etching mask. The dry etching may be reactive ion etching (RIE) using a halogen such as chlorine or fluorine. Note that the etching mask is removed by, for example, a remover or an acid solution.

Step S24 in FIG. 33 involves “forming an anode on each of the anode contact layers, and, simultaneously, forming a cathode on each of the cathode contact layers”. As illustrated in FIG. 34, the anodes A1, A2, and A3 are respectively formed on the anode contact layers F1, F2, and F3, and, simultaneously, the cathodes K1, K2, and K3 are respectively formed on the cathode contact layers C1, C2, and C3. Specifically, an electrode material (e.g., a multilayer film of aluminum and titanium), which is vapor-deposited using a resist as a mask, is patterned by liftoff.

Step S26 in FIG. 33 involves “etching to pattern the semiconductor crystal, and forming a multilayer stack”. As illustrated in FIG. 35, the semiconductor crystal SL is dry-etched and patterned to form the island-shaped multilayer stack 11, the island-shaped multilayer stack 12, and the island-shaped multilayer stack 13. Here, the semiconductor crystal SL except for regions separated as the elements from one another is protected with a resist, and a portion included in the semiconductor crystal SL and found between the elements is completely removed by, for example, halogen-based RIE, so that the growth substrate SK is exposed between the elements. The growth substrate SK itself may be etched to have asperities. In this embodiment, in order to electrically and optically separate the elements excellently from one another, the semiconductor crystal SL is etched so that the surface of the growth substrate SK is exposed, and the island-shaped multilayer stacks 11, 12, and 13 are formed on the growth substrate SK. Note that each of the island-shaped multilayer stacks 11, 12, and 13 has a sidewall W.

Step S28 in FIG. 33 involves “forming an insulating film that covers the sidewall of each of the multilayer stacks”. As illustrated in FIG. 36, an insulating film PF is formed to cover the sidewall W of each of the island-shaped multilayer stack 11, the island-shaped multilayer stack 12, and the island-shaped multilayer stack 13. Hence, the light-emitting elements D1, D2, and D3 are formed. Here, a mask is formed by, for example, photolithography to cover the anodes A1, A2, and A3, and the cathodes K1, K2, and K3. After that, silicon oxide is formed by electron-beam evaporation to cover the sidewall W and serve as the insulating film PF. The insulating film PF has a function of preventing short-circuit between, and oxidation of, the elements. This embodiment exemplifies a case where the insulating film PF is a silicon oxide film. However, this embodiment shall not be limited to such a case, and the insulating film PF may include any one of a silicon oxide film, a silicon nitride film, a silicon oxynitride film, and an aluminum oxide film. Furthermore, the insulating film PF is formed to have a thickness of preferably 3 nm or more and 100 nm or less in a direction perpendicular to the sidewalls W of the island-shaped multilayer stacks 11, 12, and 13. As described in this embodiment, in a case where the insulating film PF is formed to cover the sidewall W of each of the island-shaped multilayer stacks 11, 12, and 13, the light absorber LA to be described later can be made of a wide variety of materials. That is, if the insulating film PF is formed, a conductive material may be selected as the material of the light absorber LA. Note that if a highly insulating material is selected as the material of the light absorber LA, above Step S28 in FIG. 33 may be omitted.

Step S30 in FIG. 33 involves “forming the light absorber between the multilayer stacks”. As illustrated in FIGS. 31 and 37, the light absorber LA may be formed, for example, as high as, or lower than, a thickness between a surface, of the buffer layer BA, toward the display surface DM and a surface, of the light-emitting layer E1, toward the display surface DM. The buffer layer BA is a semiconductor layer closest from the display surface DM that releases light emitted from the light-emitting layers E1, E2, and E3. The light-emitting layer E1 is closest from the display surface DM. This embodiment exemplifies a case where the light absorber LA is formed as high as a thickness between the surface, of the buffer layer BA, toward the display surface DM and the surface, of the light-emitting layer E1, toward the display surface DM. However, this embodiment shall not be limited to such a case.

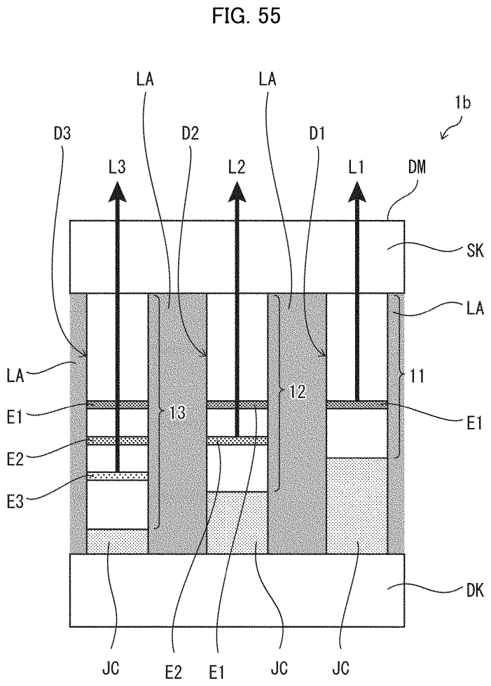

FIG. 54 is a cross-sectional view of a schematic configuration of another display panel 1a according to Embodiment 4. FIG. 55 is a cross-sectional view of a schematic configuration of still another display panel 1b according to Embodiment 4. The display panel 1a illustrated in FIG. 54 includes the light-emitting element D1, the light-emitting element D2, and the light-emitting element D3. The light-emitting element D1 includes, as the island-shaped multilayer stack 11, a first multilayer stack (the buffer layer BA, the underlayer U1, the cathode contact layer C1, the light-emitting layer E1, the middle layer G1, the p-type layer H1, the tunnel junction layer T1, and the anode contact layer F1) including the light-emitting layer E1. The light-emitting element D2 includes, as the island-shaped multilayer stack 12, the first multilayer stack and a second multilayer stack (the underlayer U2, the cathode contact layer C2, the light-emitting layer E2, the middle layer G2, the p-type layer H2, the tunnel junction layer T2, and the anode contact layer F2). The second multilayer stack includes the light-emitting layer E2 provided further from the display surface DM than the first multilayer stack. The light-emitting element D3 includes, as the island-shaped multilayer stack 13, the first multilayer stack, the second multilayer stack, and a third multilayer stack (the underlayer U3, the cathode contact layer C3, the light-emitting layer E3, the middle layer G3, the p-type layer H3, the tunnel junction layer T3, and the anode contact layer F3). The third multilayer stack includes the light-emitting layer E3 provided further from the display surface DM than the second multilayer stack. Then, the light absorber LA may be formed as high as, or lower than, a thickness between a surface, of the buffer layer BA, toward the DM and a surface, of the light-emitting layer E3, toward the display surface DM. The buffer layer BA is a semiconductor layer closest from the display surface DM. In the display panel 1a, the light absorber LA is formed as high as a thickness between the surface, of the buffer layer BA, toward the display surface DM and the surface, of the light-emitting layer E3, toward the display surface DM. The buffer layer BA is a semiconductor layer closest from the display surface DM. However, this embodiment shall not be limited to such configurations. As seen in the display panel 1b illustrated in FIG. 55, the light absorber LA may be charged to completely fill intervals between the island-shaped multilayer stacks 11, 12, 13 respectively included in the plurality of the light-emitting elements D1, D2, D3.

The light absorber LA may be formed of either an organic compound or an inorganic compound having a molecular structure including, for example, a pyridine skeleton. In this embodiment, the light absorber LA is an insulating compound; that is, for example, a black dye (trade name: N749, substance name: Ruthenium 620, tris(N,N,N-tributyl-1-butanaminium)[[2,2″6′,2″-terpyridine]-4,4′,4″-tricarboxylato(3-)-N1,N1′,N1″]tris(thiocyanato-N)hydrogen ruthenate(4-)). The black dye is represented below (by Chemical Formula 1). The black dye represented below (by Chemical Formula 1) has a molar absorbance of 3×10⁻³ to 7×10⁻³ (1/M·cm) in the visible region. The black dye represented below (by Chemical Formula 1) has a molecule structure including three pyridine skeletons with nitride and a plurality of functional groups bonding thereto. Note that, as seen in this embodiment, if an organic compound is used as the light absorber LA, even if the anodes A1, A2, A3 and the cathodes K1, K2, K3 are covered with the light absorber LA at the steps, ashing is performed with the surface of the elements protected with a metal mask having openings for the anodes A1, A2, and A3, and the cathodes K1, K2, and K3. The ashing can oxidize and remove the light absorber LA on the anodes A1, A2, A3 and the cathodes K1, K2, K3.

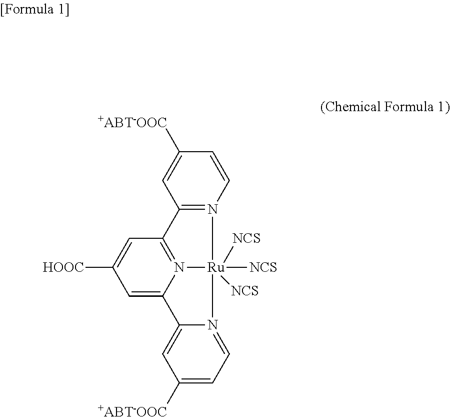

The light absorber LA may contain one or more selected from the group consisting of a modified acrylic-based resin, an epoxy-based resin, a urethane-based resin, a cyanoacrylate-based resin, a fluoroethylene-based resin, a silicone-based resin, polyvinyl alcohol (PVA), and polyvinyl chloride (PVC). Furthermore, the light absorber LA may contain one or more selected from the group consisting of an azo-based dye, a quinone-based dye, an indigo-based dye, a polymethine-based dye, a styryl-based dye, an azo-based pigment, a quinone-based pigment, an indigo-based pigment, a polymethine-based pigment, and a styryl-based pigment. Moreover, the light absorber LA may contain one or more selected from the group consisting of a carbon material, a metal sulfide, and a semiconductor material that absorbs light in a visible light region.

Step S32 in FIG. 33 involves “mounting the light-emitting elements (the first to third light-emitting elements) on the drive substrate”. As illustrated in FIG. 31, the light-emitting elements D1, D2, and D3 are mounted on the drive substrate DK, including the drive circuit, through the conductive adhesive layer JC. Hence, the display panel 1 is obtained. The conductive adhesive layer JC can be formed of solder or an anisotropic conductive adhesive. In the display panel 1 illustrated in FIGS. 31 and 37, holes of the anodes A1, A2, and A3 are tunnel-injected into the p-type layers H1, H2, and H3 through the anode contact layers F1, F2, and F3, which are n-type semiconductor layers, and the tunnel junction layers T1, T2, and T3. Thanks to such a configuration, the anodes A1, A2, A3 and the cathodes K1, K2, K3 can be formed simultaneously of the same material. The configuration simplifies the steps compared with a typical technique of forming the anodes and the cathodes in different processes with different materials. Furthermore, the configuration reduces the risk of exposing the p-type (semiconductor) layers, which are likely to have high resistance, by dry etching and mechanical polishing. Such a feature provides the light-emitting elements with an advantageous effect of a stable electric characteristic. Note that after Step S32 shown in FIG. 33, such a technique as laser liftoff is used to carry out a step of delaminating and removing the growth substrate SK from the island-shaped multilayer stack 11, the island-shaped multilayer stack 12, the island-shaped multilayer stack 13, the insulating film PF, and the light absorber LA.

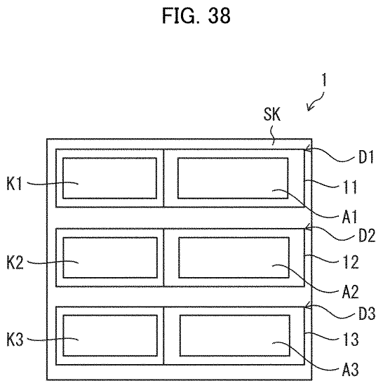

FIG. 38 is a plan view of a wafer after Step S30 shown in FIG. 33 and before Step S32 shown in FIG. 33, the wafer being viewed from toward an anode and a cathode.

As illustrated in FIG. 38, this embodiment exemplifies a case where the island-shaped multilayer stack 11 included the light-emitting element D1, the island-shaped multilayer stack 12 included in the light-emitting element D2, and the island-shaped multilayer stack 13 included in the light-emitting element D3 each have a size of 20 μm×120 μm in plan view, and where the island-shaped multilayer stacks 11, 12, and 13 are separated from each other by 10 μm. However, this embodiment shall not be limited to such a case.

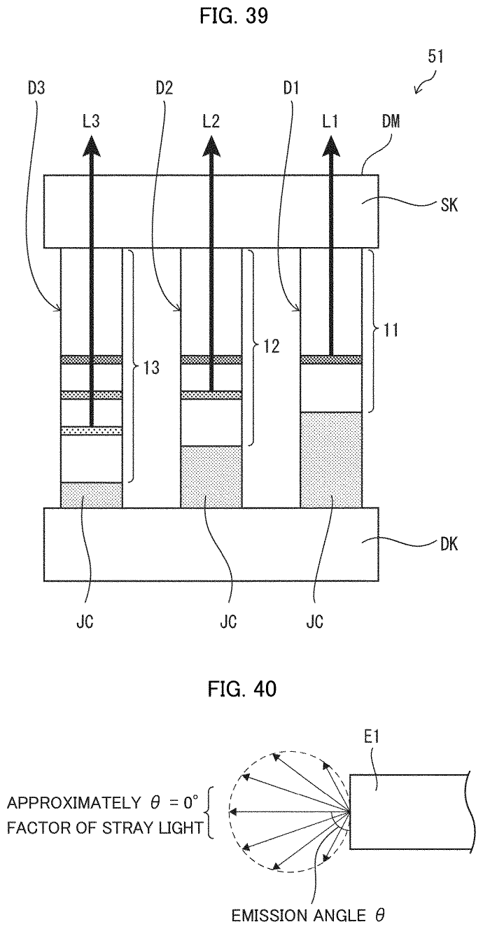

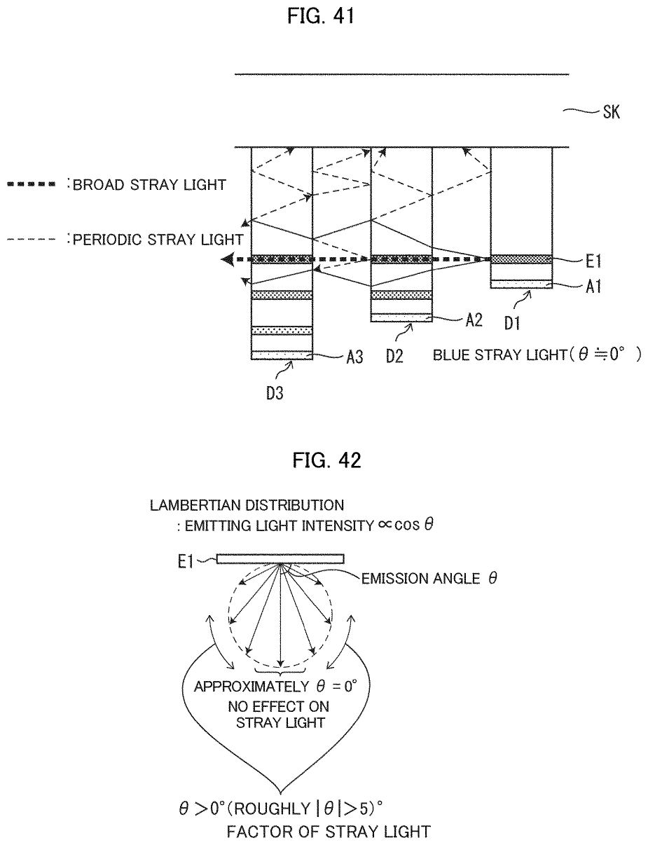

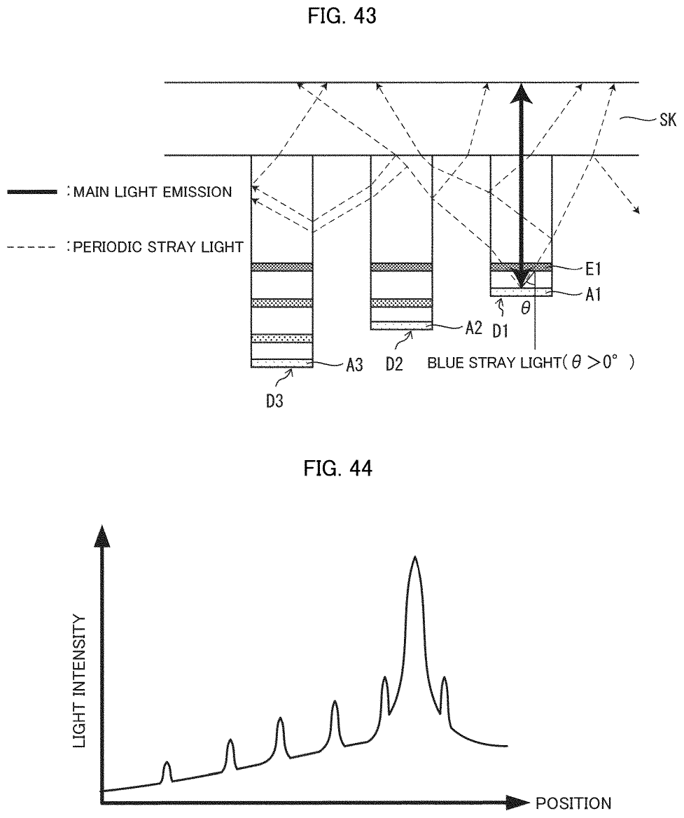

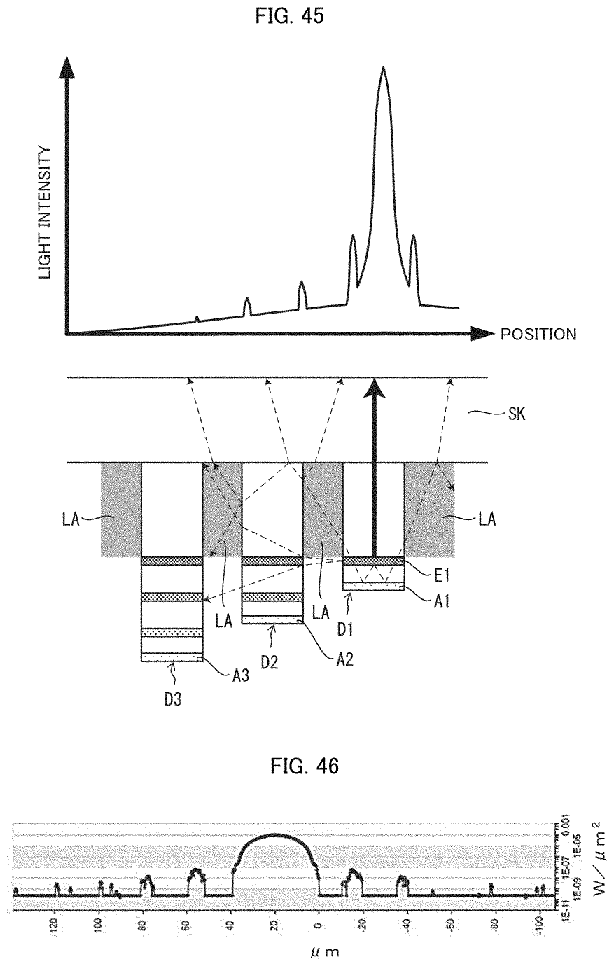

FIG. 39 is a cross-sectional view of a schematic configuration of a display panel 51 according to Comparative Example 4. FIG. 40 is a diagram showing a factor why the display panel 1 according to Embodiment 4 and the display panel 51 according to Comparative Example 4 produce stray light. FIG. 41 is a diagram showing a case where, in the display panel 51 according to Comparative Example 4, how the stray light produced by the factor illustrated in FIG. 40 makes an adjacent subpixel, including an OFF light-emitting element, appear to falsefully emit light. FIG. 42 is a diagram showing another factor why the display panel 1 according to Embodiment 4 and the display panel 51 according to Comparative Example 4 produce stray light. FIG. 43 is a diagram showing a case where, in the display panel 51 according to Comparative Example 4, how the stray light produced by the factor illustrated in FIG. 42 makes an adjacent subpixel, including an OFF light-emitting element, appear to falsefully emit light. FIG. 44 is a graph showing a distribution of stray light in the display panel 51 according to Comparative Example 4. FIG. 45 shows a graph showing a distribution of stray light in the display panel 1 according to Embodiment 4 and a diagram showing why light emitted from an ON light-emitting element can be kept from becoming stray light in the display panel 1 according to Embodiment 4.

The display panel 51 of Comparative Example 4 illustrated in FIG. 39 differs from the display panel 1 of Embodiment 4 only in that the display panel 51 omits the light absorber LA. As illustrated in FIGS. 40 and 41, in the display panel 1 of Embodiment 4 and the display panel 51 of Comparative Example 4, among the light rays emitted from end faces of the light-emitting layers E1, E2, and E3, a light component propagating in a lateral direction toward an adjacent subpixel could be one of the factors that produces stray light. As illustrated in FIG. 40, the light rays emitted from the end faces of the light-emitting layers E1, E2, and E3 can be divided into light components having an emission angle θ of 0° or approximately 0° (less than plus or minus) 5° and light components having an emission angle θ of greater than plus or minus 5°. As illustrated in FIG. 41, a light component having an emission angle θ of 0° or approximately 0° (less than plus or minus) 5° is a component that is incident perpendicularly on the sidewall of the adjacent subpixel. This component is hardly reflected on element/atmosphere and atmosphere/element interfaces, and undergoes attenuation and propagates for a relatively long distance, and becomes a broad stray light having no clear peak. The attenuation is caused by a semiconductor included in an element; particularly, by the light-emitting layer and the p-type layer. Whereas, some of the light components having an emission angle θ greater than plus or minus 5° are reflected on the element/atmosphere and atmosphere/element interfaces, and the rest of the light components transmit and propagate. Reflected light travels toward either the growth substrate SK or the drive substrate DK. However, a component traveling toward the drive substrate DK is absorbed into the drive substrate DK, and hardly becomes stray light. Whereas, a component traveling toward the growth substrate SK becomes stray light periodically forming a peak at the sidewall of the element. As illustrated in FIGS. 42 and 43, in the display panel 1 of Embodiment 4 and the display panel 51 of Comparative Example 4, among the light rays emitted toward the front (toward the drive substrate DK) and the back (toward the growth substrate SK) of the light-emitting layers E1, E2, and E3, the light component whose absolute value of the emission angle θ is greater than 0°, that is, roughly, whose absolute value of the emission angle θ is greater than 5°, is reflected on an electrode toward the front (toward the drive substrate DK), travels out of the element at the same emission angle as the incident angle, and becomes stray light having a periodic peak near the sidewall of the element. Whereas, the light component whose absolute value of the emission angle θ is 0°; that is, roughly, smaller than 5° does not become stray light. As illustrated in FIG. 44, when only the light-emitting element D1 is ON, the display panel 51 of Comparative Example 4 exhibits distribution of the periodic stray light corresponding to an arrangement of, and intervals between, the light-emitting elements D1, D2, and D3. In a display panel, stray light causes a decrease in image quality such as a decrease in contrast, virtual image, and false light.

Hence, the display panel 1 of this embodiment is provided with the above light absorber LA to reduce a chance that the light emitted from an ON light-emitting element becomes stray light. In accordance with FIG. 42, the light component whose absolute value of the emission angle θ is greater than 0°; roughly, whose absolute value of the emission angle θ is greater than 5°; that is, the light component, reflected on an electrode toward the front (toward the drive substrate DK) and traveling out of the element at the same emission angle as the incident angle, is reflected on the electrode toward the front (toward the drive substrate DK) and enters the light absorber LA, as illustrated in FIG. 45. Such a light component is incident at a certain angle in a direction in which the light-emitting elements are stacked, is refracted to change the traveling direction, and is greatly absorbed and attenuated because the light component vertically propagates in the light absorber LA. Furthermore, the stray light reaching an interface between the light absorber LA and an adjacent light-emitting element is reflected and refracted, and further changes the direction, propagates, enters the light absorber LA, and undergoes attenuation before reaching the adjacent light-emitting element. Similarly, in accordance with FIG. 40, the light component having the emission angle θ of 0° or approximately 0° (less than plus or minus) 5° also undergoes attenuation because the light component enters the light absorber LA at a constant angle. As described above, the display panel 1 of this embodiment including the above light absorber LA achieves an advantageous effect of reducing intensity of stray light having a periodic peak because the light absorber LA attenuates and refracts the light component.

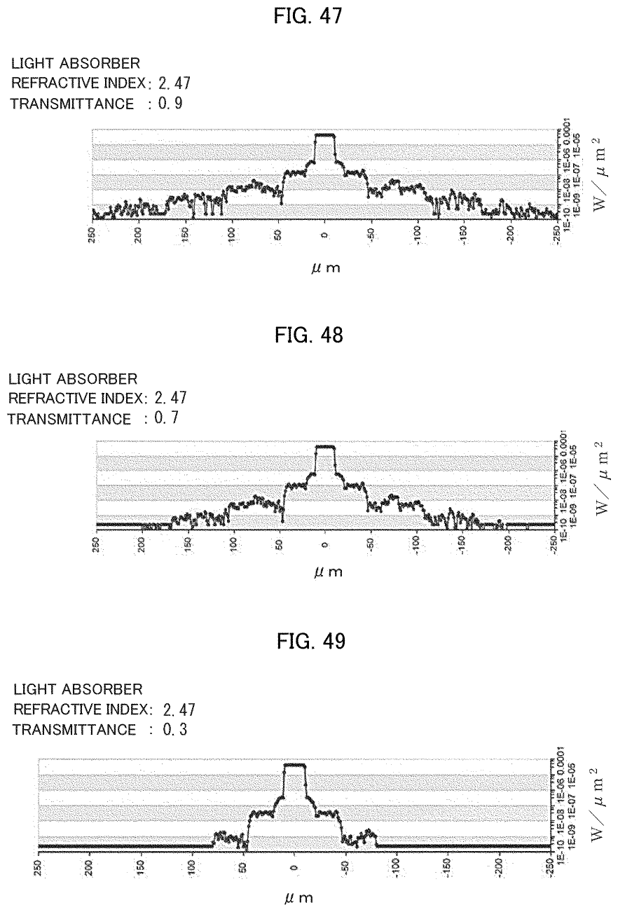

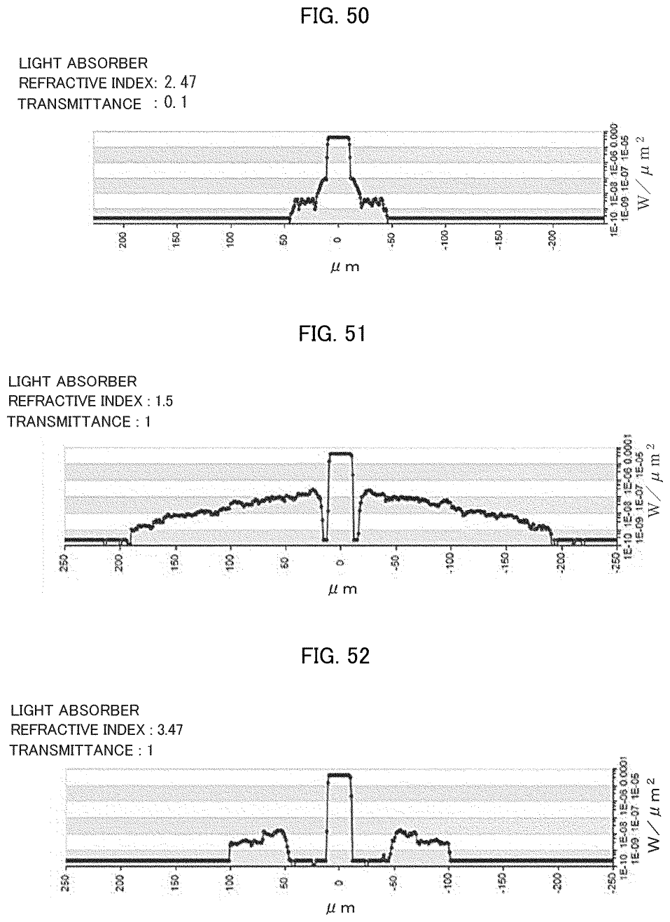

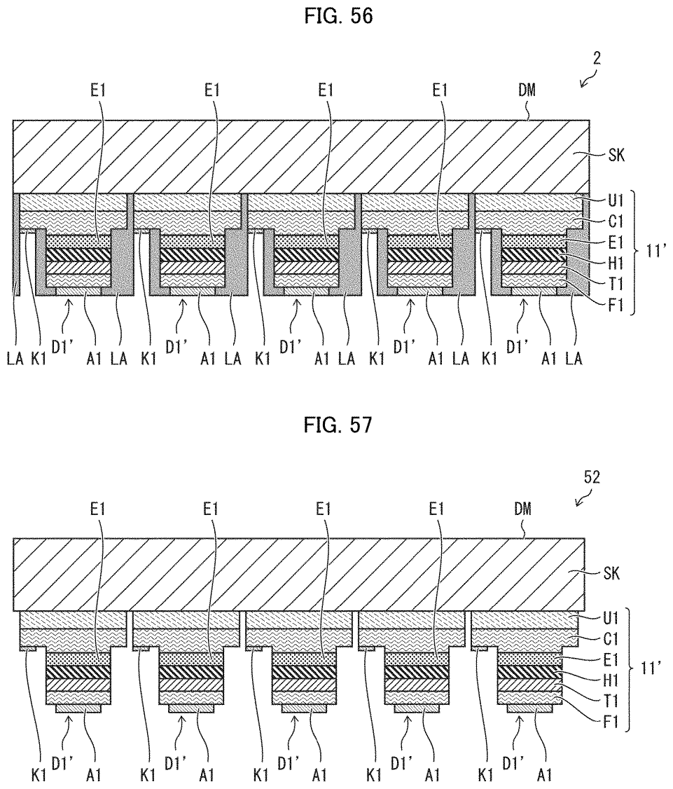

FIG. 46 is a graph showing a distribution of stray light obtained by optical calculation using, as a model, a display panel 52 according to Comparative Example 5 illustrated in FIG. 57. FIG. 47 is a graph showing a stray light distribution obtained by optical calculation using, as a model, the display panel 2 according to Embodiment 5 illustrated in FIG. 56, the display panel 2 including the light absorber LA having a refractive index of 2.47 and a transmittance of 0.9. FIG. 48 is a graph showing a stray light distribution obtained by optical calculation using, as a model, the display panel 2 according to Embodiment 5 illustrated in FIG. 56, the display panel 2 including the light absorber LA having a refractive index of 2.47 and a transmittance of 0.7. FIG. 49 is a graph showing a stray light distribution obtained by optical calculation using, as a model, the display panel 2 of Embodiment 5 illustrated in FIG. 56, the display panel 2 including the light absorber LA having a refractive index of 2.47 and a transmittance of 0.3. FIG. 50 is a graph showing a stray light distribution obtained by optical calculation using, as a model, the display panel 2 of Embodiment 5 illustrated in FIG. 56, the display panel 2 including the light absorber LA having a refractive index of 2.47 and a transmittance of 0.1.

Here, the display panel 52 of Comparative Example 5 in FIG. 57 and the display panel 2 of Embodiment 5 in FIG. 56 are introduced as optical models. The optical calculation obtains examples of the refractive indexes and the transmittances of the light absorber LA having advantageous effects.

FIG. 46 shows a stray light distribution obtained by optical calculation, using, as a model, the display panel 52 of Comparative Example 5 illustrated in FIG. 57 and omitting the light absorber LA. The stray light distribution shows a spiked peak at the sidewall of the light-emitting element D1′, and matches a result of an experiment in FIG. 58. Furthermore, an intensity ratio of a light-emitting subpixel to the spiked stray light illustrated in FIG. 46 also substantially matches the result of the experiment in FIG. 58. The match successfully confirms that an accurately constructed optical model makes it possible to calculate stray light by tracking a light ray.

Each of FIGS. 47 to 50 is a graph showing a stray light distribution obtained by optical calculation using, as a model, the display panel 2 of Embodiment 5 illustrated in FIG. 56, the display panel 2 including the light absorber LA. In order to confirm effects of a transmittance of the light absorber LA, the refractive index of the light absorber LA is fixed to the same 2.47 as the refractive index of GaN while the transmittance is varied to 0.9, 0.7, 0.3, and 0.1. The graphs show a result of the calculation. In this case, no difference in refractive index is observed between the semiconductor layer and the light absorber. Hence, the stray light is not refracted on the interface between the semiconductor layer and the light absorber. Thus, in a case where the light absorber LA has a transmittance of 0.9 as seen in FIG. 47, the case shows that a broad stray light propagating in a direction parallel to a surface of the substrate does not undergo significant attenuation. Whereas, the transmittance of the light absorber LA exhibits a significant advantageous effect. In a case where the light absorber LA has a transmittance of 0.7 as seen in FIG. 48, the case shows a decrease in intensity of the spiked stray light when the transmittance decreases from 0.9 to 0.7. Furthermore, in cases where the light absorber LA has a transmittance of 0.3 as seen in FIG. 49, and where the light absorber LA has a transmittance of 0.1 as seen in FIG. 50, the cases show significant attenuation of the broad stray light in addition to the spiked stray light when the transmittance decreases to 0.3 or below. Thanks to the attenuation, the stray light can be reduced to a degree in which the stray light is almost localized between the light-emitting element that is emitting light and the adjacent light-emitting element.

Hence, the light absorber LA has a transmittance of preferably 0.7 or below, and, more preferably, 0.3 or below, in a visible light region.

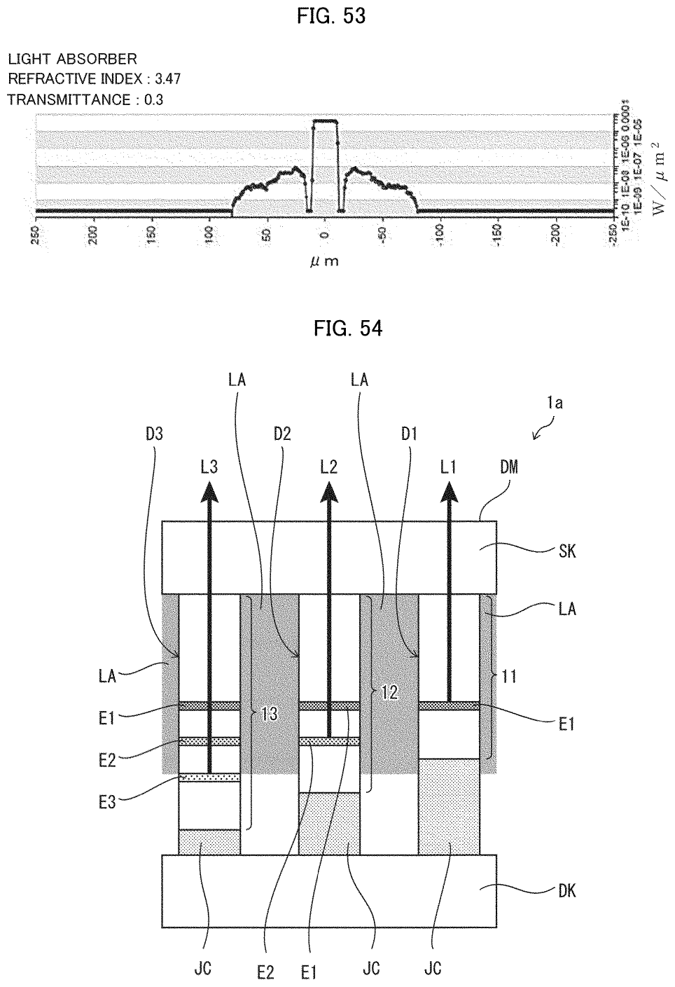

FIG. 51 is a graph showing a stray light distribution obtained by optical calculation using, as a model, the display panel 2 of Embodiment 5 illustrated in FIG. 56, the display panel including a light absorber having a refractive index of 1.5 and a transmittance of 1. FIG. 52 is a graph showing a stray light distribution obtained by optical calculation using, as a model, the display panel 2 of Embodiment 5 illustrated in FIG. 56, the display panel including a light absorber having a refractive index of 3.47 and a transmittance of 1. FIG. 53 is a graph showing a stray light distribution obtained by optical calculation using, as a model, the display panel 2 of Embodiment 5 illustrated in FIG. 56, the display panel 2 including the light absorber LA having a refractive index of 3.47 and a transmittance of 0.3.

Each of FIGS. 51 to 52 is a graph showing a stray light distribution obtained by optical calculation using, as a model, the display panel 2 of Embodiment 5 illustrated in FIG. 56, the display panel 2 including the light absorber LA. In order to confirm effects of a refractive index of the light absorber LA, the transmittance of the light absorber LA is fixed to 1 while the refractive index is varied to 1.5 and 3.47. The graphs show a result of the calculation. As illustrated in FIG. 51, in a case where the refractive index of the light absorber LA is smaller than the refractive index of the semiconductor layer (e.g., 2.47), the case shows that, in an adjacent subpixel producing a spiked stray light, the spiked stray light is significantly reduced in the adjacent subpixel; whereas, the broad stray light propagates for a long distance, and is hardly reduced. In contrast, as illustrated in FIG. 52, the light absorber LA has a refractive index larger than a refractive index of the semiconductor (e.g., 2.47). Hence, the light absorber LA can reduce the broad stray light. This is because, when the refractive index of the light absorber LA is smaller than the refractive index of the semiconductor layer, light incident close to parallel to the surface of the substrate, and at a shallow angle with respect to the sidewall of the multilayer stack included in the light-emitting element, is refracted in a direction from the light absorber LA toward the atmosphere. Whereas, when the refractive index of the light absorber LA is larger than the refractive index of the semiconductor layer, the light is refracted toward the surface of the substrate, reflected multiple times between the adjacent subpixels at a shallow angle, and attenuated. The broad stray light propagated over a wide range is a factor to decrease contrast of the display panel. However, the broad stray light can be reduced when the refractive index of the light absorber LA is set larger than the refractive index of the semiconductor layer, with the difference between the refractive indexes made greater.

As can be seen, in view of reducing the broad stray light propagating over a wide range, the refractive index of the light absorber LA is preferably larger by 0.1 or more, and, more preferably, by 1.5 or more, than a refractive index of a material forming a multilayer stack 11′ illustrated in FIG. 56.

Furthermore, in view of reducing the spiked stray light, the refractive index of the light absorber LA is preferably smaller by 0.1 or more, and, more preferably, by 1.5 or more, than a refractive index of a material forming the multilayer stack 11′ illustrated in FIG. 56.

FIG. 53 illustrates a stray light distribution obtained by optical calculation using, as a model, the display panel 2 of Embodiment 5 illustrated in FIG. 56, the display panel 2 including the light absorber LA having a refractive index of 3.47 and a transmittance of 0.3. The stray light distribution shows advantageous effects of both refraction and absorption, confirming that both the spilled stray light and the broad stray light are successfully reduced.

As can be seen, the transmittance of the light absorber LA is preferably 0.3 or smaller in the visible region. The refractive index of the light absorber LA is preferably larger by 0.1 or more, and, more preferably, by 1.5 or more, than a refractive index of a material forming the multilayer stack 11′ illustrated in FIG. 56.

### Embodiment 5

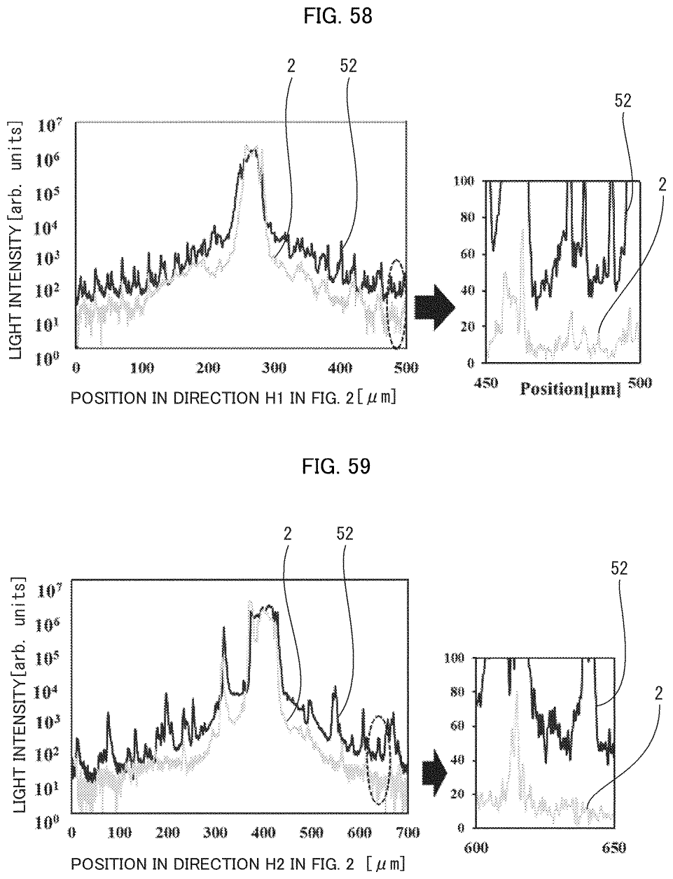

FIG. 56 is a cross-sectional view schematically illustrating a configuration of the display panel 2 according to Embodiment 5. FIG. 57 is a cross-sectional view of a schematic configuration of the display panel 52 according to Comparative Example 5. FIG. 58 is a graph showing a stray light distribution in a direction H1 in FIG. 32, as to each of the display panel 2 illustrated in FIG. 56 according to Embodiment 5 and the display panel 52 illustrated in FIG. 57 according to Comparative Example 5. FIG. 59 is a graph showing a stray light distribution in a direction H2 in FIG. 32, as to each of the display panel 2 illustrated in FIG. 56 according to Embodiment 5 and the display panel 52 illustrated in FIG. 57 according to Comparative Example 5.

The display panel 2 of Embodiment 5 illustrated in FIG. 56 and the display panel 52 of Comparative Example 5 illustrated in FIG. 57 are different from the above display panel 1 of Embodiment 4 and the above display panel 51 of Comparative Example 4 in that each of the display panel 2 and the display panel 52 is a monochromatic display panel having a plurality of light-emitting elements emitting light in one color. Each of the display panel 2 illustrated in FIG. 56 according to Embodiment 5 and the display panel 52 illustrated in FIG. 57 according to Comparative Example 5 is a blue monochromatic display panel. Note that the only difference between the display panel 2 of Embodiment 5 illustrated in FIG. 56 and the display panel 52 of Comparative Example 5 illustrated in FIG. 57 is that the display panel 2 includes the light absorber LA.

FIGS. 58 and 59 show that, as to both the stray light distribution in the direction H1 in FIG. 32 and the stray light distribution in the direction H2 in FIG. 32, the display panel 2 of Embodiment 5 illustrated in FIG. 56 reduces both the periodically spiked stray lights and the broad stray lights because of the light absorber LA provided to the display panel 2. Furthermore, compared with the display panel 52 without the light absorber LA of Comparative Example 5 illustrated in FIG. 57, it is confirmed that the display panel 2 of Embodiment 5 illustrated in FIG. 56 can reduce intensity of the stray light to at least ¼.

Note that, the above example shows a case where, in the display panel 2 of Embodiment 5 illustrated in FIG. 56, the light absorber LA is charged to completely fill the intervals between the island-shaped multilayer stacks 11′ included in the plurality of respective light-emitting elements D1′. However, Embodiment 5 shall not be limited to such a case. The light absorber LA may be formed, for example, as high as, or lower than, a thickness between a surface, of the underlayer U1, toward the display surface DM and a surface, of the light-emitting layer E1, toward the display surface DM. The underlayer U1 is a semiconductor layer closest from the display surface DM that releases light emitted from the light-emitting layer E1. The light-emitting layer E1 is closest from the display surface DM. The light absorber LA may also be formed as high as a thickness between the surface, of the underlayer U1, toward the display surface DM and the surface, of the light-emitting layer E1, toward the display surface DM.

### Embodiment 6

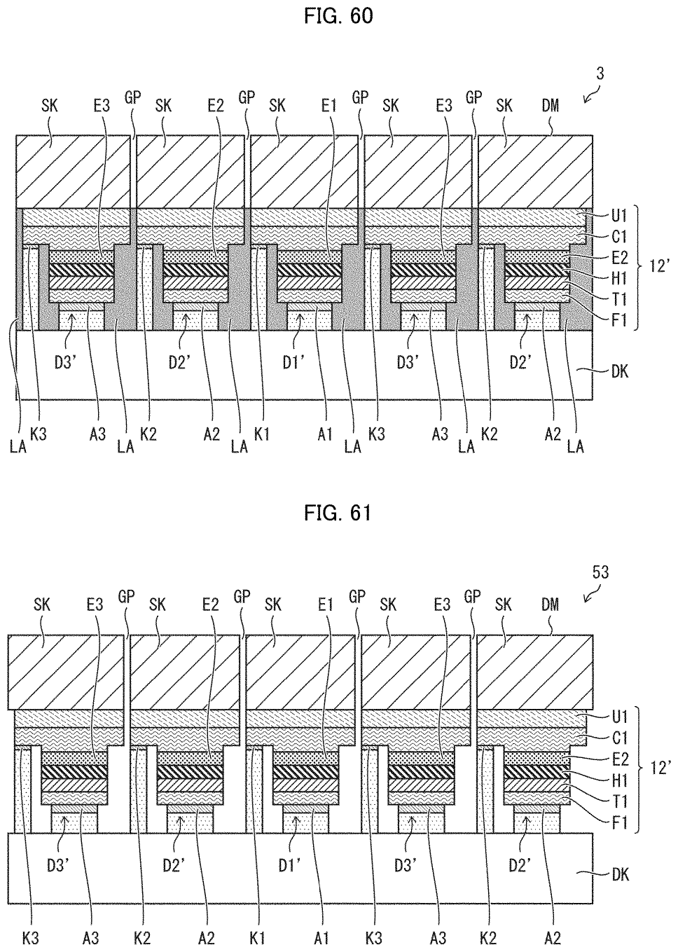

FIG. 60 is a cross-sectional view of a schematic configuration of the display panel 3 according to Embodiment 6. FIG. 61 is a cross-sectional view of a schematic configuration of the display panel 53 according to Comparative Example 6.

The display panel 3 of Embodiment 6 illustrated in FIG. 60 and the display panel 53 of Comparative Example 6 illustrated in FIG. 61 are different from the display panel 1 of Embodiment 4 and the display panel 51 of Comparative Example 4 in the points as follows. A plurality of chips are produced so that each of which includes one of the light-emitting element D1′ that is a blue light-emitting element, the light-emitting element D2′ that is a green light-emitting element, or the light-emitting element D3′ that is a red light-emitting element. The plurality of chips are bonded to one drive substrate DK on a chip-by-chip basis through the conductive adhesive layer JC, and arranged on the one drive substrate DK, to form the display panel 3 and the display panel 53. Note that the only difference between the display panel 3 of Embodiment 6 illustrated in FIG. 60 and the display panel 53 of Comparative Example 6 illustrated in FIG. 61 is that the display panel 3 includes the light absorber LA.

Although not shown, as to both the stray light distribution in the direction H1 in FIG. 32 and the stray light distribution in the direction H2 in FIG. 32, the display panel 3 of Embodiment 6 illustrated in FIG. 60 can reduce both the periodically spiked stray lights and the broad stray lights because of the light absorber LA provided to the display panel 3. Furthermore, compared with the display panel 53 without the light absorber LA of Comparative Example 6 illustrated in FIG. 61, the display panel 3 of Embodiment 6 illustrated in FIG. 60 can reduce intensity of the stray light to at least ¼.

Note that, in a case of the steps of producing the display panel 3 of Embodiment 6 illustrated in FIG. 60, at Step S26 in FIG. 33, each of the plurality of light-emitting elements D1′, D2′ and D3′ is individually formed into a chip. In such a case, Step S32 in FIG. 33 has to be carried out before Step S30 in FIG. 33, in order to mount, on the drive substrate DK, the plurality of light-emitting elements D1′, D2′ and D3′ formed into chips. Note that Step S28 in FIG. 33 is omitted. At Step S30 shown in FIG. 33, the light absorber LA can be charged to fill the intervals between the island-shaped multilayer stacks, using a gap GP made at above Step S32 in the growth substrate SK.

### Embodiment 7

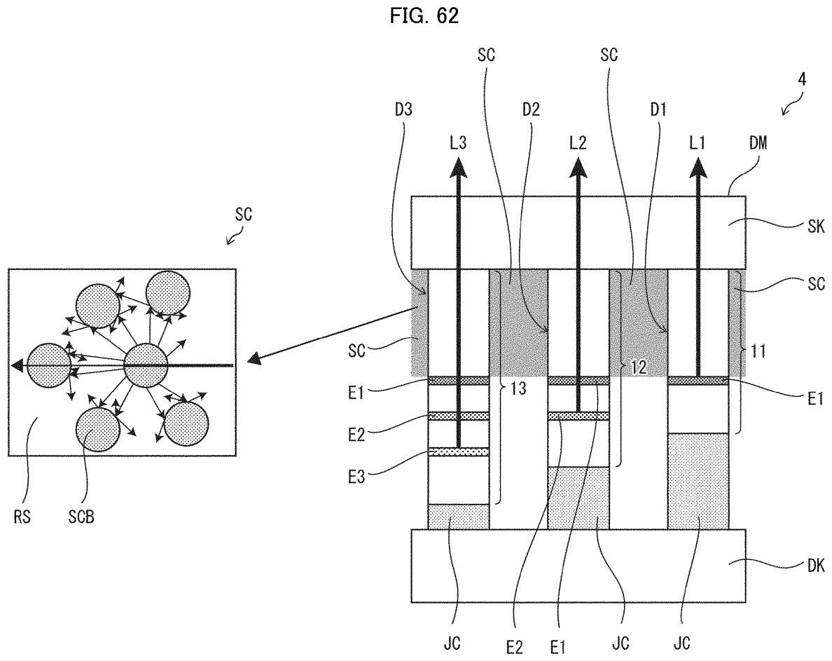

FIG. 62 is a cross-sectional view of a schematic configuration of a display panel 4 according to Embodiment 7. Note that FIG. 62 omits illustrations of anodes A1 to A3, cathodes K1 to K3, and an insulating film PF.

As illustrated in FIG. 62, the display panel 4 includes a light-emitting element D1, a light-emitting element D2, and a light-emitting element D3. The light-emitting element D1 includes: an island-shaped multilayer stack 11 including a plurality of semiconductor layers stacked on top of another and including a light-emitting layer E1; the anode A1; and the cathode K1. The light-emitting element D2 includes: an island-shaped multilayer stack 12 including a plurality of semiconductor layers stacked on top of another and including light-emitting layers E1 and E2; the anode A2; and the cathode K2. The light-emitting element D3 includes: an island-shaped multilayer stack 13 including a plurality of semiconductor layers stacked on top of another and including light-emitting layers E1 to E3; the anode A3; and the cathode K3. Scatterers SCB are provided between the island-shaped multilayer stacks 11, 12, and 13 respectively included in the light-emitting elements D1, D2, and D3. The scatterers SCB contain a material different from a material of the island-shaped multilayer stacks 11 to 13, and scatter light in a visible light region.

This embodiment exemplifies a case as follows. The light-emitting element (i.e., a first light-emitting element) D1 includes the island-shaped multilayer stack 11 including a plurality of semiconductor layers stacked on top of another and including the light-emitting layer E1 that is a blue light-emitting layer. The light-emitting element D1 serves as a blue light-emitting element in which the light-emitting layer E1 emits a light L1 colored blue. The light-emitting element (i.e., a second light-emitting element) D2 includes the island-shaped multilayer stack 12 including a plurality of semiconductor layers stacked on top of another and including the light-emitting layer E2 that is a green light-emitting layer and the light-emitting layer E1 that does not emit light. The light-emitting element D2 serves as a green light-emitting element in which the light-emitting layer E2 emits a light L2 colored green. The light-emitting element (i.e., a third light-emitting element) D3 includes the island-shaped multilayer stack 13 including a plurality of semiconductor layers stacked on top of another and including the light-emitting layer E3 that is a red light-emitting layer and the light-emitting layers E1 and E2 that do not emit light. The light-emitting element D3 serves as a red light-emitting element in which the light-emitting layer E3 emits a light L3 colored red. However, this embodiment shall not be limited to such a case.

As illustrated in FIG. 62, between the island-shaped multilayer stacks 11, 12, and 13 respectively included in the plurality of light-emitting elements D1, D2, and D3, a recess portion SC is provided to include the scatterers SCB. The recess portion SC is shorter in height than a tallest portion of each of the multilayer stacks 11 to 13. This embodiment exemplifies a case where the recess portion SC including the scatterers SCB is formed of a mixed material of the scatterers SCB and a resin material RS. However, this embodiment shall not be limited to such a case. The recess portion SC including the scatterers SCB may be formed of the scatterers SCB alone. Note that, in this embodiment, the resin material RS is a transparent resin material having a high transmittance in a visible light region.

As illustrated in FIG. 62, the recess portion SC of the display panel 4 may be formed as high as, or lower than, a thickness between a surface, of a semiconductor layer, toward a display surface DM and a surface, of the light-emitting layer E1, toward the display surface DM. The semiconductor layer is closest from the display surface DM that releases light emitted from the light-emitting layers E1 to E3, and the light-emitting layer E1 is closest from the display surface DM. In this embodiment, the recess portion SC is formed to have a height between a growth substrate SK and the surface, of the light-emitting layer E1, toward the display surface DM, the light-emitting layer E1 being included the island-shaped multilayer stacks 11 to 13 and being closest from the display surface DM. However, the recess portion SC shall not be limited to such a configuration. Although not shown, when the growth substrate SK (e.g., a C-plane sapphire substrate) is removed, as will be described later, a new display surface is the surface of the semiconductor layer closest from the display surface DM of the growth substrate SK before the growth substrate SK is removed.

As illustrated in FIG. 62, this embodiment exemplifies a case where, in the display panel 4, a bottom surface of the recess portion SC is a surface, of the growth substrate SK, across from the display surface DM. However, this embodiment shall not be limited to such an example. Although not shown, the bottom surface of the recess portion SC may be an indentation portion formed on a surface, of the growth substrate SK, across from the display surface DM.

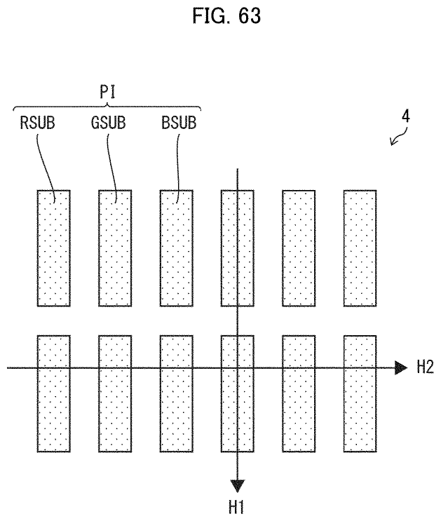

FIG. 63 is a plan view of a display surface SM of the display panel 4 illustrated in FIG. 62.

As illustrated in FIG. 63, this embodiment exemplifies a case as follows. One pixel PI includes: a red subpixel RSUB; a green subpixel GSUB; and a blue subpixel BSUB. The blue subpixel BSUB includes the light-emitting element (i.e., the first light-emitting element) D1 that is a blue light-emitting element. The green subpixel GSUB includes the light-emitting element (i.e., the second light-emitting element) D2 that is a green light-emitting element. The red subpixel RSUB includes the light-emitting element (i.e., the third light emitting element) D3 that is a red light-emitting element. However, this embodiment shall not be limited to such a case. For example, the one pixel PI may further include a subpixel in another color, other than the red subpixel RSUB, the green subpixel GSUB, and the blue subpixel BSUB.

The light-emitting elements D1 to D3 illustrated in FIG. 62 are separated from each other, and can control emission of light on a subpixel-by-subpixel basis illustrated in FIG. 63. This embodiment exemplifies a case of the display panel 4 produced as follows. A plurality of monolithic wafers are produced so that each of which has the plurality of light-emitting elements D1 to D3 provided on a growth substrate SK (e.g., a C-plane sapphire substrate) to emit light in different colors. On a wafer-by-wafer basis, the plurality of wafers are arranged on, and bonded to, a drive substrate DK through a conductive adhesive layer JC to form the display panel 4. However, this embodiment shall not be limited to such a case. For example, as seen in a display panel 5 to be described later in Embodiment 10, a plurality of monolithic wafers may be produced so that each of which has a plurality of the light-emitting elements D1′ provided on the growth substrate SK to emit light in the same color. On a wafer-by-wafer basis, the plurality of wafers may be arranged on, and bonded to, the drive substrate DK through the conductive adhesive layer JC to form the display panel 5. Furthermore, for example, as seen in a display panel 6 to be described later in Embodiment 11, a plurality of chips may be produced so that each of which includes one of the light-emitting element D1′ that is a blue light-emitting element, a light-emitting element D2′ that is a green light-emitting element, or a light-emitting element D3′ that is a red light-emitting element. The plurality of chips may be bonded to one drive substrate DK on a chip-by-chip basis through the conductive adhesive layer JC, and arranged on the one drive substrate DK, to form the display panel 6. Note that the display panels 1, 1a, and 1b to be described in this embodiment and the display panel 6 to be described in Embodiment 11 are display panels including a plurality of light-emitting elements that emit light in different colors. Hence, for example, one such display panel can be used for the augmented reality (AR), the virtual reality (VR), and small to large color display devices. Whereas, the display panel 5 to be described in Embodiment 10 is a monochromatic display panel including a plurality of light-emitting elements that emit light in one color. Hence, for example, three display panels including a red monochromatic display panel, a green monochromatic display panel, and a blue monochromatic display panel, and an optical member such as a mirror, can be used for the augmented reality (AR), the virtual reality (VR), and small to large color display devices.

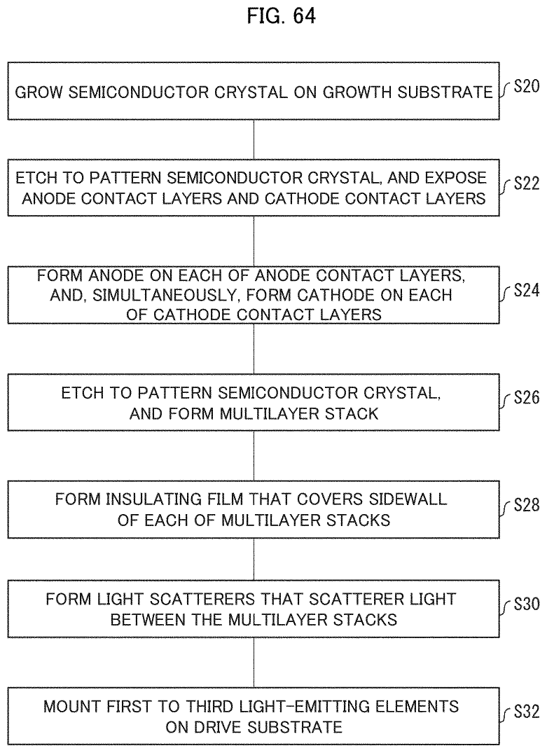

Hereinafter, steps of producing the display panel 4 according to this embodiment will be described, with reference to FIGS. 64 to 68.

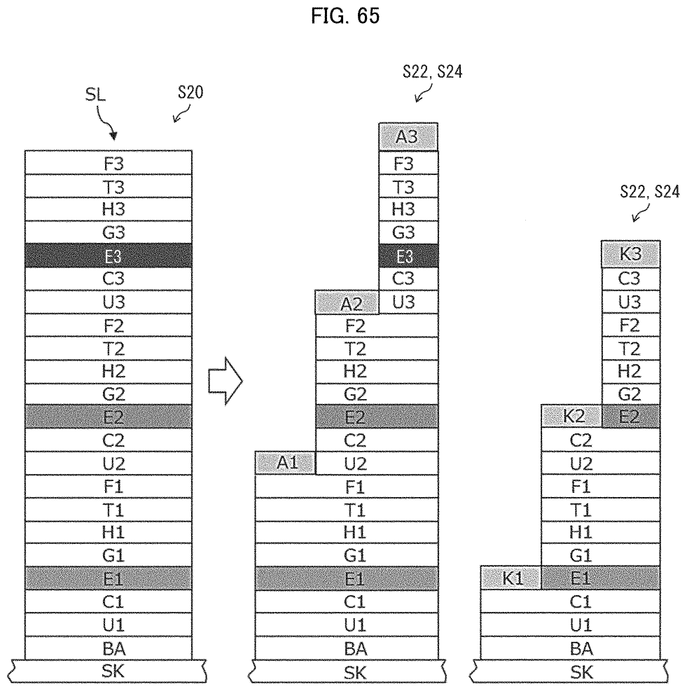

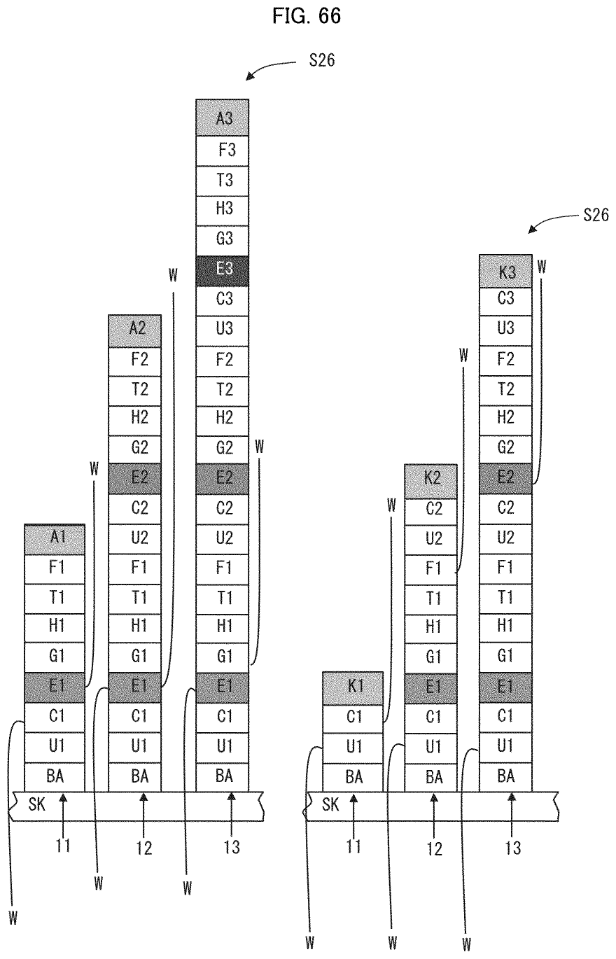

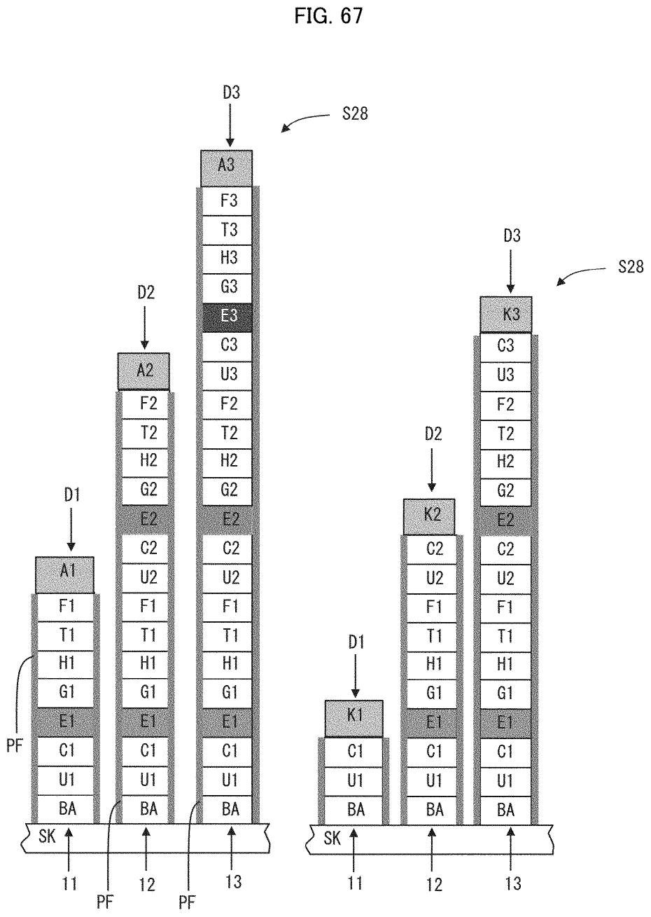

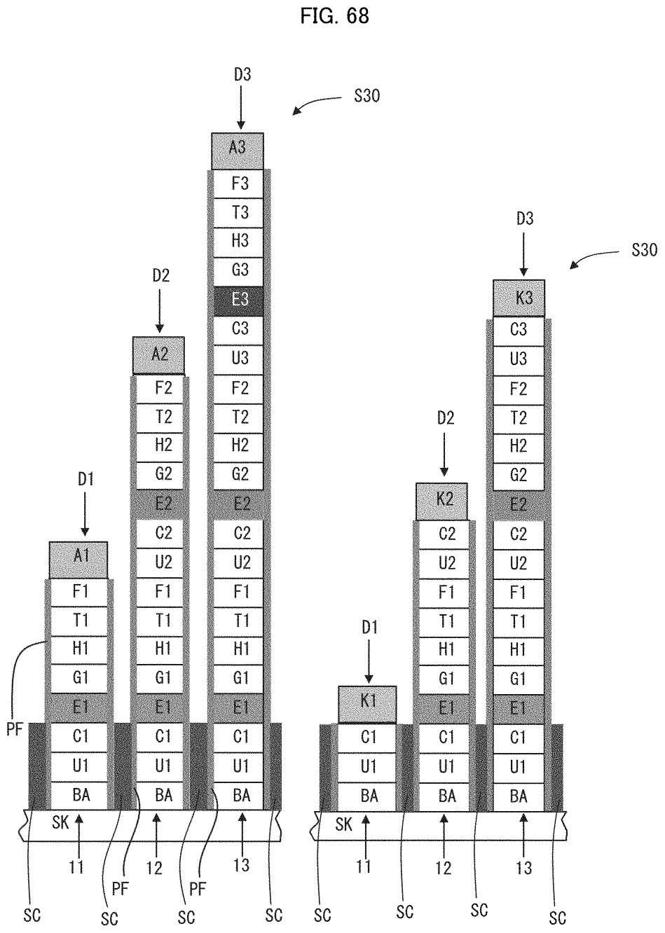

FIG. 64 is a flowchart showing a method for producing the display panel 4 illustrated in FIG. 62. FIG. 65 is a diagram showing Step S20, Step S22, and Step S24 in FIG. 64. FIG. 66 is a diagram showing Step S26 in FIG. 64. FIG. 67 is a diagram showing Step S28 in FIG. 64. FIG. 68 is a diagram showing Step S30 in FIG. 64.

Step S20 in FIG. 64 involves “growing a semiconductor crystal on a growth substrate”. As illustrated in FIG. 65, a semiconductor crystal SL is epitaxially grown on the growth substrate SK (e.g., a C-plane sapphire substrate), using such an apparatus as an MOCVD apparatus. The semiconductor crystal SL may be, for example, a nitride semiconductor crystal. Examples of the nitride semiconductor crystal may include GaN-based semiconductor, and additionally include aluminum nitride (AlN) and indium nitride (InN).

As illustrated in FIG. 65, Step S20 of forming the semiconductor crystal SL includes: a first step of forming a buffer layer BA, an underlayer U1, a cathode contact layer C1, the light-emitting layer E1, a middle layer G1, a p-type layer H1, a tunnel junction layer T1, and an anode contact layer F1 in the stated order; a second step of forming an underlayer U2, a cathode contact layer C2, the light-emitting layer E2, a middle layer G2, a p-type layer H2, a tunnel junction layer T2, and an anode contact layer F2 in the stated order; and a third step of forming an underlayer U3, a cathode contact layer C3, the light-emitting layer E3, a middle layer G3, a p-type layer H3, a tunnel junction layer T3, and an anode contact layer F3 in the stated order. Each of the first to third steps described above can be sequentially carried out in, for example, the MOCVD apparatus.

The buffer layer BA may be a gallium nitride crystal (e.g., 40 nm thick) formed at a low temperature (e.g., 600° C. or below).

The underlayers U1, U2, and U3 may be non-doped gallium nitride crystals (e.g., 2 μm thick). The cathode contact layers C1, C2, and C3 may be n-type gallium nitride crystals (e.g., 2 μm thick). The light-emitting layers E1, E2, and E3 may be active layers having a multiple quantum well (MQW) structure. For example, the light-emitting layer E1 that emits a blue light having a wavelength of approximately 450 nm may be formed of indium gallium nitride (i.e., a mixed crystal containing In and Ga at an atomic ratio of 1 to 4) having a thickness of 50 nm and containing indium (In) at a composition rate of 20%. For example, the light-emitting layer E2 that emits a green light having a wavelength of approximately 550 nm may be formed of indium gallium nitride (i.e., a mixed crystal) containing In at a composition rate of 25%. For example, the light-emitting layer E3 that emits a red light having a wavelength of approximately 630 nm may be formed of indium gallium nitride (i.e., a mixed crystal) containing In at a composition rate of 30%. The middle layers G1, G2, and G3 may be p-type aluminum gallium nitride crystals (e.g., 20 nm thick). The p-type layers H1, H2, and H3 may be p-type gallium nitride crystals (e.g., 120 nm thick). The tunnel junction layers T1, T2, and T3 may be non-doped gallium nitride crystals (e.g., 25 nm thick). The anode contact layers F1, F2, and F3 may be n-type gallium nitride crystals (e.g., 400 μm thick).

Step S22 in FIG. 64 involves “etching to pattern the semiconductor crystal, and exposing the anode contact layers and the cathode contact layers”. As illustrated in FIG. 65, the semiconductor crystal SL is dry-etched and patterned, and the cathode contact layers C1, C2, and C3 and the anode contact layers F1, F2, and F3 are exposed. At this step, a resist or an inorganic film (e.g., a silicon oxide film or a nickel film) patterned by liftoff can be used as an etching mask. The dry etching may be reactive ion etching (RIE) using a halogen such as chlorine or fluorine. Note that the etching mask is removed by, for example, a remover or an acid solution.

Step S24 in FIG. 64 involves “forming an anode on each of the anode contact layers, and, simultaneously, forming a cathode on each of the cathode contact layers”. As illustrated in FIG. 65, the anodes A1, A2, and A3 are respectively formed on the anode contact layers F1, F2, and F3, and, simultaneously, the cathodes K1, K2, and K3 are respectively formed on the cathode contact layers C1, C2, and C3. Specifically, an electrode material (e.g., a multilayer film of aluminum and titanium), which is vapor-deposited using a resist as a mask, is patterned by liftoff.

Step S26 in FIG. 64 involves “etching to pattern the semiconductor crystal, and forming a multilayer stack”. As illustrated in FIG. 66, the semiconductor crystal SL is dry-etched and patterned to form the island-shaped multilayer stack 11, the island-shaped multilayer stack 12, and the island-shaped multilayer stack 13. Here, the semiconductor crystal SL except for regions separated as the elements from one another is protected with a resist, and a portion included in the semiconductor crystal SL and found between the elements is completely removed by, for example, halogen-based RIE, so that the growth substrate SK is exposed between the elements. The growth substrate SK itself may be etched to have asperities. In this embodiment, in order to electrically and optically separate the elements excellently from one another, the semiconductor crystal SL is etched so that the surface of the growth substrate SK is exposed, and the island-shaped multilayer stacks 11, 12, and 13 are formed on the growth substrate SK. Note that each of the island-shaped multilayer stacks 11, 12, and 13 has a sidewall W.

Step S28 in FIG. 64 involves “forming an insulating film that covers the sidewall of each of the multilayer stacks”. As illustrated in FIG. 67, an insulating film PF is formed to cover the sidewall W of each of the island-shaped multilayer stack 11, the island-shaped multilayer stack 12, and the island-shaped multilayer stack 13. Hence, the light-emitting elements D1, D2, and D3 are formed. Here, a mask is formed by, for example, photolithography to cover the anodes A1, A2, and A3, and the cathodes K1, K2, and K3. After that, silicon oxide is formed by electron-beam evaporation to cover the sidewall W and serve as the insulating film PF. The insulating film PF has a function of preventing short-circuit between, and oxidation of, the elements. This embodiment exemplifies a case where the insulating film PF is a silicon oxide film. However, this embodiment shall not be limited to such a case, and the insulating film PF may include any one of a silicon oxide film, a silicon nitride film, a silicon oxynitride film, and an aluminum oxide film. Furthermore, the insulating film PF is formed to have a thickness of preferably 3 nm or more and 100 nm or less in a direction perpendicular to the sidewalls W of the island-shaped multilayer stacks 11, 12, and 13. As described in this embodiment, in a case where the insulating film PF is formed to cover the sidewall W of each of the island-shaped multilayer stacks 11, 12, and 13, the scatterers SCB, the resin material RS, and the light absorber LA to be described later can be made of a wide variety of materials. That is, if the insulating film PF is formed, conductive materials may be selected as the materials of the scatterers SCB, the resin material RS, and the light absorber LA. Note that if highly insulating materials are selected as the materials of the scatterers SCB, the resin material RS, and the light absorber LA, above Step S28 in FIG. 64 may be omitted.

Step S30 in FIG. 64 involves “forming scatterers that scatterer light between the multilayer stacks”. As illustrated in FIGS. 62 and 68, the height of the recess portion SC from the growth substrate SK may be, for example, a height between the growth substrate SK and the surface, of the light-emitting layer E1, toward the display surface DM, the light-emitting layer E1 being included the island-shaped multilayer stacks 11 to 13 and being closest from the display surface DM. However, the recess portion SC shall not be limited to such a configuration.

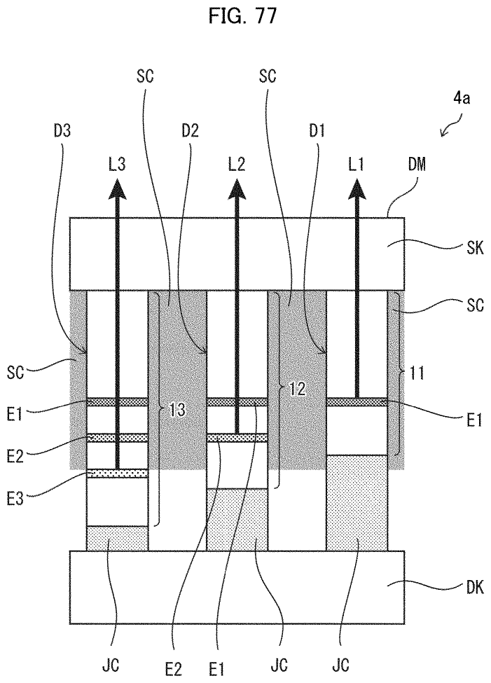

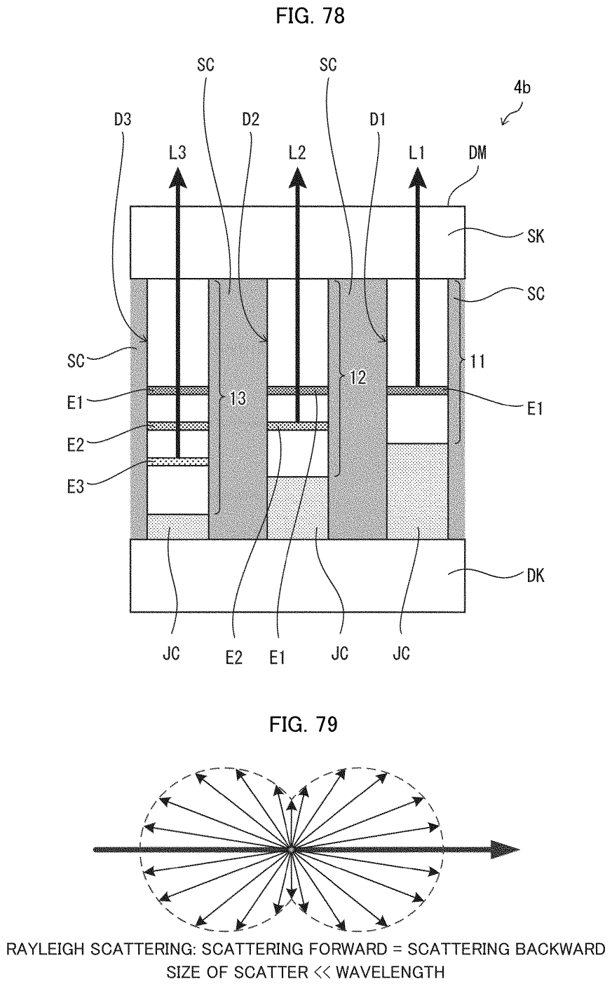

FIG. 77 is a cross-sectional view of a schematic configuration of another display panel 4a according to Embodiment 7. FIG. 78 is a cross-sectional view of a schematic configuration of still another display panel 4b according to Embodiment 7. The display panel 4a illustrated in FIG. 77 includes the light-emitting element D1, the light-emitting element D2, and the light-emitting element D3. The light-emitting element D1 includes, as the island-shaped multilayer stack 11, a first multilayer stack (the buffer layer BA, the underlayer U1, the cathode contact layer C1, the light-emitting layer E1, the middle layer G1, the p-type layer H1, the tunnel junction layer T1, and the anode contact layer F1) including the light-emitting layer E1. The light-emitting element D2 includes, as the island-shaped multilayer stack 12, the first multilayer stack and a second multilayer stack (the underlayer U2, the cathode contact layer C2, the light-emitting layer E2, the middle layer G2, the p-type layer H2, the tunnel junction layer T2, and the anode contact layer F2). The second multilayer stack includes the light-emitting layer E2 provided further from the display surface DM than the first multilayer stack. The light-emitting element D3 includes, as the island-shaped multilayer stack 13, the first multilayer stack, the second multilayer stack, and a third multilayer stack (the underlayer U3, the cathode contact layer C3, the light-emitting layer E3, the middle layer G3, the p-type layer H3, the tunnel junction layer T3, and the anode contact layer F3). The third multilayer stack includes the light-emitting layer E3 provided further from the display surface DM than the second multilayer stack. The display panel 4a further includes the recess portion SC containing the scatterers SCB and shorter in height than the tallest portion of the island-shaped multilayer stack 13 included in the light-emitting element D3. The recess portion SC may be formed as high as, or lower than, a thickness between a surface, of the buffer layer BA, toward the display surface DM and a surface, of the light-emitting layer E3, toward the display surface DM. The buffer layer BA is a semiconductor layer closest from the display surface DM that releases light emitted from the light-emitting layers E1 to E3. In the display panel 4a, the recess portion SC containing the scatterers SCB may be formed as high as a thickness between the surface, of the buffer layer BA, toward the display surface DM and the surface, of the light-emitting layer E3, toward the display surface DM. The buffer layer BA is a semiconductor layer closest from the display surface DM. However, this embodiment shall not be limited to such configurations. As seen in the display panel 4b illustrated in FIG. 78, the recess portion SC containing the scatterers SCB may be provided to completely fill intervals between the island-shaped multilayer stacks 11, 12, 13 respectively included in the plurality of the light-emitting elements D1, D2, D3.

In this embodiment, the scatterers SCB are, but not limited to, insulating SiO₂ particles having an average particle diameter of 450 nm. In this embodiment, as described above, the insulating SiO₂ particles are used as a mixture with a transparent resin material serving as the resin material RS. Alternatively, as seen in, for example, the display panel 4b illustrated in FIG. 78, if the recess portion SC containing the scatterers SCB is provided to completely fill the intervals between the island-shaped multilayer stacks 11, 12, 13, the recess portion SC containing the scatterers SCB may be formed of the insulating SiO₂ particles alone.

Each of the scatterers SCB may have a maximum length 5 nm or more and 5 μm or less. Each scatterer SCB may be a nanoparticle. The scatterer SCB may be a nanoparticle including a core and a shell. The scatterers SCB may be either an organic compound or an inorganic compound. The scatterers SCB may be any one of an insulator, a semiconductor, a metal, or a metal oxide. The scatterers SCB may be a resin containing one or more of an acrylic group, an epoxy group, a urethane group, and a silicone group. Furthermore, a refractive index of the scatterers SCB may be different from a refractive index of at least one layer included in the multilayer stacks 11 to 13.

Step S32 in FIG. 64 involves “mounting the light-emitting elements (the first to third light-emitting elements) on the drive substrate”. As illustrated in FIG. 62, the light-emitting elements D1, D2, and D3 are mounted on the drive substrate DK, including the drive circuit, through the conductive adhesive layer JC. Hence, the display panel 4 is obtained. The conductive adhesive layer JC can be formed of solder or an anisotropic conductive adhesive. In the display panel 4 illustrated in FIGS. 62 and 68, holes of the anodes A1, A2, and A3 are tunnel-injected into the p-type layers H1, H2, and H3 through the anode contact layers F1, F2, and F3, which are n-type semiconductor layers, and the tunnel junction layers T1, T2, and T3. Thanks to such a configuration, the anodes A1, A2, A3 and the cathodes K1, K2, K3 can be formed simultaneously of the same material. The configuration simplifies the steps compared with a typical technique of forming the anodes and the cathodes in different processes with different materials. Furthermore, the configuration reduces the risk of exposing the p-type (semiconductor) layers, which are likely to have high resistance, by dry etching and mechanical polishing. Such a feature provides the light-emitting elements with an advantageous effect of a stable electric characteristic. Note that after Step S32 shown in FIG. 64, such a technique as laser liftoff is used to carry out a step of delaminating and removing the growth substrate SK from the island-shaped multilayer stack 11, the island-shaped multilayer stack 12, the island-shaped multilayer stack 13, the insulating film PF, and the recess portion SC containing the scatterers SCB.

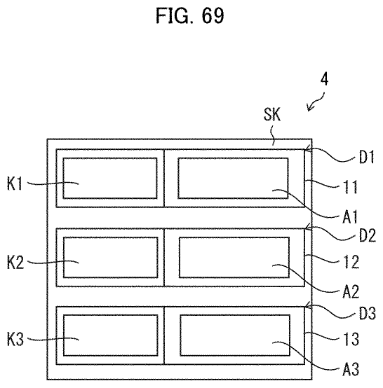

FIG. 69 is a plan view of a wafer after Step S30 shown in FIG. 64 and before Step S32 shown in FIG. 64, the wafer being viewed from toward an anode and a cathode.

As illustrated in FIG. 69, this embodiment exemplifies a case where the island-shaped multilayer stack 11 included the light-emitting element D1, the island-shaped multilayer stack 12 included in the light-emitting element D2, and the island-shaped multilayer stack 13 included in the light-emitting element D3 each have a size of 20 μm×120 μm in plan view, and where the island-shaped multilayer stacks 11, 12, and 13 are separated from each other by 10 μm. However, this embodiment shall not be limited to such a case.

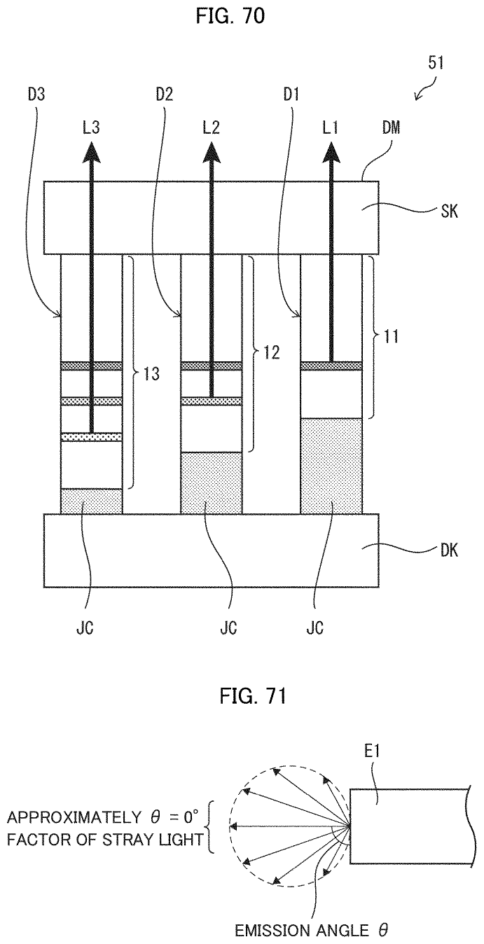

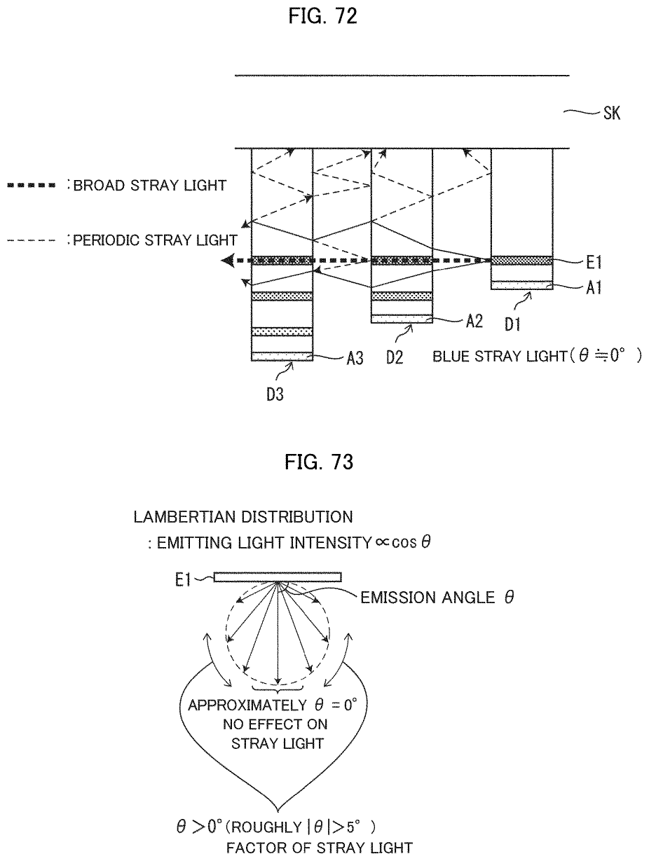

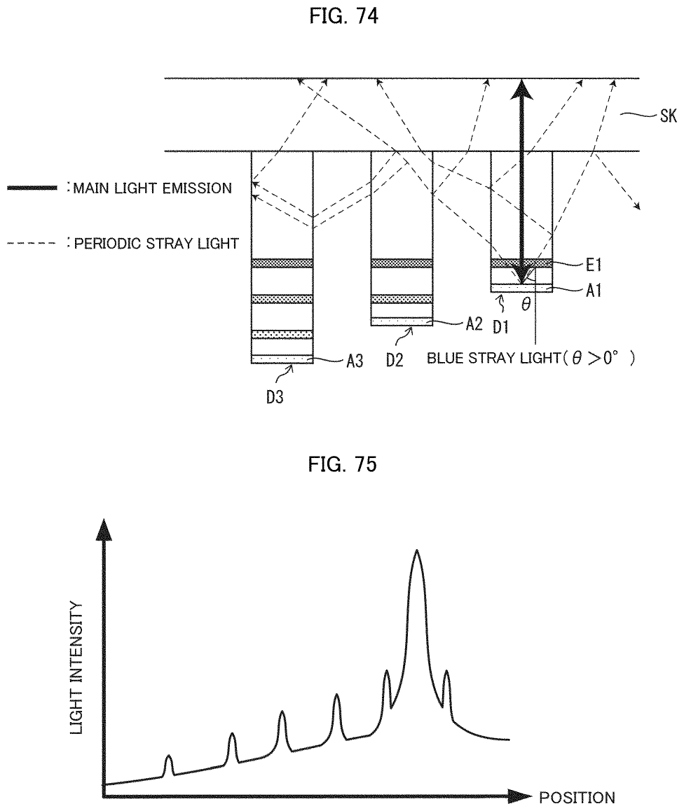

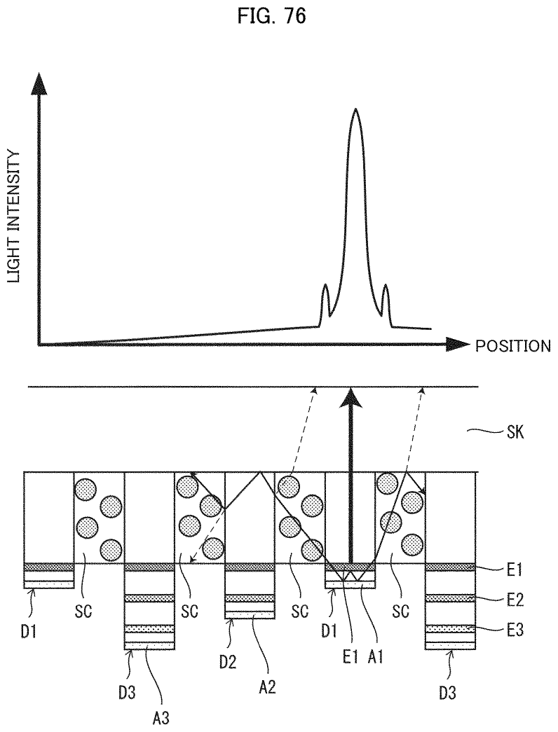

FIG. 70 is a cross-sectional view of a schematic configuration of a display panel 51 according to Comparative Example 4. FIG. 71 is a diagram showing a factor why the display panel 4 according to Embodiment 7 and the display panel 51 according to Comparative Example 4 produce stray light. FIG. 72 is a diagram showing a case where, in the display panel 51 according to Comparative Example 4, how the stray light produced by the factor illustrated in FIG. 71 makes an adjacent subpixel, including an OFF light-emitting element, appear to falsefully emit light. FIG. 73 is a diagram showing another factor why the display panel 4 according to Embodiment 7 and the display panel 51 according to Comparative Example 4 produce stray light. FIG. 74 is a diagram showing a case where, in the display panel 51 according to Comparative Example 4, how the stray light produced by the factor illustrated in FIG. 73 makes an adjacent subpixel, including an OFF light-emitting element, appear to falsefully emit light. FIG. 75 is a graph showing a distribution of stray light in the display panel 51 according to Comparative Example 4. FIG. 76 shows a graph showing a distribution of stray light in the display panel 4 according to Embodiment 7 and a diagram showing why light emitted from an ON light-emitting element can be kept from becoming stray light in the display panel 4 according to Embodiment 7.

The display panel 51 of Comparative Example 4 illustrated in FIG. 70 differs from the display panel 4 of Embodiment 7 only in that the display panel 51 omits the scatterers SCB. As illustrated in FIGS. 71 and 72, in the display panel 4 of Embodiment 7 and the display panel 51 of Comparative Example 4, among the light rays emitted from end faces of the light-emitting layers E1, E2, and E3, a light component propagating in a lateral direction toward an adjacent subpixel could be one of the factors that produces stray light. As illustrated in FIG. 71, the light rays emitted from the end faces of the light-emitting layers E1, E2, and E3 can be divided into light components having an emission angle θ of 0° or approximately 0° (less than plus or minus) 5° and light components having an emission angle θ of greater than plus or minus 5°. As illustrated in FIG. 72, a light component having an emission angle θ of 0° or approximately 0° (less than plus or minus) 5° is a component that is incident perpendicularly on the sidewall of the adjacent subpixel. This component is hardly reflected on element/atmosphere and atmosphere/element interfaces, and undergoes attenuation and propagates for a relatively long distance, and becomes a broad stray light having no clear peak. The attenuation is caused by a semiconductor included in an element; particularly, by the light-emitting layer and the p-type layer. Whereas, some of the light components having an emission angle θ greater than plus or minus 5° are reflected on the element/atmosphere and atmosphere/element interfaces, and the rest of the light components transmit and propagate. Reflected light travels toward either the growth substrate SK or the drive substrate DK. However, a component traveling toward the drive substrate DK is absorbed into the drive substrate DK, and hardly becomes stray light.

Whereas, a component traveling toward the growth substrate SK becomes stray light periodically forming a peak at the sidewall of the element. As illustrated in FIGS. 73 and 74, in the display panel 4 of Embodiment 7 and the display panel 51 of Comparative Example 4, among the light rays emitted toward the front (toward the drive substrate DK) and the back (toward the growth substrate SK) of the light-emitting layers E1, E2, and E3, the light component whose absolute value of the emission angle θ is greater than 0°, that is, roughly, whose absolute value of the emission angle θ is greater than 5°, is reflected on an electrode toward the front (toward the drive substrate DK), travels out of the element at the same emission angle as the incident angle, and becomes stray light having a periodic peak near the sidewall of the element. Whereas, the light component whose absolute value of the emission angle θ is 0°; that is, roughly, smaller than 5° does not become stray light. As illustrated in FIG. 75, when only the light-emitting element D1 is ON, the display panel 51 of Comparative Example 4 exhibits distribution of the periodic stray light corresponding to an arrangement of, and intervals between, the light-emitting elements D1, D2, and D3. In a display panel, stray light causes a decrease in image quality such as a decrease in contrast, virtual image, and false light.

Hence, the display panel 4 of this embodiment is provided with the above scatterers SCB to reduce a chance that the light emitted from an ON light-emitting element becomes stray light. The light component incident on the scatterers SCB is multiply scattered by the scatterers SCB, so that the light propagating to an adjacent subpixel is significantly attenuated. Furthermore, the scatterers SCB uniformly scatter incident light rays from all the directions. Such a feature can reduce a peaked stray light and a broad stray light at the same time.

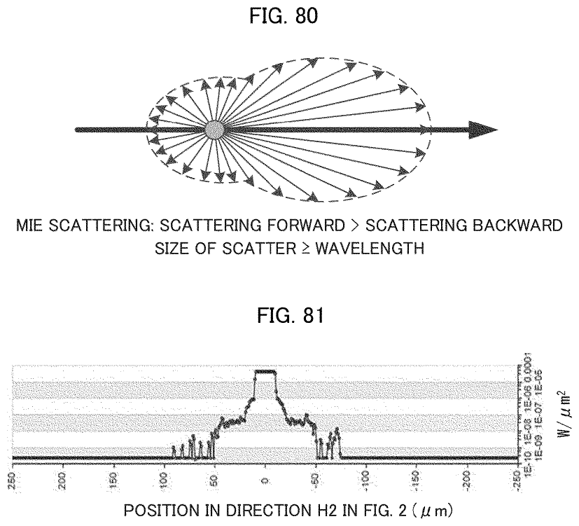

FIG. 79 is a diagram showing Rayleigh scattering by a scatterer. FIG. 80 is a diagram showing Mie scattering by a scatterer.

A scatterer SCB having an average particle diameter of 5 nm can further reduce stray light. This is because such a scatterer SCB can achieve an advantageous effect of Rayleigh scattering illustrated in FIG. 79 and caused when a size of the scatterer SCB is smaller than an emission wavelength. Compared with Mie scattering illustrated in FIG. 80 and caused when the size of the scatterer SCB is larger than, or equal to, the emission wavelength, the Rayleigh scattering allows stray light to scatter with greater intensity. Furthermore, as illustrated in FIG. 80, Mie scattering allows stray light to scatter with great intensity forward. Whereas, as illustrated in FIG. 79, Rayleigh scattering allows stray light to scatter isotropically, thereby more effectively attenuating incident light traveling straight. Moreover, in Rayleigh scattering illustrated in FIG. 79, light scatters with greater intensity in proportion to the minus fourth power of the wavelength. Such a feature achieves an advantageous effect of further reducing stray light in the order of red, green, and blue. In addition to the above advantageous effect, if the scatterers SCB have a diameter in the nanometer order, which is smaller than the emission wavelength, such scatterers SCB can be charged without any problem even if intervals between adjacent subpixels are reduced. As a result, the display panel can present images with higher definition. For example, if the scatterers SCB have a particle diameter of 5 nm, the scatterers SCB can be charged in the intervals provided between the island-shaped multilayer stacks 11 to 13 and each having a width of approximately 20 nm.

### Embodiment 8

FIG. 81 is a graph showing a distribution of stray light obtained by optical calculation using, as a model, a display panel 5 according to Embodiment 8, which is the same as the display panel 4 illustrated in FIG. 62, except that scatterers used for the display panel 5 according to Embodiment 8 are larger in size than the scatterers used for the display panel 4 illustrated in FIG. 62.

The display panel of this embodiment is the same as the display panel 4 illustrated in FIG. 62 except that the scatterers SCB used for the display panel 5 have an average particle diameter of 600 nm. In the case of the display panel of according to this embodiment, the average particle diameter of the scatterers SCB is larger than the emission wavelength. Thus, the effect of Rayleigh scattering illustrated in FIG. 79 is small, and the effect of Mie scattering illustrated in FIG. 80 is large. Hence, as illustrated in FIG. 81, a spiked stray light appears between the closest subpixels. As a result, Embodiment 8 shows that the scatterers SCB having an average particle diameter close to the emission wavelength can obtain an advantageous effect of further reducing stray light. Hence, the scatterers SCB may have an average particle diameter of 630 nm for red, 550 nm for green, and 450 nm for 450 nm. Furthermore, in a display panel in which red light-emitting elements, green light-emitting elements, and blue light-emitting elements are integrated, the scatterers SCB of these three sizes may be mixed together and charged between the elements provided throughout the panel.

### Embodiment 9

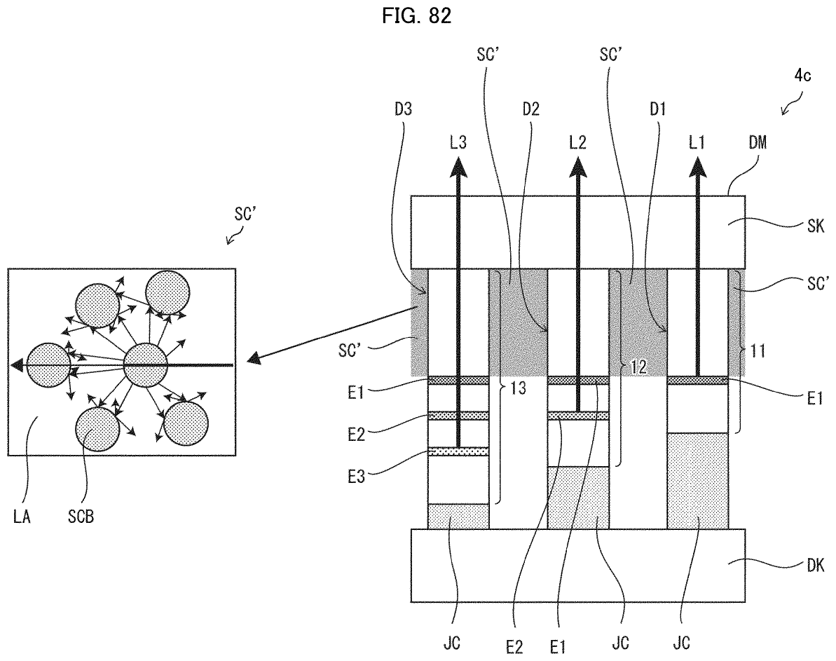

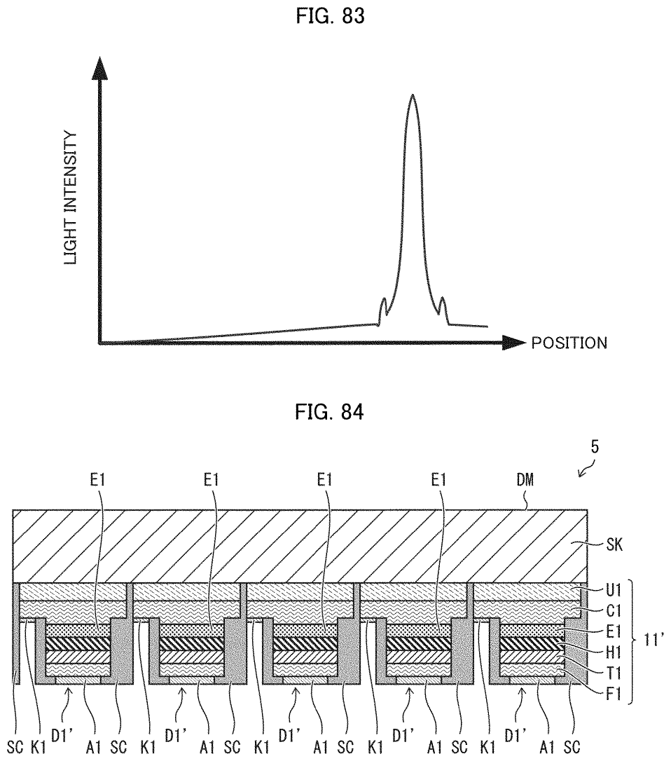

FIG. 82 is a cross-sectional view of a schematic configuration of a display panel 4c according to Embodiment 9. FIG. 83 is a graph showing a distribution of stray light in the display panel 4c according to Embodiment 9.

As illustrated in FIG. 82, a recess portion SC′ containing the scatterers SCB has the light absorber LA provided around the scatterers SCB to absorb light in a visible light region.

The light absorber LA may be formed of either an organic compound or an inorganic compound having a molecular structure including, for example, a pyridine skeleton. In this embodiment, the light absorber LA is an insulating compound; that is, for example, a black dye (trade name: N749, substance name: Ruthenium 620, tris(N,N,N-tributyl-1-butanaminium)[[2,2″6′,2″-terpyridine]-4,4′,4″-tricarboxylato(3-)-N1,N1′,N1″]tris(thiocyanato-N)hydrogen ruthenate(4-)). The black dye has a molar absorbance of 3×10⁻³ to 7×10⁻³ (1/M·cm) in the visible region. The black dye has a molecule structure including three pyridine skeletons with nitride and a plurality of functional groups bonding thereto. Note that, as seen in this embodiment, if an organic compound is used as the light absorber LA, even if the anodes A1, A2, A3 and the cathodes K1, K2, K3 are covered with the light absorber LA at the steps, ashing is performed with the surface of the elements protected with a metal mask having openings for the anodes A1, A2, and A3, and the cathodes K1, K2, and K3. The ashing can oxidize and remove the light absorber LA on the anodes A1, A2, A3 and the cathodes K1, K2, K3.

The light absorber LA may contain one or more selected from the group consisting of a modified acrylic-based resin, an epoxy-based resin, a urethane-based resin, a cyanoacrylate-based resin, a fluoroethylene-based resin, a silicone-based resin, polyvinyl alcohol (PVA), and polyvinyl chloride (PVC). Furthermore, the light absorber LA may contain one or more selected from the group consisting of an azo-based dye, a quinone-based dye, an indigo-based dye, a polymethine-based dye, a styryl-based dye, an azo-based pigment, a quinone-based pigment, an indigo-based pigment, a polymethine-based pigment, and a styryl-based pigment. Moreover, the light absorber LA may contain one or more selected from the group consisting of a carbon material, a metal sulfide, and a semiconductor material that absorbs light in a visible light region.

As illustrated in FIG. 83, the display panel 4c includes the light absorber LA together with the scatterers SCB. Compared with the scatterers SCB alone, such a feature makes it possible to further reduce stray light. When scattered light is dispersed multiple times and propagated in all directions, the scattered light is absorbed in large amount by the light absorber LA. As a result, light traveling straight toward an adjacent subpixel is quickly attenuated.

Note that, as to the recess portion SC′ including the scatterers SCB, the scatterers SCB are mixed and applied together with, for example, a liquid die such as a black die or a liquid pigment. Such a feature makes it possible to form the light absorber LA and the scatterers SCB together.

### Embodiment 10

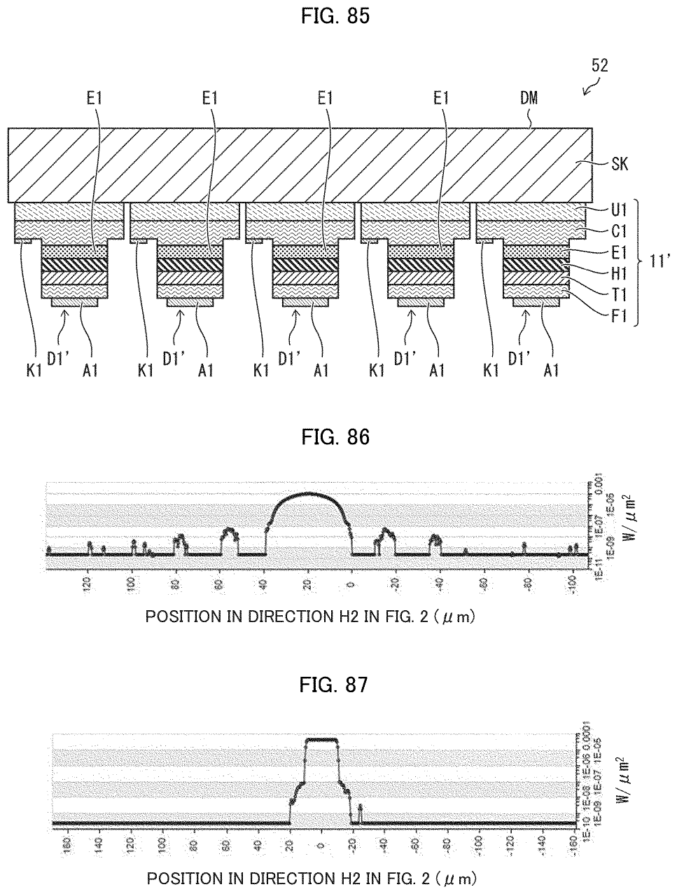

FIG. 84 is a cross-sectional view of a schematic configuration of a display panel 5 according to Embodiment 10. FIG. 85 is a cross-sectional view of a schematic configuration of a display panel 52 according to Comparative Example 5. FIG. 86 is a graph showing a distribution of stray light obtained by optical calculation using, as a model, the display panel 52 according to Comparative Example 5 illustrated in FIG. 85. FIG. 87 is a graph showing a distribution of stray light obtained by optical calculation using, as a model, the display panel 5 according to Embodiment 10 illustrated in FIG. 84.

The display panel 5 of Embodiment 10 illustrated in FIG. 84 and the display panel 52 of Comparative Example 5 illustrated in FIG. 85 are different from the above display panel 4 of Embodiment 7 and the above display panel 51 of Comparative Example 4 in that each of the display panel 5 and the display panel 52 is a monochromatic display panel having a plurality of light-emitting elements emitting light in one color. Each of the display panel 5 illustrated in FIG. 84 according to Embodiment 10 and the display panel 52 illustrated in FIG. 85 according to Comparative Example 5 is a blue monochromatic display panel. Note that the only difference between the display panel 5 of Embodiment 10 illustrated in FIG. 84 and the display panel 52 of Comparative Example 5 illustrated in FIG. 85 is that the display panel 5 includes the scatterers SCB.

FIGS. 86 and 87 show that, as to the stray light distribution in the direction H2 in FIG. 63, the display panel 5 of Embodiment 10 illustrated in FIG. 87 reduces both the periodically spiked stray lights and the broad stray lights because of the scatterers SCB provided to the display panel 5. Furthermore, compared with the display panel 52 without the scatterers SCB of Comparative Example 5 illustrated in FIG. 86, it is confirmed that the display panel 5 of Embodiment 10 illustrated in FIG. 87 can reduce intensity of the stray light to at least 1/10.

Note that, the above example shows a case where, in the display panel 5 of Embodiment 10 illustrated in FIG. 87, the scatterers SCB are charged to completely fill the intervals between the island-shaped multilayer stacks 11′ included in the plurality of respective light-emitting elements D1′. However, Embodiment 10 shall not be limited to such a case. The scatterers SCB may be formed, for example, as high as, or lower than, a thickness between a surface, of the underlayer U1, toward the display surface DM and a surface, of the light-emitting layer E1, toward the display surface DM. The underlayer U1 is a semiconductor layer closest from the display surface DM that releases light emitted from the light-emitting layer E1. The light-emitting layer E1 is closest from the display surface DM. The scatterers SCB may also be formed as high as a thickness between the surface, of the underlayer U1, toward the display surface DM and the surface, of the light-emitting layer E1, toward the display surface DM.

### Embodiment 11

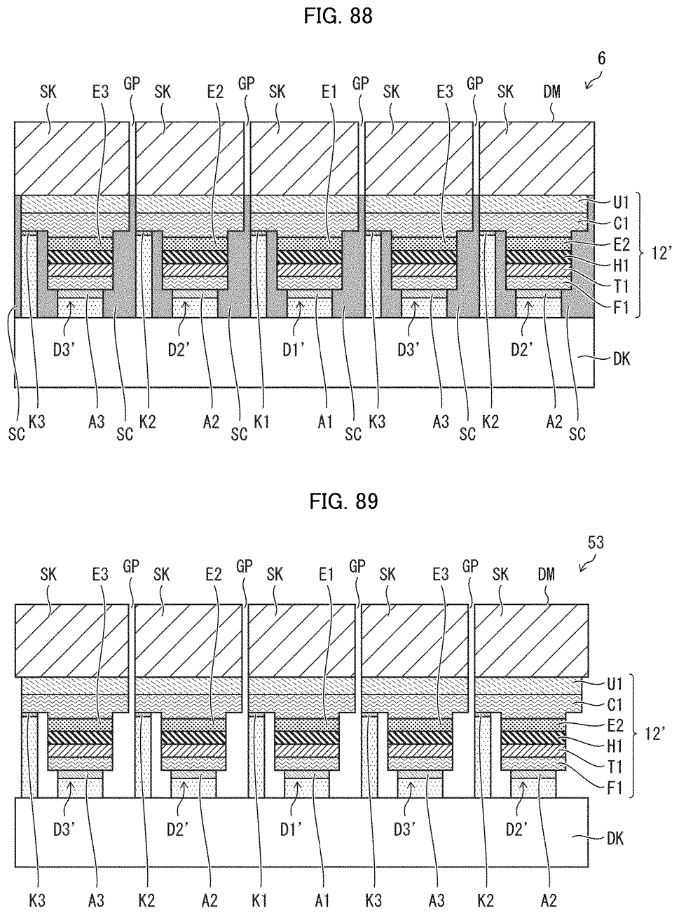

FIG. 88 is a cross-sectional view of a schematic configuration of a display panel 6 according to Embodiment 11. FIG. 89 is a cross-sectional view of a schematic configuration of a display panel 53 according to Comparative Example 6.

The display panel 6 of Embodiment 11 illustrated in FIG. 88 and the display panel 53 of Comparative Example 6 illustrated in FIG. 89 are different from the display panel 5 of Embodiment 10 and the display panel 52 of Comparative Example 5 in the points as follows. A plurality of chips are produced so that each of which includes one of the light-emitting element D1′ that is a blue light-emitting element, the light-emitting element D2′ that is a green light-emitting element, or the light-emitting element D3′ that is a red light-emitting element. The plurality of chips are bonded to one drive substrate DK on a chip-by-chip basis through the conductive adhesive layer JC, and arranged on the one drive substrate DK, to form the display panel 6 and the display panel 53. Note that the only difference between the display panel 6 of Embodiment 11 illustrated in FIG. 88 and the display panel 53 of Comparative Example 6 illustrated in FIG. 89 is that the display panel 6 includes the scatterers SCB.

Although not shown, as to the stray light distribution in the direction H2 in FIG. 63, the display panel 6 of Embodiment 11 illustrated in FIG. 88 can reduce both the periodically spiked stray lights and the broad stray lights because of the scatterers SCB provided to the display panel 6. Furthermore, compared with the display panel 53 without the scatterers SCB of Comparative Example 6 illustrated in FIG. 89, the display panel 6 of Embodiment 11 illustrated in FIG. 88 can reduce intensity of the stray light to at least 1/10.

Note that, in a case of the steps of producing the display panel 6 of Embodiment 11 illustrated in FIG. 88, at Step S26 in FIG. 64, each of the plurality of light-emitting elements D1′, D2′ and D3′ is individually formed into a chip. In such a case, Step S32 in FIG. 64 has to be carried out before Step S30 in FIG. 64, in order to mount, on the drive substrate DK, the plurality of light-emitting elements D1′, D2′ and D3′ formed into chips. Note that Step S28 in FIG. 64 is omitted. At Step S30 shown in FIG. 64, the scatterers SCB can be charged to fill the intervals between the island-shaped multilayer stacks, using a gap GP made at above Step S32 in the growth substrate SK.

### Embodiment 12

It is an object of one aspect of the present disclosure to reduce stray light in a light-emitting device by a non-conventional technique.

The following will describe Embodiment 12. For convenience of description, components (members) of Embodiment 13 and subsequent Embodiments that have the same function as components discussed in Embodiment 12 are indicated by the same reference numerals, and description thereof is not repeated. For the sake of brevity, the description of publicly known technical matters is also omitted where appropriate.

The components, materials, and numerical values described in the present specification are all merely illustrative as long as the description is consistent in content. Therefore, for example, the positional and connection relationships of the components are not limited to the examples shown in the drawings as long as the description is consistent in content. In addition, the drawings are not necessarily drawn to scale. The notation “A to B” for two numbers A and B denotes “from A to B, both inclusive” throughout the present specification as long as the description is not particularly inconsistent.

### Light-Emitting Device 10

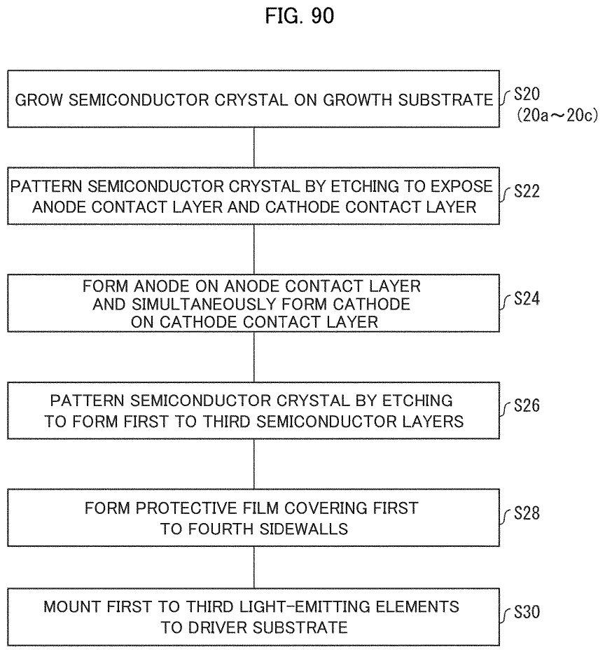

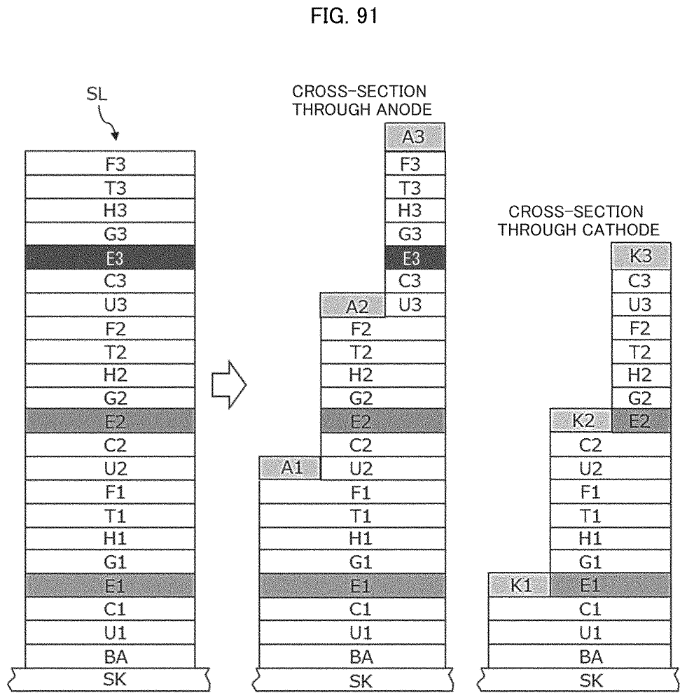

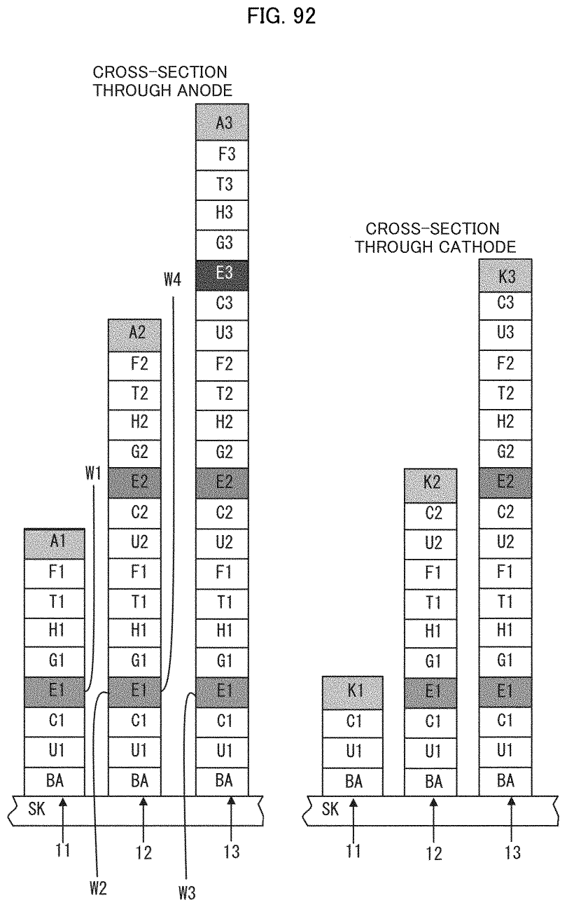

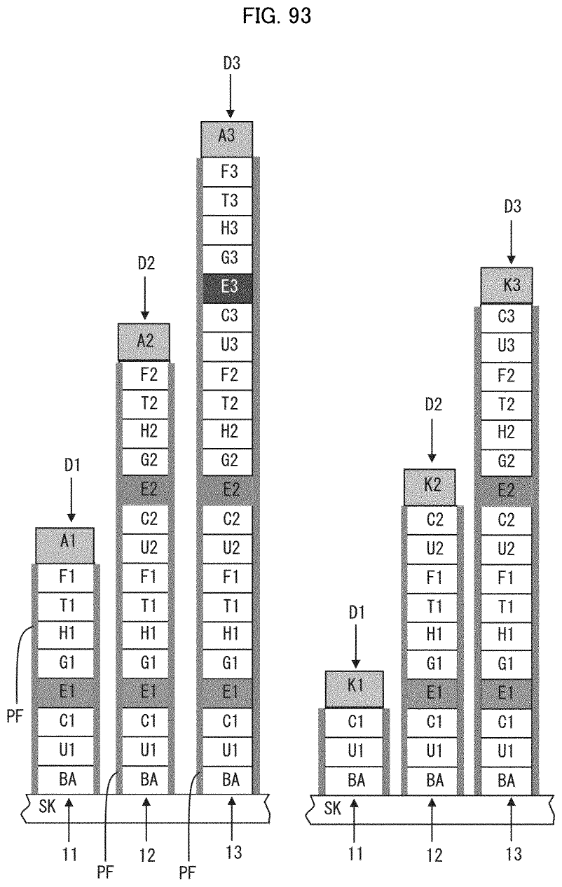

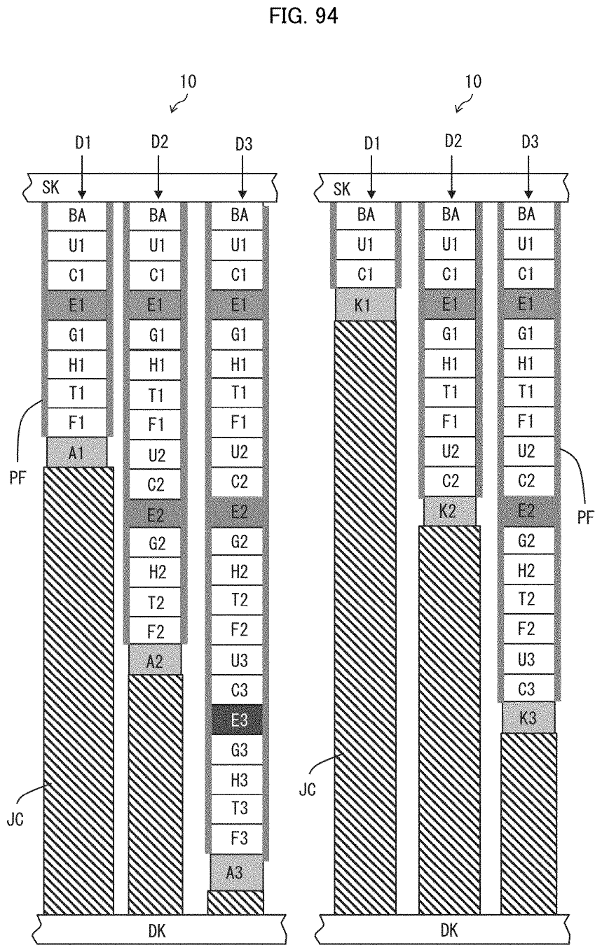

FIG. 90 is a flow chart representing an exemplary method of manufacturing a light-emitting device 10 in accordance with Embodiment 12. FIGS. 91 to 94 are cross-sectional views of this exemplary method of manufacturing the light-emitting device 10. Referring to FIGS. 90 to 94, in step S20, a semiconductor crystal SL is epitaxially grown on a growth substrate SK (e.g., a C-plane sapphire substrate) using, for example, an MOCVD device. The semiconductor crystal SL may be a nitride semiconductor crystal. Examples of the nitride semiconductor include AlN (aluminum nitride) and InN (indium nitride) as well as GaN-based semiconductors.

Step S20 in FIG. 90 involves: step 20a of forming a buffer layer BA, a base layer U1, a cathode contact layer C1, a first light-emitting layer E1, an intermediate layer G1, a p-type layer H1, a tunnel junction layer T1, and an anode contact layer F1, all of which are provided in this order; step 20b of forming a base layer U2, a cathode contact layer C2, a second light-emitting layer E2, an intermediate layer G2, a p-type layer H2, a tunnel junction layer T2, and an anode contact layer F2, all of which are provided in this order; and step 20c of forming a base layer U3, a cathode contact layer C3, a third light-emitting layer E3, an intermediate layer G3, a p-type layer H3, a tunnel junction layer T3, and an anode contact layer F3, all of which are provided in this order. Steps 20a to 20c can be sequentially performed in, for example, an MOCVD device.

The buffer layer BA may be a gallium nitride crystal (e.g., with a thickness of 40 nm) formed at low temperature (e.g., at or below 600° C.). The base layers U1, U2, and U3 may be a non-doped gallium nitride crystal (e.g., with a thickness of 2 [μm]). The cathode contact layers C1, C2, and C3 may be an n-type gallium nitride crystal (e.g., with a thickness of 2 [μm]). The first light-emitting layer E1, the second light-emitting layer E2, and the third light-emitting layer E3 may be active layers with an MQW (multiplex quantum well) structure. As an example, the first light-emitting layer E1 that emits blue light of a wavelength of approximately 450 nm may be indium gallium nitride (a mixed crystal with an In—Ga atomic ratio of 1:4) with an In (indium) composition ratio of 20% and a thickness of 50 nm. As an example, the second light-emitting layer E2 that emits green light of a wavelength of approximately 550 nm may be indium gallium nitride (a mixed crystal) with an In composition ratio of 25%. As an example, the third light-emitting layer E3 that emits red light of a wavelength of approximately 630 nm may be indium gallium nitride (a mixed crystal) with an In composition ratio of 30%. The intermediate layers G1, G2, and G3 may be a p-type aluminum gallium nitride crystal (e.g., with a thickness of 20 nm). The p-type layers H1, H2, and H3 may be a p-type gallium nitride crystal (e.g., with a thickness of 120 nm). The tunnel junction layers T1, T2, and T3 may be a non-doped gallium nitride crystal (e.g., with a thickness of 25 nm). The anode contact layers F1, F2, and F3 may be an n-type gallium nitride crystal (e.g., with a thickness of 400 nm).

In step S22 in FIG. 90, the semiconductor crystal SL is patterned by dry etching to expose the cathode contact layers C1, C2, and C3. An etching mask in step S22 may be either a resist or an inorganic film (e.g., a silicon oxide film or a nickel film) patterned by lift-off. The dry etching may be reactive ion etching (RIE) using a halogen such as chlorine or fluorine. The etching mask is removed using, for example, a remover or an acidic solution.

In step S24 in FIG. 90, anodes A1, A2, and A3 are formed on the anode contact layers F1, F2, and F3, and cathodes K1, K2, and K3 are simultaneously formed on the cathode contact layers C1, C2, and C3. Specifically, an electrode material vapor-deposited using a resist as a mask (e.g., a stack film of aluminum and titanium) is patterned by lift-off.

In step S26 in FIG. 90, the semiconductor crystal SL is patterned by dry etching to form a first semiconductor layer 11, a second semiconductor layer 12, and a third semiconductor layer 13. In this example, the regions other than the regions in which elements are isolated are protected with a resist, and those portions of the semiconductor crystal SL which are between elements are completely removed by, for example, halogen-based RIE so as to expose the growth substrate SK between the elements. Projections and depressions may be formed on the growth substrate SK by etching the growth substrate SK itself. Electrical element isolation can be done by stopping the etching immediately below the first light-emitting layer E1, the second light-emitting layer E2, and the third light-emitting layer E3. Alternatively, the etching may be performed so as to expose the surface of the growth substrate SK for optical element isolation.

In step S28 in FIG. 90, a first light-emitting element D1, a second light-emitting element D2, and a third light-emitting element D3 are obtained by forming a protective film PF that covers a first sidewall W1 contained in the first semiconductor layer 11, a second sidewall W2 and a fourth sidewall W4 both contained in the second semiconductor layer 12, and a third sidewall W3 contained in the third semiconductor layer 13. In this example, after a mask that covers the anodes A1, A2, and A3 and the cathodes K1, K2, and K3 is formed by, for example, photolithography, silicon oxide that covers the first to fourth sidewalls W1 to W4 is formed by electron beam evaporation, to obtain the protective film PF. The protective film PF has functions of preventing short-circuiting between elements and preventing oxidation.

In step S30 in FIG. 90, the first light-emitting element D1, the second light-emitting element D2, and the third light-emitting element D3 are mounted to a driver substrate DK via a conductive layer JC, to obtain the light-emitting device 10. The conductive layer JC may be solder or an anisotropic conductive adhesive.

The light-emitting device 10 is structured to tunnel-inject holes from the anodes A1, A2, and A3 to the p-type layers H1, H2, and H3 via the cathode contact layers C1, C2, and C3, which are n-type semiconductor layers, and also via the tunnel junction layers T1, T2, and T3. This particular structure enables forming the anodes A1, A2, and A3 and the cathodes K1, K2, and K3 simultaneously from the same material, which allows for simplification of steps over general techniques where the anodes and cathodes are formed from different materials in different processes. In addition, the p-type (semiconductor) layers, which will readily have their resistance increased in dry etching and machine polishing, do not need to be exposed, so that the light-emitting elements advantageously exhibit stable electrical properties. FIGS. 90 to 94 show the first to third light-emitting elements D1 to D3 being formed monolithically on the growth substrate SK, which is merely illustrative. The first to third light-emitting elements D1 to D3 may be formed individually and mounted to the driver substrate DK. In addition, the growth substrate SK may be lifted off by, for example, laser lift-off after the first to third light-emitting elements D1 to D3 are mounted to the driver substrate DK.

### Display Device 50

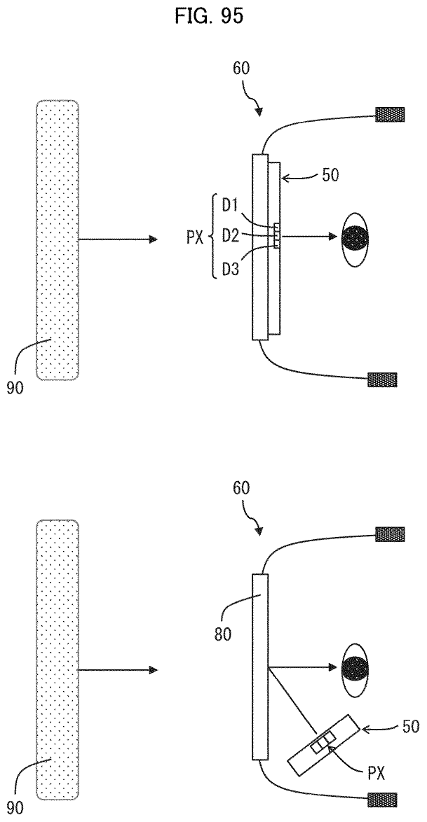

FIG. 95 is a cross-sectional view of an exemplary structure of a display device 50 in accordance with Embodiment 12. The display device 50 includes a light-emitting device in accordance with an aspect of the present disclosure. In the example in accordance with Embodiment 12, the display device 50 includes the light-emitting device 10. The display device 50 includes a plurality of pixels PX, and each pixel PX includes, for example, the first to third light-emitting elements D1 to D3. Light from the pixel PX may incident, for example, to the human eye or a sensor either directly or via a projection object 80. A wearable device 60 including the display device 50 may be constructed to superimpose an image produced by the display device 50 onto an external world 90.

### Embodiment 13

### Light-Emitting Device 10V

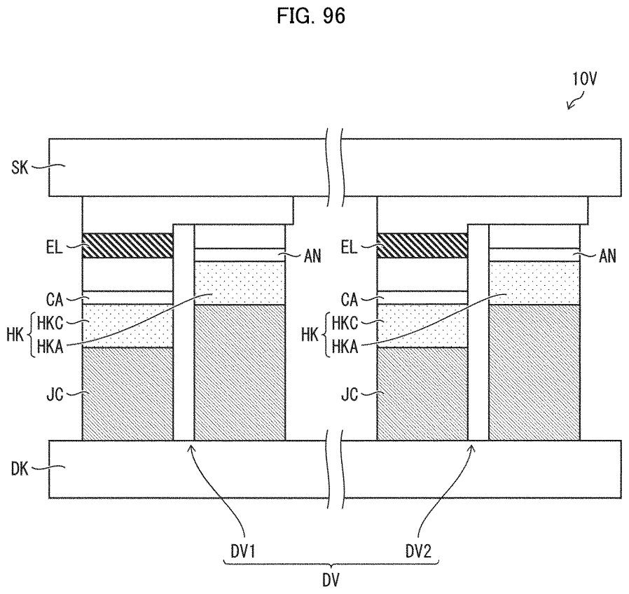

FIG. 96 is a schematic illustration of a structure of the light-emitting device 10V in accordance with Embodiment 13. The light-emitting device 10V includes a plurality of light-emitting elements DV. FIG. 96 shows an example where two of the light-emitting elements DV are a first light-emitting element DV1 and a second light-emitting element DV2. The second light-emitting element DV2 is a light-emitting element that is adjacent to the first light-emitting element DV1 in the example of FIG. 96.

FIG. 96 shows the first light-emitting element DV1 and the second light-emitting element DV2 having an equivalent structure for convenience of description. Accordingly, the description of one light-emitting element DV in the example of FIG. 96 is applicable to both the first light-emitting element DV1 and the second light-emitting element DV2.

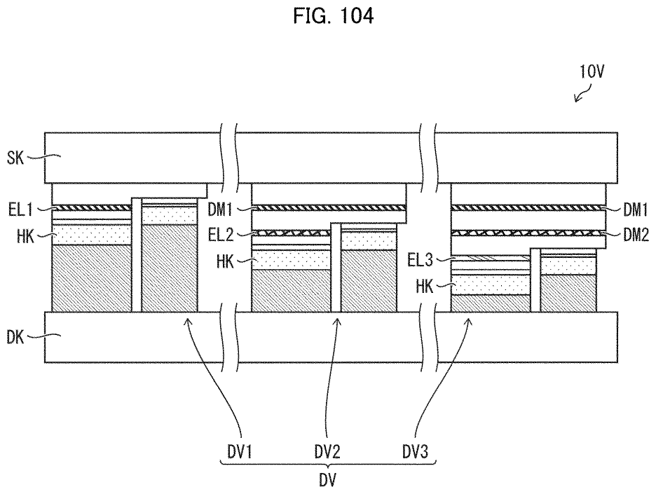

It should be understood however that the second light-emitting element DV2 may have a different structure than the first light-emitting element DV1 as clearly understood from the description in Embodiment 12. Therefore, for example, various parts of the second light-emitting element DV2 may be provided in different locations than the corresponding parts of the first light-emitting element DV1. As an example, when the second light-emitting element DV2 emits light of a different color than the first light-emitting element DV1, the position of a light-emitting layer EL in the second light-emitting element DV2 may differ from the position of a light-emitting layer EL in the first light-emitting element DV1 in terms of the height direction of the light-emitting device 10V (see also FIG. 104 described later).

The light-emitting element DV includes an anode AN, a cathode CA, and the light-emitting layer EL. In addition, unlike Embodiment 12, the light-emitting element DV further includes a light absorber HK. In the example of FIG. 96, the growth substrate SK is supposed to be transparent to light. Accordingly, in the example of FIG. 96, light is extracted in a direction (“light-extracting direction”) from a side of the driver substrate DK to a side of the growth substrate SK in the plane of the paper on which FIG. 96 is drawn.

In the description related to FIG. 96, the light-extracting direction is referred to as the upward direction. On the other hand, the direction opposite the upward direction (in other words, the direction from a side of the growth substrate SK to a side of the driver substrate DK in the plane of the paper on which FIG. 96 is drawn) is referred to as the downward direction. Therefore, in the description related to FIG. 96, the top face of the growth substrate SK is supposed to be a light-extracting face. This is applicable to examples shown in subsequent Figures corresponding to FIG. 96 as long as the description is consistent in content.

In Embodiment 13, each of the plurality of light-emitting elements DV is again electrically isolated. Accordingly, the first light-emitting element DV1 and the second light-emitting element DV2 are electrically insulated from each other. The first light-emitting element DV1 and the second light-emitting element DV2 are hence adjacent to each other, but separated by a distance, in the example of FIG. 96.

Part of the light emitted by the light-emitting layer EL is stray light (details will be given later). Accordingly, the light-emitting device 10V includes the light absorber HK to reduce stray light. The light absorber HK needs only to have relatively good light absorption characteristics at frequencies of the light emitted by the light-emitting layer EL.

The light-emitting element DV may include either one or both of an anode-side light absorber HKA and a cathode-side light absorber HKC as the light absorber HK. In the example of FIG. 96, the light-emitting element DV includes both the anode-side light absorber HKA and the cathode-side light absorber HKC.

The anode-side light absorber HKA needs only to be disposed below the anode AN when viewed from the light-extracting side of the light-emitting device 10V. The anode-side light absorber HKA may be either separated from the anode AN or in contact with the bottom face of the anode AN. Therefore, as an example, the anode-side light absorber HKA may cover at least a part of the bottom face of the anode AN.

Likewise, the cathode-side light absorber HKC needs only to be disposed below the cathode CA when viewed from the light-extracting side of the light-emitting device 10V. The cathode-side light absorber HKC may be either separated from the cathode CA or in contact with the bottom face of the cathode CA. Therefore, as an example, the cathode-side light absorber HKC may cover at least a part of the bottom face of the cathode CA.

Either one or both of the anode AN and the cathode CA may be disposed above the light absorber HK as described above. Therefore, either one or both of the anode AN and the cathode CA may be transparent to light. Preferably, both the anode AN and the cathode CA may be transparent to light.

As an example, either one or both of the anode AN and the cathode CA may contain, as a material, at least one of ITO, FTO, IGZO®, ZnO, silicide, and SiC. Therefore, for example, either one or both of the anode AN and the cathode CA may include a stack of two or more of these materials.

Stray light can occur in various manners in the light-emitting device 10V, depending on, for example, the refractive indices of various parts of the light-emitting device 10V. The inventors of the present application (hereinafter, the “inventors”) have investigated the relationships between stray light and the refractive index nHK of the light absorber HK and also between stray light and the refractive index nSC of the semiconductor material constituting the light-emitting element DV through an optical simulation. Throughout the following description, the optical simulation will be simply referred to as the simulation.

The inventors have found, from the results of the simulation, that stray light can be effectively reduced when nHK is close to nSC. Specifically, the inventors have found that stray light can be effectively reduced when the difference between nHK and nSC is in ±0.5. As described so far, the light-emitting element DV preferably satisfies |nHK-nSC|≤0.5. As an example, nSC may be the refractive index of the material of the light-emitting layer EL (e.g., the material of MQW).

Generally, the light absorber HK has a light-absorbing property that improves with an increase in the extinction coefficient of the light absorber HK. The inventors have found, from the results of the simulation, that stray light can be effectively reduced even when the extinction coefficient of the light absorber HK is greater than or equal to 5.

In addition, the light-absorbing property of the light absorber HK can depend also on the thickness of the light absorber HK. The inventors have found, from the results of the simulation, that stray light can be effectively reduced even when the light absorber HK has a thickness of from 0.5 μm to 5 μm inclusive.

When the light-emitting layer in the light-emitting element in accordance with an aspect of the present disclosure emits light, electric current flows, for example, along an electric current path that extends from the drive circuit to the anode, to the light-emitting layer, to the cathode, and then to the drive circuit. Then, as shown in FIG. 96, the light absorber HK may reside between a drive circuit DK and the anode AN. In addition, the light absorber HK may reside also between the drive circuit DK and the cathode CA.

Therefore, the light absorber HK is preferably electrically conductive. When this is the case, the risk can be reduced of reducing electric current in the electric current path due to the light absorber HK.

Therefore, for example, the light absorber HK may contain a Group IV semiconductor, a Group III-V semiconductor except for nitrides, C, or a metal sulfide. From this, as an example, the light absorber HK may be graphite containing C as a primary component. As another example, the light absorber HK may be DLC (diamond-like carbon) containing C and H.

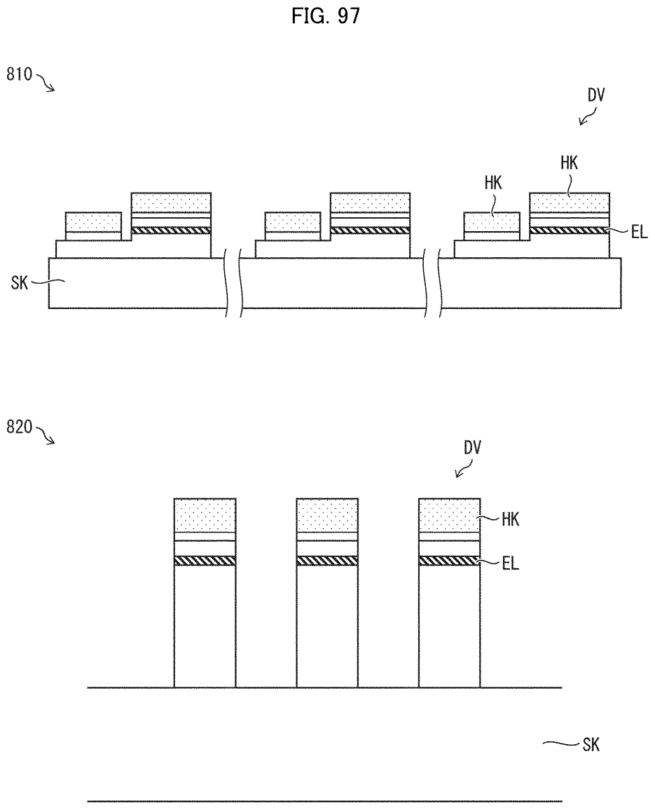

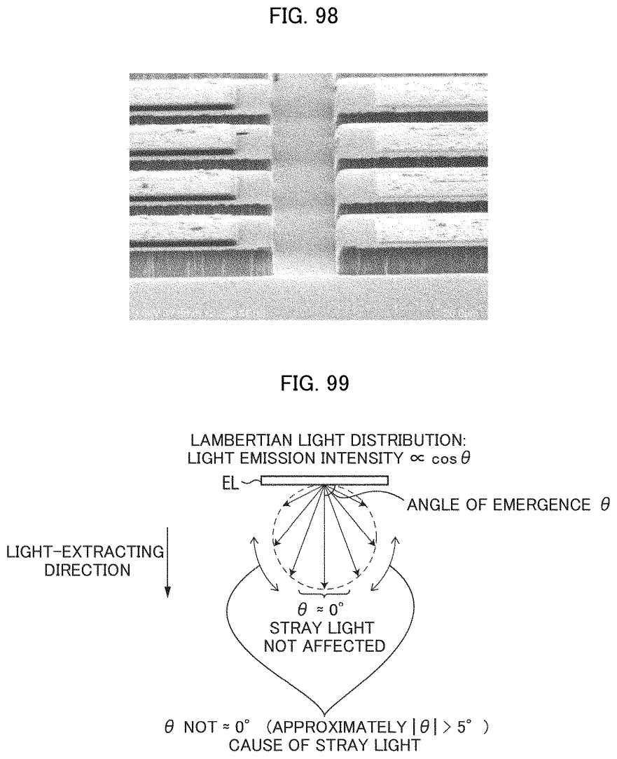

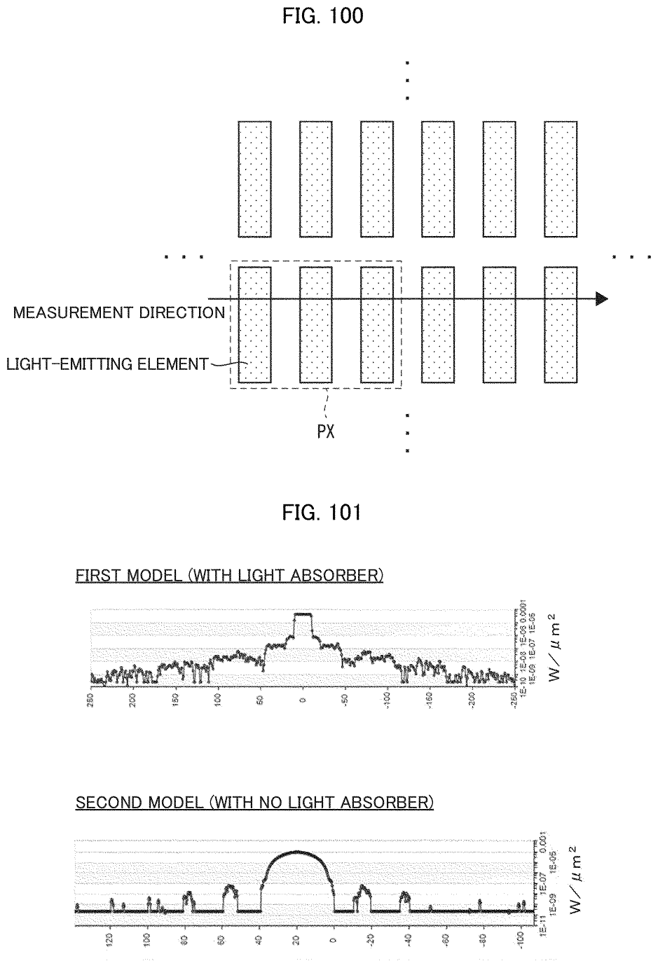

FIG. 97 is a schematic cross-sectional view of the light-emitting device 10V. In FIG. 97, reference numeral 810 is a schematic cross-sectional view of the light-emitting element DV taken parallel to the long side of the light-emitting element DV (see also FIG. 100 described later), and reference numeral 820 is a schematic cross-sectional view of the light-emitting element DV taken parallel to the short side of the light-emitting element DV. Unlike the example of FIG. 96, FIG. 97 shows the light-emitting element DV before it is mounted to the drive circuit DK. FIG. 98 is an exemplary image of the plurality of actual light-emitting elements DV manufactured by the inventors.

### Description of Cause of Stray Light

A description is given next of an exemplary cause of stray light in a light-emitting device in accordance with an aspect of the present disclosure with reference to FIG. 99. The angle of emergence θ of light in the example of FIG. 99 is the angle between the optical axis of the light emitted through the primary face of the light-emitting layer EL and the normal to the primary face of the light-emitting layer EL. The direction of this normal in the example of FIG. 99 is supposed to match with the light-extracting direction.

The emitted light in the example of FIG. 99 exhibits a Lambertian light distribution. In other words, the light emission intensity in the example of FIG. 99 is proportional to cosθ. When θ≈0°, the direction in which the emitted light travels substantially matches with the light-extracting direction. Therefore, the component of the emitted light at θ≈0° is a primary emitted light component and hardly affects stray light.

On the other hand, when θ≈0° is not the case, the direction in which the emitted light travels does not well match with the light-extracting direction. Throughout the following description, the direction that is parallel to the primary face of the light-emitting layer EL in the plane of the paper on which FIG. 99 is drawn is referred to as the lateral direction. When θ≈0° is not the case, the emitted light that has a lateral direction component would be a likely cause of stray light. Specifically, the components of the emitted light at approximately |θ|>5° would be a likely cause of stray light.

If, for example, there is a metal electrode in the light-emitting element, the emitted light that have a lateral direction component is reflected off this metal electrode. Then, the reflection off the metal electrode can propagate in the lateral direction inside the light-emitting device. Therefore, for example, the reflected light that travels from the light-emitting element toward the atmosphere can be refracted at the interface between the light-emitting element and the atmosphere. Likewise, the reflected light that travels from the atmosphere toward the light-emitting element can be refracted at the same interface. In addition, the reflected light that travels from the light-emitting element toward the mounting substrate can be refracted at the interface between the light-emitting element and the mounting substrate. As described here, the propagation direction of reflected light can change due to the refraction of the reflected light at various interfaces. This diverse propagation directions of the reflected light can be a likely cause of stray light.

In the light-emitting device, the difference between the refractive index of the light-emitting element and the refractive index of the atmosphere would be relatively large. Reflection of light would therefore evidently occur at the interface between the light-emitting element and the atmosphere. From this, the stray light intensity can exhibit a cyclic distribution that corresponds to the layout and interval of the light-emitting elements. As described here, for example, cyclic spiky stray light peaks can occur due to the emitted light that has a lateral direction component in the light-emitting device in accordance with an aspect of the present disclosure. The spiky stray light peaks can occur at locations that can correspond to, for example, the locations of the sidewalls of the light-emitting element.

### Analysis of Reduction of Stray Light

Stray light in the light-emitting device could lead to poor display quality in the display device including this light-emitting device. Accordingly, the inventors analyzed through a simulation how the light absorber HK could contribute to reduction of stray light. First, the inventors constructed a first model and a second model as simulation models. The first model simulated a light-emitting device including a light-emitting element that in turn included the light absorber HK (e.g., the light-emitting device 10V). Meanwhile, the second model simulated a light-emitting device including a light-emitting element that in turn did not include the light absorber HK (e.g., the light-emitting device 10).

Referring to FIG. 100, the inventors specified the short side direction of the light-emitting element as the light intensity measurement direction in each of the first model and the second model. The inventors then derived a distribution of light intensity in this measurement direction by a simulation for each of the first model and the second model. FIG. 101 represents exemplary light intensity distributions respectively in the first model and in the second model derived in a simulation. In the graph of FIG. 101, the horizontal axis shows positions along the measurement direction, and the vertical axis shows light intensities.

It is understood from FIG. 101 that the simulation demonstrates that the provision of the light absorber HK enables effective reduction of stray light. Specifically, it is verified that the maximum stray light intensity can be reduced approximately to 1/10 when the light absorber HK is provided in comparison with when the light absorber HK is not provided. It is also verified that the provision of the light absorber HK enables reduction of cyclic spiky stray light peaks.

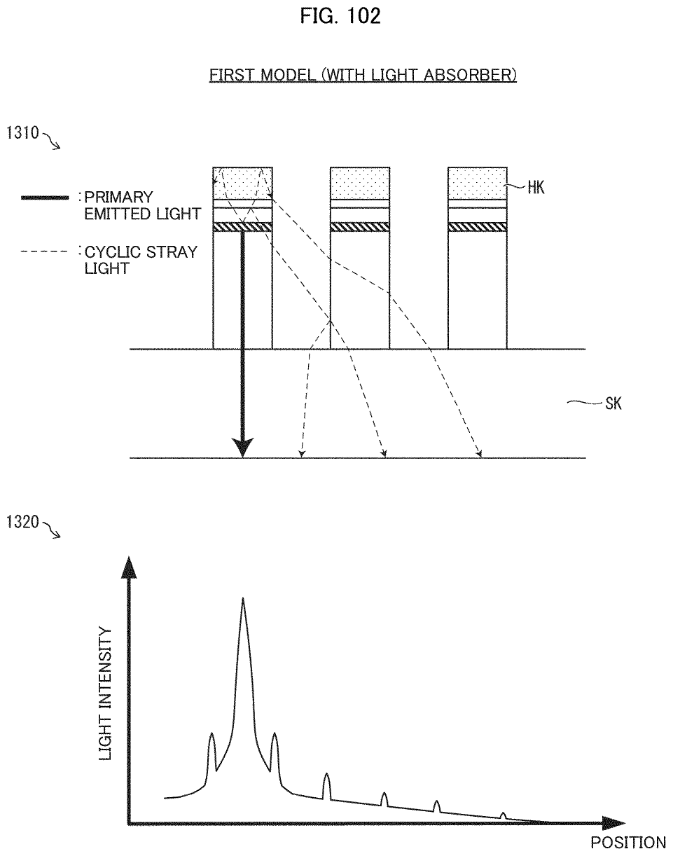

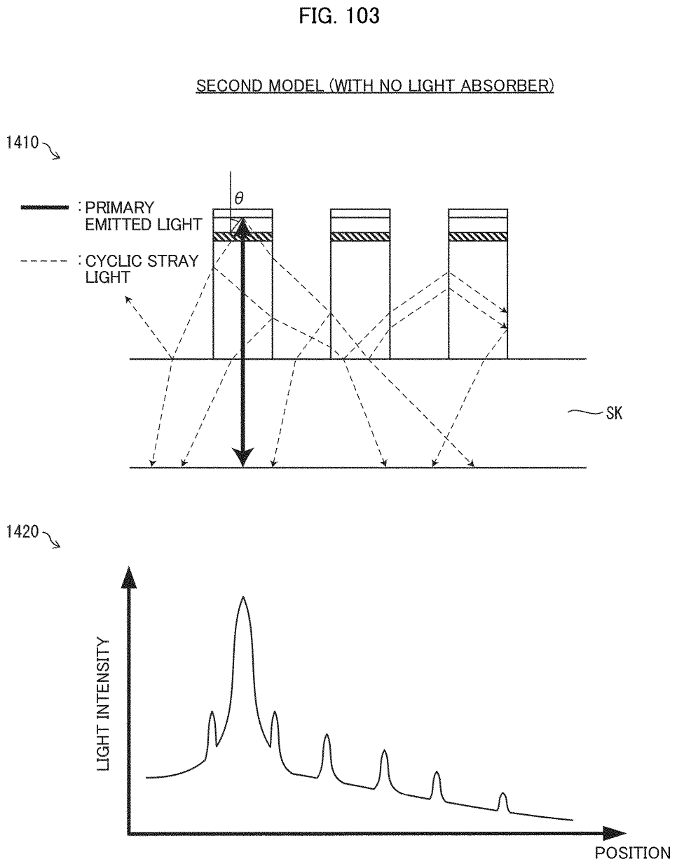

FIG. 102 is a schematic illustration of stray light that occurs in the first model, and FIG. 103 is a schematic illustration of stray light that occurs in the second model. Under reference numeral 1310 in FIG. 102 and reference numeral 1410 in FIG. 103, only the leftmost one of the three light-emitting elements in the plane of the paper is shown to be emitting light as an example.

Under reference numeral 1320 in FIG. 102, a schematic example of light intensity distribution in the first model is shown. Meanwhile, under reference numeral 1420 in FIG. 103, a schematic example of light intensity distribution in the second model is shown. In the first model, unlike in the second model, much of the reflected light that comes from the emitted light that has a lateral direction component can be absorbed by the light absorber HK. Therefore, the stray light intensity can be reduced overall in the first model when compared with the second model. In addition, the cyclic spiky stray light peaks can be reduced in the first model when compared with the second model.

### Effects

As described so far, the light-emitting device 10V enables reducing stray light through the non-conventional structure of the light-emitting device. For example, unlike the light-emitting device described in Patent Literature 1, the light-emitting device 10V enables reducing stray light without having to use a reflector. As described here, the light-emitting device 10V has been invented on the basis of a concept that cannot be found in conventional art.

The analyses conducted by inventors have revealed that the influence of stray light in the light-emitting device in accordance with an aspect of the present disclosure is increasingly evident with, for example, a decrease in the distance between the light-emitting elements. From this, the light-emitting device 10V is preferably used in the display device 50 that is compact. Therefore, as an example, the display device 50 may include the light-emitting device 10V. The display device 50 can be hence provided that exhibits excellent display quality.

### Another Exemplary Structure of Light-Emitting Device 10V

FIG. 104 illustrates another exemplary structure of the light-emitting device 10V. The light-emitting layer EL in accordance with Embodiment 13 may include a first light-emitting layer EL1 that emits first-color light, a second light-emitting layer EL2 that emits second-color light, and a third light-emitting layer EL3 that emits third-color light. Therefore, the light-emitting device 10V may include a first light-emitting element DV1 that includes the first light-emitting layer EL1, a second light-emitting element DV2 that includes the second light-emitting layer EL2, and a third light-emitting element DV3 that includes the third light-emitting layer EL3.

The second-color light may have a different color than the first-color light. As an example, the second-color light may be light that has a longer wavelength than the first-color light. In addition, the third-color light may have a different color than the first-color light and the second-color light. As an example, the second-color light may be light that has a longer wavelength than the first-color light and the second-color light. Therefore, as an example, the first-color light may be blue light, the second-color light may be green light, and the third-color light may be red light. The third light-emitting element DV3 may be a light-emitting element that is adjacent to the second light-emitting element DV2. Therefore, as an example, the first light-emitting element DV1, the second light-emitting element DV2, and the third light-emitting element DV3 may be disposed in this order along the measurement direction shown in FIG. 100.

The second light-emitting element DV2 may have a first dummy light-emitting layer DM1. The first dummy light-emitting layer DM1 may be made of the same material as the first light-emitting layer EL1. The first dummy light-emitting layer DM1 may reside in the same location as the first light-emitting layer EL1 in terms of the height direction of the light-emitting device 10V. The first dummy light-emitting layer DM1 in the second light-emitting element DV2 needs only to be structured so as not to emit light when the second light-emitting element DV2 is being driven.

From the description so far, the second light-emitting layer EL2 can reside in a different location than the first light-emitting layer EL1 in terms of the height direction of the light-emitting device 10V. The second light-emitting layer EL2 is disposed below the first light-emitting layer EL1 in the example of FIG. 104. As described here, the distance from the light-extracting face of the light-emitting device 10V to the first light-emitting layer EL1 can differ from the distance from this light-extracting face to the second light-emitting layer EL2. Therefore, the distance from the light-extracting face of the light-emitting device 10V to the light absorber HK in the first light-emitting element DV1 can differ from the distance from this light-extracting face to the light absorber HK in the second light-emitting element DV2.

The third light-emitting element DV3 may have a first dummy light-emitting layer DM1 and a second dummy light-emitting layer DM2. The second dummy light-emitting layer DM2 may be made of the same material as the second light-emitting layer EL2. The second dummy light-emitting layer DM2 may reside in the same location as the second light-emitting layer EL2 in terms of the height direction of the light-emitting device 10V. The first dummy light-emitting layer DM1 and the second dummy light-emitting layer DM2 in the third light-emitting element DV3 need only to be structured so as not to emit light when the third light-emitting element DV3 is being driven.

From the description so far, the third light-emitting layer EL3 can reside in a different location than the first light-emitting layer EL1 and the second light-emitting layer EL2 in terms of the height direction of the light-emitting device 10V. The third light-emitting layer EL3 is disposed below the second light-emitting layer EL2 in the example of FIG. 104. As described here, the distance from the light-extracting face of the light-emitting device 10V to the second light-emitting layer EL2 can differ from the distance from this light-extracting face to the third light-emitting layer EL3. Therefore, the distance from the light-extracting face of the light-emitting device 10V to the light absorber HK in the second light-emitting element DV2 can also differ from the distance from this light-extracting face to the light absorber HK in the third light-emitting element DV3.

### Alternative Exemplary Structure of Light-Emitting Device 10V

Alternatively, the light-emitting layer EL in accordance with Embodiment 13 may be only the first light-emitting layer EL1 that emits the first-color light. When this is the case, all the light-emitting elements in the light-emitting device 10V may be disposed in the same location in terms of the height direction of the first light-emitting layer EL1 (see also FIG. 96 described earlier).

As described here, the distance from the light-extracting face of the light-emitting device 10V to the first light-emitting layer EL1 in the first light-emitting element DV1 may be equal to the distance from this light-extracting face to the first light-emitting layer EL1 in the second light-emitting element DV2. Therefore, the distance from the light-extracting face of the light-emitting device 10V to the light absorber HK in the first light-emitting element DV1 may also be equal to the distance from this light-extracting face to the light absorber HK in the second light-emitting element DV2.

In addition, when the light-emitting layer EL in accordance with Embodiment 13 is only the first light-emitting layer EL1, the light-emitting device 10V may include a wavelength conversion member for converting the first-color light to light of another color. As an example, the light-emitting device 10V may include, as the wavelength conversion member, (i) a first wavelength conversion member for converting the first-color light to the second-color light and (ii) a second wavelength conversion member for converting the first-color light to the third-color light. The first wavelength conversion member may be disposed in the light-extracting side of the first light-emitting layer EL1 in the second light-emitting element DV2. In addition, the second wavelength conversion member may be disposed in the light-extracting side of the first light-emitting layer EL1 in the third light-emitting element DV3.

According to the this structure, the first-color light emitted by the first light-emitting layer EL1 in the first light-emitting element DV1 is discharged outside the light-emitting device 10V without being converted by the wavelength conversion member. Meanwhile, the first-color light emitted by the first light-emitting layer EL1 in the second light-emitting element DV2 is converted to the second-color light by the first wavelength conversion member. Therefore, the converted second-color light is discharged outside the light-emitting device 10V. In addition, the first-color light emitted by the first light-emitting layer EL1 in the third light-emitting element DV3 is converted to the third-color light by the second wavelength conversion member. Therefore, the converted third-color light is discharged outside the light-emitting device 10V. As described so far, even when the first light-emitting layer EL1, which emits the first-color light, is used alone, the light-emitting device 10V can be provided which emits the first-color light, the second-color light, and the third-color light.

### Summation 1

The present disclosure, in aspect 1 thereof, is directed to a light-emitting device including: a first semiconductor layer including a first light-emitting layer; and a second semiconductor layer including a second light-emitting layer, wherein the first semiconductor layer has a first sidewall adjacent to a second sidewall of the second semiconductor layer over a gap, and a normal to the first sidewall is not parallel to a normal to the second sidewall.

In aspect 2 of the present disclosure, the light-emitting device of aspect 1 may be configured such that the first sidewall and the second sidewall are separated from each other by a minimum distance of from 30 nm to 2.0 μm.

In aspect 3 of the present disclosure, the light-emitting device of aspect 1 or 2 may be configured such that the first sidewall and the second sidewall are separated from each other by a variable distance in a plan view of the first semiconductor layer and the second semiconductor layer.

In aspect 4 of the present disclosure, the light-emitting device of any of aspects 1 to 3 may be configured such that the gap has a lower refractive index than refractive indices of the first semiconductor layer and the second semiconductor layer.

In aspect 5 of the present disclosure, the light-emitting device of any of aspects 1 to 4 may be configured such that the first light-emitting layer and the second light-emitting layer are separated by different distances from a light-extracting face.

In aspect 6 of the present disclosure, the light-emitting device of any of aspects 1 to 5 may be configured such that light exits also through the first sidewall and the second sidewall.

In aspect 7 of the present disclosure, the light-emitting device of any of aspects 1 to 6 may be configured such that the first sidewall and the second sidewall are planar.

In aspect 8 of the present disclosure, the light-emitting device of any of aspects 1 to 7 may be configured such that the first sidewall and the second sidewall are curved.

In aspect 9 of the present disclosure, the light-emitting device of any of aspects 1 to 7 may be configured such that the first semiconductor layer and the second semiconductor layer are quadrilateral in a plan view.

In aspect 10 of the present disclosure, the light-emitting device of any of aspects 1 to 6 and 8 may be configured such that the first semiconductor layer and the second semiconductor layer are elliptical in a plan view.

In aspect 11 of the present disclosure, the light-emitting device of aspect 10 may be configured such that a major axis of an ellipse of the first semiconductor layer in a plan view is not parallel to a major axis of the second semiconductor layer in a plan view.

In aspect 12 of the present disclosure, the light-emitting device of aspect 7 may be configured such that the first semiconductor layer and the second semiconductor layer are concave polygons with five or more sides in a plan view.

In aspect 13 of the present disclosure, the light-emitting device of any of aspects 1 to 12 may be configured such that the first sidewall and the second sidewall are separated from each other by a distance that does not change with a position along a thickness direction.

In aspect 14 of the present disclosure, the light-emitting device of any of aspects 1 to 12 may be configured such that the first sidewall and the second sidewall are separated from each other by a distance that changes with a position along a thickness direction.

In aspect 15 of the present disclosure, the light-emitting device of aspect 14 may be configured such that the first semiconductor layer and the second semiconductor layer are tapered.

In aspect 16 of the present disclosure, the light-emitting device of aspect 15 may be configured such that the first semiconductor layer and the second semiconductor layer become thinner with an increase in a distance from a light-extracting face.

In aspect 17 of the present disclosure, the light-emitting device of any of aspects 1 to 16 may be configured such that the normal to the first sidewall and the normal to the second sidewall form an acute angle of less than or equal to 10°.

In aspect 18 of the present disclosure, the light-emitting device of any of aspects 1 to 17 may be configured so as to further include a third semiconductor layer including a third light-emitting layer, wherein the third semiconductor layer has a third sidewall adjacent to a fourth sidewall of the second semiconductor layer opposite the second sidewall over a gap, and a normal to the third sidewall is not parallel to a normal to the fourth sidewall.

In aspect 19 of the present disclosure, the light-emitting device of any of aspects 1 to 18 may be configured so as to include a first light-emitting element including the first light-emitting layer and a second light-emitting element including the second light-emitting layer.

In aspect 20 of the present disclosure, the light-emitting device of aspect 19 may be configured so as to further include: a growth substrate bonded to the first semiconductor layer and the second semiconductor layer; and a driver substrate to which the first light-emitting element and the second light-emitting element are mounted.

In aspect 21 of the present disclosure, the light-emitting device of any of aspects 1 to 20 may be configured such that light that exits the first light-emitting layer and the second light-emitting layer exhibits a Lambertian light distribution.

In aspect 22 of the present disclosure, the light-emitting device of any of aspects 1 to 21 may be configured such that both the first semiconductor layer and the second semiconductor layer are a gallium-containing nitride semiconductor crystal.

In aspect 23 of the present disclosure, the light-emitting device of any of aspect 20 and aspects 21 and 22, which are dependent from aspect 20, may be configured such that the first semiconductor layer is bonded to a growth face of the growth substrate, and a face opposite the growth face of the growth substrate is a light-extracting face.

In aspect 24 of the present disclosure, the light-emitting device of any of aspect 19 and aspects 20 to 23, which are dependent from aspect 19, may be configured such that the first light-emitting element includes an anode and a cathode, and either one or both of the anode and the cathode exhibit(s) light reflectivity.

The present disclosure, in aspect 25 thereof, is directed to a display device including the light-emitting device of any of aspects 1 to 24.

The present disclosure, in aspect 26 thereof, is directed to a wearable device including the light-emitting device of any of aspects 1 to 25.

The present disclosure, in aspect 27 thereof, is directed to a method of manufacturing a light-emitting device, the method including: a step of growing a semiconductor crystal on a growth substrate; and a step of forming a first semiconductor layer and a second semiconductor layer by patterning the semiconductor crystal, the first semiconductor layer including a first light-emitting layer and having a first sidewall, the second semiconductor layer including a second light-emitting layer and having a second sidewall, wherein the first sidewall is adjacent to the second sidewall over a gap, and a normal to the first sidewall is not parallel to a normal to the second sidewall.

In aspect 28 of the present disclosure, the method of manufacturing a light-emitting device of aspect 27 may be configured so as to further include: a step of forming a first light-emitting element including the first semiconductor layer and a second light-emitting element including the second semiconductor layer; and a step of mounting the first light-emitting element and the second light-emitting element to a driver substrate.

In a light-emitting device in accordance with the present disclosure, a normal to the first sidewall may intersect with the second sidewall, and a normal to the second sidewall may intersect with the first sidewall.

In a light-emitting device in accordance with the present disclosure, the first semiconductor layer and the second semiconductor layer may have a refractive index greater than or equal to twice the refractive index of the gap.

In a light-emitting device in accordance with the present disclosure, the quadrilateral of aspect 9 may be any one of a rectangle, a trapezoid, and a rhombus.

In a light-emitting device in accordance with the present disclosure, the second semiconductor layer may include a dummy light-emitting layer made of a same material as the first light-emitting layer.

In a light-emitting device in accordance with the present disclosure, the first light-emitting layer may emit light of a first color, and the second light-emitting layer may emit light of a second color.

In a light-emitting device in accordance with the present disclosure, the first sidewall and the second sidewall may be covered with respective insulating films, in which case a normal to the insulating film covering the first sidewall is not parallel to a normal to the insulating film covering the second sidewall.

In a light-emitting device in accordance with the present disclosure, a normal to the third sidewall may intersect with the fourth sidewall, and a normal to the fourth sidewall may intersect with the third sidewall.

In a light-emitting device in accordance with the present disclosure, the third sidewall and the fourth sidewall may be separated from each other by a minimum distance of from 30 nm to 2.0 μm.

In a light-emitting device in accordance with the present disclosure, the third sidewall and the fourth sidewall may be separated from each other by a variable distance in a plan view of the third semiconductor layer and the second semiconductor layer.

In a light-emitting device in accordance with the present disclosure, the third light-emitting layer may emit light of a third color.

In a light-emitting device in accordance with the present disclosure, the first light-emitting element may include an anode and a cathode between the first semiconductor layer and the driver substrate.

In a light-emitting device in accordance with the present disclosure, the first semiconductor layer may include an anode contact layer in contact with the anode and a cathode contact layer in contact with the cathode, and both the anode contact layer and the cathode contact layer may be an n-type semiconductor layer.

In a light-emitting device in accordance with the present disclosure, the first semiconductor layer may include a tunnel junction layer between the first light-emitting layer and the anode contact layer.

In a light-emitting device in accordance with the present disclosure, the anode and the cathode may be made of a same material.

In a light-emitting device in accordance with the present disclosure, the first semiconductor layer may include a buffer layer in contact with the growth substrate.

In a light-emitting device in accordance with the present disclosure, the first color may be any of red, green, and blue colors.

### Summation 2

A display panel according to a first aspect of the present disclosure includes: a plurality of light-emitting elements each including an island-shaped multilayer stack, an anode, and a cathode, the island-shaped multilayer stack including a plurality of semiconductor layers stacked on top of another and including a light-emitting layer; and a light absorber provided between a plurality of the island-shaped multilayer stacks each included in one of the plurality of light-emitting elements, the light absorber containing a material different from a material of the island-shaped multilayer stacks and absorbing light in a visible light region.

A display panel according to a second aspect of the present disclosure is the display panel according to the first aspect. The display panel according to the second aspect may further include an insulating film provided between the island-shaped multilayer stack and the light absorber.

A display panel according to a third aspect of the present disclosure is the display panel according to the first or second aspect. In the display panel according to the third aspect, the light absorber may have a transmittance of 0.7 or less in the visible light region.

A display panel according to a fourth aspect of the present disclosure is the display panel according to the first or second aspect. In the display panel according to the fourth aspect, the light absorber may have a transmittance of 0.3 or less in the visible light region.

A display panel according to a fifth aspect of the present disclosure is the display panel according to any one of the first to fourth aspects. In the display panel according to the fifth aspect, a refractive index of the light absorber may be larger by 0.1 or more than a refractive index of a material forming the island-shaped multilayer stack.

A display panel according to a sixth aspect of the present disclosure is the display panel according to any one of the first to fourth aspects. In the display panel according to the sixth aspect, the refractive index of the light absorber may be larger by 1.5 or more than the refractive index of the material forming the island-shaped multilayer stack.

A display panel according to a seventh aspect of the present disclosure is the display panel according to any one of the first to fourth aspects. In the display panel according to the seventh aspect, the refractive index of the light absorber may be smaller by 0.1 or more than the refractive index of the material forming the island-shaped multilayer stack.

A display panel according to an eighth aspect of the present disclosure is the display panel according to any one of the first to fourth aspects. In the display panel according to the eighth aspect, the refractive index of the light absorber may be smaller by 1.5 or more than the refractive index of the material forming the island-shaped multilayer stack.

A display panel according to a ninth aspect of the present disclosure is the display panel according to any one of the first to eighth aspects. In the display panel according to the ninth aspect, the light absorber may be either an organic compound or an inorganic compound.

A display panel according to a tenth aspect of the present disclosure is the display panel according to any one of the first to eighth aspects. In the display panel according to the tenth aspect, the light absorber may include a pyridine skeleton.

A display panel according to an eleventh aspect of the present disclosure is the display panel according to any one of the first to eight aspects. In the display panel according to the eleventh aspect, the light absorber may contain one or more selected from the group consisting of a modified acrylic-based resin, an epoxy-based resin, a urethane-based resin, a cyanoacrylate-based resin, a fluoroethylene-based resin, a silicone-based resin, polyvinyl alcohol (PVA), and polyvinyl chloride (PVC).

A display panel according to a twelfth aspect of the present disclosure is the display panel according to any one of the first to eight aspects. In the display panel according to the twelfth aspect, the light absorber may contain one or more selected from the group consisting of an azo-based dye, a quinone-based dye, an indigo-based dye, a polymethine-based dye, a styryl-based dye, an azo-based pigment, a quinone-based pigment, an indigo-based pigment, a polymethine-based pigment, and a styryl-based pigment.

A display panel according to a thirteenth aspect of the present disclosure is the display panel according to any one of the first to eight aspects. In the display panel according to the thirteenth aspect, the light absorber may contain one or more selected from the group consisting of a carbon material, a metal sulfide, and a semiconductor material that absorbs light in the visible light region.

A display panel according to a fourteenth aspect of the present disclosure is the display panel according to the second aspect. In the display panel according to the fourteenth aspect, the insulating film may include any one of a silicon oxide film, a silicon nitride film, a silicon oxynitride film, and an aluminum oxide film.

A display panel according to a fifteenth aspect of the present disclosure is the display panel according to the second or fourteenth aspect. In the display panel according to the fifteenth aspect, the insulating film may be formed to have a thickness of 3 nm or more and 100 nm or less in a direction perpendicular to a sidewall of the island-shaped multilayer stack.

A display panel according to a sixteenth aspect of the present disclosure is the display panel according to any one of the first to fifteenth aspects. In the display panel according to the sixteenth aspect, the light absorber may be formed as high as, or lower than, a thickness between a surface, of each of the semiconductor layers, toward a display surface and a surface, of the light-emitting layer, toward the display surface, each of the semiconductor layers being closest from the display surface that releases light emitted from the light-emitting layer, and the light-emitting layer being closest from the display surface.

A display panel according to a seventeenth aspect of the present disclosure is the display panel according to any one of the first to fifteenth aspects. In the display panel according to the seventeenth aspect, the plurality of light-emitting elements may include: a first light-emitting element configured to emit light in a first color; a second light-emitting element configured to emit light in a second color different from the first color; and a third light-emitting element configured to emit light in a third color different from the first color and the second color, the first light-emitting element may include, as the island-shaped multilayer stack, a first multilayer stack including a first light-emitting layer configured to emit light in the first color, the second light-emitting element may include, as the island-shaped multilayer stack, the first multilayer stack and a second multilayer stack, the second multilayer stack including a second light-emitting layer provided further from a display surface than the first multilayer stack, and configured to emit light in the second color, the display surface releasing light emitted from the light-emitting layer, the third light-emitting element may include, as the island-shaped multilayer stack, the first multilayer stack, the second multilayer stack, and a third multilayer stack, the third multilayer stack including a third light-emitting layer provided further from the display surface than the second multilayer stack, and configured to emit light in the third color, and the light absorber may be formed as high as, or lower than, a thickness between a surface, of one of the semiconductor layers, toward the display surface and a surface, of the third light-emitting layer, toward the display surface, the one semiconductor layer being closest from the display surface.

### Summation 3

A display panel according to a first aspect of the present disclosure includes: a plurality of light-emitting elements each including an island-shaped multilayer stack, an anode, and a cathode, the island-shaped multilayer stack including a plurality of semiconductor layers stacked on top of another and including a light-emitting layer; and scatterers provided between a plurality of the island-shaped multilayer stacks each included in one of the plurality of light-emitting elements, the scatterers containing a material different from a material of the island-shaped multilayer stacks and scattering light in a visible light region.

A display panel according a second aspect of the present disclosure is the display panel according to the first aspect. The display panel according to the second aspect may include a recess portion containing the scatterers and provided between the plurality of island-shaped multilayer stacks each included in one of the plurality of light-emitting elements, the recess portion being shorter in height than a tallest portion of each of the plurality of island-shaped multilayer stacks.

A display panel according to a third aspect of the present disclosure is the display panel according to the second aspect. In the display panel according to the third aspect, the recess portion may be formed as high as, or lower than, a thickness between a surface, of each of the semiconductor layers, toward a display surface and a surface, of the light-emitting layer, toward the display surface, each of the semiconductor layers being closest from the display surface that releases light emitted from the light-emitting layer, and the light-emitting layer being closest from the display surface.

A display panel according to a fourth aspect of the present disclosure is the display panel according to the second aspect. The display panel according to the fourth aspect may further include a substrate having the display surface that releases light emitted from the light-emitting layer, wherein a bottom surface of the recess portion may be a surface, of the substrate, across from the display surface.

A display panel according to a fifth aspect of the present disclosure is the display panel according to the second aspect. The display panel according to the fifth aspect may further include a substrate having the display surface that releases light emitted from the light-emitting layer, wherein a bottom surface of the recess portion may be an indentation portion formed on a surface, of the substrate, across from the display surface.

A display panel according to a sixth aspect of the present disclosure is the display panel according to any one of the first to fifth aspects. The display panel according to the sixth aspect may further include an insulating film provided between the island-shaped multilayer stack and the scatterers.

A display panel according to a seventh aspect of the present disclosure is the display panel according to the sixth aspect. In the display panel according to the seventh aspect, the insulating film includes any one of a silicon oxide film, a silicon nitride film, a silicon oxynitride film, and an aluminum oxide film.

A display panel according to an eighth aspect of the present disclosure is the display panel according to the sixth aspect. In the display panel according to the eighth aspect, the insulating film may be formed to have a thickness of 3 nm or more and 100 nm or less in a direction perpendicular to a sidewall of the island-shaped multilayer stack.

A display panel according to a ninth aspect of the present disclosure is the display panel according to any one of the first to eighth aspects. In the display panel according to the ninth aspect, each of the scatterers may have a maximum length 5 nm or more and 5 μm or less.

A display panel according to a tenth aspect of the present disclosure is the display panel according to any one of the first to eighth aspects. In the display panel according to the tenth aspect, each of the scatterers may be a nanoparticle.

A display panel according to an eleventh aspect of the present disclosure is the display panel according to any one of the first to tenth aspects. In the display panel according to the eleventh aspect, each of the scatterers may be a nanoparticle including a core and a shell.

A display panel according to a twelfth aspect of the present disclosure is the display panel according to any one of the first to eleventh aspects. In the display panel according to the twelfth aspect, the scatterers may be either an organic compound or an inorganic compound.

A display panel according to a thirteenth aspect of the present disclosure is the display panel according to any one of the first to eleventh aspects. In the display panel according to the thirteenth aspect, the scatterer may be any one of an insulator, a semiconductor, a metal, or a metal oxide.

A display panel according to a fourteenth aspect of the present disclosure is the display panel according to any one of the first to eleventh aspects. In the display panel according to the fourteenth aspect, the scatterers may be a resin containing one or more of an acrylic group, an epoxy group, a urethane group, and a silicone group.

A display panel according to a fifteenth aspect of the present disclosure is the display panel according to any one of the first to fourteenth aspects. In the display panel according to the fifteenth aspect, a refractive index of the scatterers may be different from a refractive index of at least one layer included in the island-shaped multilayer stack.

A display panel according to a sixteenth aspect of the present disclosure is the display panel according to any one of the first to fifteenth aspects. The display panel according to the sixteenth aspect may further include a light absorber provided around the scatterers to absorb light in a visible light region.

A display panel according to a seventeenth aspect of the present disclosure is the display panel according to the sixteenth aspect. In the display panel according to the seventeenth aspect, the light absorber may be either an organic compound or an inorganic compound.

A display panel according to an eighteenth aspect of the present disclosure is the display panel according to the sixteenth aspect. In the display panel according to the eighteenth aspect, the light absorber may include a pyridine skeleton.

A display panel according to a nineteenth aspect of the present disclosure is the display panel according to sixteenth aspect. In the display panel according to the nineteenth aspect, the light absorber may contain one or more selected from the group consisting of a modified acrylic-based resin, an epoxy-based resin, a urethane-based resin, a cyanoacrylate-based resin, a fluoroethylene-based resin, a silicone-based resin, polyvinyl alcohol (PVA), and polyvinyl chloride (PVC).

A display panel according to a twentieth aspect of the present disclosure is the display panel according to a sixteenth aspect. In the display panel according to the twentieth aspect, the light absorber may contain one or more selected from the group consisting of an azo-based dye, a quinone-based dye, an indigo-based dye, a polymethine-based dye, a styryl-based dye, an azo-based pigment, a quinone-based pigment, an indigo-based pigment, a polymethine-based pigment, and a styryl-based pigment.

A display panel according to a twenty first aspect of the present disclosure is the display panel according to the sixteenth aspect. In the display panel according to the twenty first aspect, the light absorber may contain one or more selected from the group consisting of a carbon material, a metal sulfide, and a semiconductor material that absorbs light in the visible light region.

A display panel according to a twenty second aspect of the present disclosure is the display panel according to any one of the first, second and fourth to eighth aspects. In the display panel according to the twenty second aspect, the plurality of light-emitting elements may include: a first light-emitting element configured to emit light in a first color; a second light-emitting element configured to emit light in a second color different from the first color; and a third light-emitting element configured to emit light in a third color different from the first color and the second color, the first light-emitting element may include, as the island-shaped multilayer stack, a first multilayer stack including a first light-emitting layer configured to emit light in the first color, the second light-emitting element may include, as the island-shaped multilayer stack, the first multilayer stack and a second multilayer stack, the second multilayer stack including a second light-emitting layer provided further from a display surface than the first multilayer stack, and configured to emit light in the second color, the display surface releasing light emitted from the light-emitting layer, the third light-emitting element may include, as the island-shaped multilayer stack, the first multilayer stack, the second multilayer stack, and a third multilayer stack, the third multilayer stack including a third light-emitting layer provided further from the display surface than the second multilayer stack, and configured to emit light in the third color, and the display panel may further include a recess portion containing the scatterers and shorter in height than a tallest portion of the island-shaped multilayer stack included in the third light-emitting element, the recess portion being formed as high as, or lower than, a thickness between a surface, of each of the semiconductor layers, toward a display surface and a surface, of the third light-emitting layer, toward the display surface, each of the semiconductor layers being closest from the display surface that releases light emitted from the light-emitting layer.

### Summation 4

The present disclosure, in aspect 1 thereof, is directed to a light-emitting device including a plurality of light-emitting elements each including: an anode; a cathode; and a light absorber, each two adjacent light-emitting elements in the plurality of light-emitting elements being electrically insulated from each other, wherein the light absorber includes either one or both of (i) an anode-side light absorber disposed below the anode when viewed from a light-extracting side of the light-emitting device and (ii) a cathode-side light absorber disposed below the cathode when viewed from the light-extracting side.

In aspect 2 of the present disclosure, the light-emitting device of aspect 1 may be configured such that either one or both of the anode and the cathode is/are transparent to light.

In aspect 3 of the present disclosure, the light-emitting device of aspect 1 or 2 may be configured such that either one or both of the anode and the cathode contain(s), as a material, at least one of ITO, FTO, IGZO, ZnO, silicide, and SiC.

In aspect 4 of the present disclosure, the light-emitting device of any one of aspects 1 to 3 may be configured such that the light absorber has a refractive index that differs by not more than ±0.5 from a refractive index of a semiconductor material that constitutes the plurality of light-emitting elements.

In aspect 5 of the present disclosure, the light-emitting device of any one of aspects 1 to 4 may be configured such that the light absorber has an extinction coefficient of greater than or equal to 5.

In aspect 6 of the present disclosure, the light-emitting device of any one of aspects 1 to 5 may be configured such that the light absorber has a thickness of from 0.5 μm to 5 μm both inclusive.

In aspect 7 of the present disclosure, the light-emitting device of any one of aspects 1 to 6 may be configured such that the light absorber is electrically conductive.

In aspect 8 of the present disclosure, the light-emitting device of any one of aspects 1 to 7 may be configured such that the light absorber contains a Group IV semiconductor, a Group III-V semiconductor except for nitrides, C, or a metal sulfide.

In aspect 9 of the present disclosure, the light-emitting device of any one of aspects 1 to 8 may be configured such that the light absorber is either (i) graphite containing C as a primary component or (ii) DLC containing C and H.

In aspect 10 of the present disclosure, the light-emitting device of any one of aspects 1 to 9 may be configured such that each of the plurality of light-emitting elements includes a first light-emitting element and a second light-emitting element, the first light-emitting element includes a first light-emitting layer configured to emit first-color light, the second light-emitting element includes a second light-emitting layer configured to emit second-color light that has a different color than the first-color light, and the light-emitting device has a light-extracting face separated by a different distance from the first light-emitting layer than from the second light-emitting layer.

In aspect 11 of the present disclosure, the light-emitting device of aspect 10 may be configured such that the light-extracting face is separated by a different distance from the light absorber in the first light-emitting element than from the light absorber in the second light-emitting element.

In aspect 12 of the present disclosure, the light-emitting device of any one of aspects 1 to 9 may be configured such that the plurality of light-emitting elements include a first light-emitting element and a second light-emitting element, each of the first light-emitting element and the second light-emitting element includes a first light-emitting layer configured to emit first-color light, and the light-emitting device has a light-extracting face separated by an equal distance from the first light-emitting layer in the first light-emitting element and from the first light-emitting layer in the second light-emitting element.

In aspect 13 of the present disclosure, the light-emitting device of aspect 12 may be configured such that the light-extracting face is separated by an equal distance from the light absorber in the first light-emitting element and from the light absorber in the second light-emitting element.

The present disclosure, in aspect 14 thereof, is directed to a display device including the light-emitting device of any one of aspects 1 to 11.

### Additional Remarks

The present disclosure is not limited to the description of the embodiments above and may be altered within the scope of the claims. Embodiments based on a proper combination of technical means disclosed in different embodiments are encompassed in the technical scope of the present disclosure. Furthermore, new technological features can be created by combining different technical means disclosed in the embodiments.

### CROSS-REFERENCE TO RELATED APPLICATIONS

The present application claims the benefit of priorities to Japanese Patent Application No. 2023-099520, No. 2023-099521, No. 2023-099522 and No. 2023-099523 filed on Jun. 16, 2023, the entire contents of which are incorporated herein by reference.

### REFERENCE SIGNS LIST

10 Light-emitting Device
11 First Semiconductor Layer
12 Second Semiconductor Layer
13 Third Semiconductor Layer
50 Display Device
60 Wearable Device
A1, A2, A3 Anode
BA Buffer Layer
BS Growth Face
C1, C2, C3 Cathode Contact Layer
D1 First Light-emitting Element
D2 Second Light-emitting Element
D3 Third Light-emitting Element
DK Driver Substrate
E1 First Light-emitting Layer
E2 Second Light-emitting Layer
E3 Third Light-emitting Layer
F1, F2, F3 Anode Contact Layer
K1, K2, K3 Cathode
N1, N2 Dummy Light-emitting Layer
S1, S2 Gap
SK Growth Substrate
SL Semiconductor Crystal
T1, T2, T3 Tunnel Junction Layer
TS Light-extracting Face
W1 First Sidewall
W2 Second Sidewall
W3 Third Sidewall
W4 Fourth Sidewall

What is claimed is:

1. A light-emitting device comprising:
a first semiconductor layer including a first light-emitting layer; and
a second semiconductor layer including a second light-emitting layer, wherein
the first semiconductor layer has a first sidewall adjacent to a second sidewall of the second semiconductor layer over a gap,
a normal to the first sidewall is not parallel to a normal to the second sidewall, and
the first sidewall and the second sidewall are separated from each other by a minimum distance of from 30 nm to 2.0 μm.

2. The light-emitting device according to claim 1, wherein the gap has a lower refractive index than refractive indices of the first semiconductor layer and the second semiconductor layer.

3. The light-emitting device according to claim 1, wherein the first light-emitting layer and the second light-emitting layer are separated by different distances from a light-extracting face.

4. The light-emitting device according to claim 1, wherein the first sidewall and the second sidewall are planar.

5. The light-emitting device according to claim 1, wherein the first sidewall and the second sidewall are curved.

6. The light-emitting device according to claim 4, wherein the first semiconductor layer and the second semiconductor layer are quadrilateral in a plan view.

7. The light-emitting device according to claim 5, wherein
the first semiconductor layer and the second semiconductor layer are elliptical in a plan view, and
a major axis of an ellipse of the first semiconductor layer in a plan view is not parallel to a major axis of the second semiconductor layer in a plan view.

8. The light-emitting device according to claim 4, wherein the first semiconductor layer and the second semiconductor layer are concave polygons with five or more sides in a plan view.

9. The light-emitting device according to claim 1, wherein the first sidewall and the second sidewall are separated from each other by a distance that does not change with a position along a thickness direction.

10. The light-emitting device according to claim 1, wherein
the first sidewall and the second sidewall are separated from each other by a distance that changes with a position along a thickness direction,
the first semiconductor layer and the second semiconductor layer are tapered, or
the first semiconductor layer and the second semiconductor layer become thinner with an increase in a distance from a light-extracting face.

11. The light-emitting device according to claim 1, wherein the normal to the first sidewall and the normal to the second sidewall form an acute angle of less than or equal to 10°.

12. The light-emitting device according to claim 1, further comprising a third semiconductor layer including a third light-emitting layer, wherein
the third semiconductor layer has a third sidewall adjacent to a fourth sidewall of the second semiconductor layer opposite the second sidewall over a gap, and
a normal to the third sidewall is not parallel to a normal to the fourth sidewall.

13. The light-emitting device according to claim 1, further comprising a first light-emitting element including the first light-emitting layer and a second light-emitting element including the second light-emitting layer.

14. The light-emitting device according to claim 13, further comprising:
a growth substrate bonded to the first semiconductor layer and the second semiconductor layer; and
a driver substrate to which the first light-emitting element and the second light-emitting element are mounted.

15. The light-emitting device according to claim 1, wherein light that exits the first light-emitting layer and the second light-emitting layer exhibits a Lambertian light distribution.

16. The light-emitting device according to claim 14, wherein
the first semiconductor layer is bonded to a growth face of the growth substrate, and
a face opposite the growth face of the growth substrate is a light-extracting face.

17. The light-emitting device according to claim 13, wherein
the first light-emitting element includes an anode and a cathode, and
either one or both of the anode and the cathode exhibit(s) light reflectivity.

18. A display device or wearable device comprising the light-emitting device according to claim 1.

19. A method of manufacturing a light-emitting device, the method comprising:
a step of growing a semiconductor crystal on a growth substrate; and
a step of forming a first semiconductor layer and a second semiconductor layer by patterning the semiconductor crystal, the first semiconductor layer including a first light-emitting layer and having a first sidewall, the second semiconductor layer including a second light-emitting layer and having a second sidewall, wherein
the first sidewall is adjacent to the second sidewall over a gap, and
a normal to the first sidewall is not parallel to a normal to the second sidewall.

20. The method according to claim 19, further comprising:
a step of forming a first light-emitting element including the first semiconductor layer and a second light-emitting element including the second semiconductor layer; and
a step of mounting the first light-emitting element and the second light-emitting element to a driver substrate.
